(19) United States
(12) Patent Application Publication
(10) Pub. No.: US 2023/0197725 A1
(43) Pub. Date: Jun. 22, 2023

(54) INTEGRATED STRUCTURE OF COMPLEMENTARY METAL-OXIDE-SEMICONDUCTOR DEVICES AND MANUFACTURING METHOD THEREOF

(71) Applicant: Richtek Technology Corporation, Zhubei City (TW)

(72) Inventors: Wu-Te Weng, Hsinchu (TW); Chih-Wen Hsiung, Hsinchu (TW); Ta-Yung Yang, Taoyuan (TW)

(21) Appl. No.: 18/052,950

(22) Filed: Nov. 7, 2022

Related U.S. Application Data
(60) Provisional application No. 63/290,554, filed on Dec. 16, 2021.

(30) Foreign Application Priority Data
Jul. 12, 2022 (TW) 111126166

(51) Int. Cl. H01L 27/092; H01L 21/8238

(52) U.S. Cl. CPC H01L 27/0922; H01L 27/0928; H01L 21/823857; H01L 21/823871; H01L 21/823878; H01L 21/823892; H01L 21/823814

(57) ABSTRACT

An integrated structure of CMOS devices includes: a semiconductor layer, insulation regions, a first high voltage P-type well and a second high voltage P-type well, a first high voltage N-type well and a second high voltage N-type well, a first low voltage P-type well and a second low voltage P-type well, a first low voltage N-type well and a second low voltage N-type well, and eight gates. A CMOS device having an ultra high threshold voltage is formed in ultra high threshold device region; a CMOS device having a high threshold voltage is formed in high threshold device region; a CMOS device having a middle threshold voltage is formed in the middle threshold device region; and a CMOS device having a low threshold voltage is formed in the low threshold device region.

### CROSS REFERENCE

The present invention claims priority to U.S. 63/290,554 filed on Dec. 16, 2021 and claims priority to TW 111126166 filed on Jul. 12, 2022.

### BACKGROUND OF THE INVENTION

### Field of Invention

The present invention relates to an integrated structure of complementary metal-oxide-semiconductor (CMOS) devices and a manufacturing method thereof; particularly, it relates to such integrated structure of CMOS devices which integrates a CMOS device having an ultra high threshold voltage, a CMOS device having a high threshold voltage, a CMOS device having a middle threshold voltage and a CMOS device a having low threshold voltage, and a manufacturing method thereof.

### Description of Related Art

Conventionally, when it is required to use CMOS devices having different threshold voltages in one certain application, the different CMOS devices having different threshold voltages are formed by different dedicated ion implantation process steps specifically for the different threshold voltages. However, the manufacturing time and the manufacturing cost are increased by such an approach.

In view of the above, to overcome the drawbacks in the prior art, the present invention proposes an integration process, which integrates process steps that already exist in the manufacturing process, to form an integrated structure of CMOS devices which integrates different CMOS devices having different threshold voltages, saving manufacturing time and reducing manufacturing cost.

### SUMMARY OF THE INVENTION

From one perspective, the present invention provides an integrated structure of complementary metal-oxide-semiconductor (CMOS) devices, comprising: a semiconductor layer, which is formed on a substrate; a plurality of insulation regions, which are formed on the semiconductor layer, for defining an ultra high threshold device region, a high threshold device region, a middle threshold device region and a low threshold device region, wherein a CMOS device having an ultra high threshold voltage is formed in the ultra high threshold device region, wherein a CMOS device having a high threshold voltage is formed in the high threshold device region, wherein a CMOS device having a middle threshold voltage is formed in the middle threshold device region, and wherein a CMOS device having a low threshold voltage is formed in the low threshold device region; a first low voltage P-type well and a second low voltage P-type well, which are formed in the semiconductor layer, for a first NMOS device in the ultra high threshold device region and for a third NMOS device in the middle threshold device region, respectively, by one same ion implantation process step; a first high voltage P-type well and a second high voltage P-type well, which are formed in the semiconductor layer, for a second NMOS device in the high threshold device region and for a fourth NMOS device in the low threshold device region, respectively, by one same ion implantation process step; a first low voltage N-type well and a second low voltage N-type well, which are formed in the semiconductor layer, for a first PMOS device in the ultra high threshold device region and for a third PMOS device in the middle threshold device region, respectively, by one same ion implantation process step; a first high voltage N-type well and a second high voltage N-type well, which are formed in the semiconductor layer, for a second PMOS device in the high threshold device region and for a fourth PMOS device in the low threshold device region, respectively, by one same ion implantation process step; a first gate, which is formed on the semiconductor layer of the first NMOS device in the ultra high threshold device region, wherein the first gate has a first P-type polysilicon layer and two first N-type polysilicon sub-layers, wherein the two first N-type polysilicon sub-layers are located beside and in contact with two sides of the first P-type polysilicon layer, respectively; a second gate, which is formed on the semiconductor layer of the first PMOS device in the ultra high threshold device region, wherein the second gate has a first N-type polysilicon layer and two first P-type polysilicon sub-layers, wherein the two first P-type polysilicon sub-layers are located beside and in contact with two sides of the first N-type polysilicon layer, respectively; a third gate, which is formed on the semiconductor layer of the second NMOS device in the high threshold device region, wherein the third gate has a second P-type polysilicon layer and two second N-type polysilicon sub-layers, wherein the two second N-type polysilicon sub-layers are located beside and in contact with two sides of the second P-type polysilicon layer, respectively; a fourth gate, which is formed on the semiconductor layer of the second PMOS device in the ultra high threshold device region, wherein the fourth gate has a second N-type polysilicon layer and two second P-type polysilicon sub-layers, wherein the two second P-type polysilicon sub-layers are located beside and in contact with two sides of the second N-type polysilicon layer, respectively; a fifth gate, which is formed on the semiconductor layer of the third NMOS device in the middle threshold device region, wherein the fifth gate has a third N-type polysilicon layer; a sixth gate, which is formed on the semiconductor layer of the third PMOS device in the middle threshold device region, wherein the sixth gate has a third P-type polysilicon layer; a seventh gate, which is formed on the semiconductor layer of the fourth NMOS device in the low threshold device region, wherein the seventh gate has a fourth N-type polysilicon layer; and an eighth gate, which is formed on the semiconductor layer of the fourth PMOS device in the low threshold device region, wherein the eighth gate has a fourth P-type polysilicon layer; wherein a threshold voltage of the first NMOS device is higher than a threshold voltage of the second NMOS device; the threshold voltage of the second NMOS device is higher than a threshold voltage of the third NMOS device; and the threshold voltage of the third NMOS device is higher than a threshold voltage of the fourth NMOS device; wherein an absolute value of a threshold voltage of the first PMOS device is higher than an absolute value of a threshold voltage of the second PMOS device; the absolute value of the threshold voltage of the second PMOS device is higher than an absolute value of a threshold voltage of the third PMOS device; and the absolute value of the threshold voltage of the third PMOS device is higher than an absolute value of a threshold voltage of the fourth PMOS device; wherein the CMOS device having an ultra high threshold voltage includes: the first NMOS device and the first PMOS device; the CMOS device having a high threshold voltage includes: the second NMOS device and the second PMOS device; the CMOS device having a middle threshold voltage includes: the third NMOS device and the third PMOS device; and the CMOS device having a low threshold voltage includes: the fourth NMOS device and the fourth PMOS device; wherein a P-type doped impurities concentration of the first low voltage P-type well and the second low voltage P-type well is higher than a P-type doped impurities concentration of the first high voltage P-type well and the second high voltage P-type well; wherein an N-type doped impurities concentration of the first low voltage N-type well and the second low voltage N-type well is higher than an N-type doped impurities concentration of the first high voltage N-type well and the second high voltage N-type well.

From another perspective, the present invention provides a manufacturing method of an integrated structure of complementary metal-oxide-semiconductor devices, comprising: forming a semiconductor layer on a substrate; forming a plurality of insulation regions on the semiconductor layer, for defining an ultra high threshold device region, a high threshold device region, a middle threshold device region and a low threshold device region, wherein a CMOS device having an ultra high threshold voltage is formed in the ultra high threshold device region, wherein a CMOS device having a high threshold voltage is formed in the high threshold device region, wherein a CMOS device having a middle threshold voltage is formed in the middle threshold device region, and wherein a CMOS device having a low threshold voltage is formed in the low threshold device region; forming a first low voltage P-type well and a second low voltage P-type well in the semiconductor layer, for a first NMOS device in the ultra high threshold device region and for a third NMOS device in the middle threshold device region, respectively, by one same ion implantation process step; forming a first high voltage P-type well and a second high voltage P-type well in the semiconductor layer, for a second NMOS device in the high threshold device region and for a fourth NMOS device in the low threshold device region, respectively, by one same ion implantation process step; forming a first low voltage N-type well and a second low voltage N-type well in the semiconductor layer, for a first PMOS device in the ultra high threshold device region and for a third PMOS device in the middle threshold device region, respectively, by one same ion implantation process step; forming a first high voltage N-type well and a second high voltage N-type well in the semiconductor layer, for a second PMOS device in the high threshold device region and for a fourth PMOS device in the low threshold device region, respectively, by one same ion implantation process step; forming a first gate on the semiconductor layer for the first NMOS device in the ultra high threshold device region, wherein the first gate has a first P-type polysilicon layer and two first N-type polysilicon sub-layers, wherein the two first N-type polysilicon sub-layers are located beside and in contact with two sides of the first P-type polysilicon layer, respectively; forming a second gate on the semiconductor layer for the first PMOS device in the ultra high threshold device region, wherein the second gate has a first N-type polysilicon layer and two first P-type polysilicon sub-layers, wherein the two first P-type polysilicon sub-layers are located beside and in contact with two sides of the first N-type polysilicon layer, respectively; forming a third gate on the semiconductor layer for the second NMOS device in the high threshold device region, wherein the third gate has a second P-type polysilicon layer and two second N-type polysilicon sub-layers, wherein the two second N-type polysilicon sub-layers are located beside and in contact with two sides of the second P-type polysilicon layer, respectively; forming a fourth gate on the semiconductor layer for the second PMOS device in the ultra high threshold device region, wherein the fourth gate has a second N-type polysilicon layer and two second P-type polysilicon sub-layers, wherein the two second P-type polysilicon sub-layers are located beside and in contact with two sides of the second N-type polysilicon layer, respectively; forming a fifth gate on the semiconductor layer for the third NMOS device in the middle threshold device region, wherein the fifth gate has a third N-type polysilicon layer; forming a sixth gate on the semiconductor layer for the third PMOS device in the middle threshold device region, wherein the sixth gate has a third P-type polysilicon layer; forming a seventh gate on the semiconductor layer for the fourth NMOS device in the low threshold device region, wherein the seventh gate has a fourth N-type polysilicon layer; and forming an eighth gate on the semiconductor layer for the fourth PMOS device in the low threshold device region, wherein the eighth gate has a fourth P-type polysilicon layer; wherein a threshold voltage of the first NMOS device is higher than a threshold voltage of the second NMOS device; the threshold voltage of the second NMOS device is higher than a threshold voltage of the third NMOS device; and the threshold voltage of the third NMOS device is higher than a threshold voltage of the fourth NMOS device; wherein an absolute value of a threshold voltage of the first PMOS device is higher than an absolute value of a threshold voltage of the second PMOS device; the absolute value of the threshold voltage of the second PMOS device is higher than an absolute value of a threshold voltage of the third PMOS device; and the absolute value of the threshold voltage of the third PMOS device is higher than an absolute value of a threshold voltage of the fourth PMOS device; wherein the CMOS device having an ultra high threshold voltage includes: the first NMOS device and the first PMOS device; the CMOS device having a high threshold voltage includes: the second NMOS device and the second PMOS device; the CMOS device having a middle threshold voltage includes: the third NMOS device and the third PMOS device; and the CMOS device having a low threshold voltage includes: the fourth NMOS device and the fourth PMOS device; wherein a P-type doped impurities concentration of the first low voltage P-type well and the second low voltage P-type well is higher than a P-type doped impurities concentration of the first high voltage P-type well and the second high voltage P-type well; wherein an N-type doped impurities concentration of the first low voltage N-type well and the second low voltage N-type well is higher than an N-type doped impurities concentration of the first high voltage N-type well and the second high voltage N-type well.

In one embodiment, the integrated structure of complementary metal-oxide-semiconductor devices further comprises: a first N-type buried layer, a second N-type buried layer, a third N-type buried layer, a fourth N-type buried layer, a fifth N-type buried layer, a sixth N-type buried layer, a seventh N-type buried layer and an eighth N-type buried layer, which are formed in the semiconductor layer and in the substrate which are below the first low voltage P-type well in the ultra high threshold device region, in the semiconductor layer and in the substrate which are below the first low voltage N-type well in the ultra high threshold device region, in the semiconductor layer and in the substrate which are below the first high voltage P-type well in the high threshold device region, in the semiconductor layer and in the substrate which are below the first high voltage N-type well in the high threshold device region, in the semiconductor layer and in the substrate which are below the second low voltage P-type well in the middle threshold device region, in the semiconductor layer and in the substrate which are below the second low voltage N-type well in the middle threshold device region, in the semiconductor layer and in the substrate which are below the second high voltage P-type well in the low threshold device region and in the semiconductor layer and in the substrate which are below the second high voltage N-type well in the low threshold device region, respectively, by one same process step; two third low voltage N-type wells and two third high voltage N-type wells, which are formed in the semiconductor layer in the ultra high threshold device region, wherein the two third low voltage N-type wells are located beside and in contact with two sides of the first low voltage P-type well, respectively, whereas, the two third high voltage N-type wells are located beside and in contact with two sides of the first low voltage P-type well, respectively, wherein lower boundaries the two third high voltage N-type wells are in contact with the first N-type buried layer, wherein the two third low voltage N-type wells, the two third high voltage N-type wells and the first N-type buried layer constitute a first isolation region, which serves to electrically isolate the first NMOS device in the semiconductor layer, wherein the two third low voltage N-type wells are formed by the same ion implantation process step that forms the first low voltage N-type well, whereas, the two third high voltage N-type wells are formed by the same ion implantation process step that forms the first high voltage N-type well; two third low voltage P-type wells and two third high voltage P-type wells, which are formed in the semiconductor layer in the ultra high threshold device region, wherein the two third low voltage P-type wells are located beside and in contact with two sides of the first low voltage N-type well, respectively, whereas, the two third high voltage P-type wells are located beside and in contact with two sides of the first low voltage N-type well, respectively, wherein lower boundaries the two third high voltage P-type wells are in contact with the second N-type buried layer, wherein the two third low voltage P-type wells, the two third high voltage P-type wells and the second N-type buried layer constitute a second isolation region, which serves to electrically isolate the first PMOS device in the semiconductor layer, wherein the two third low voltage P-type wells are formed by the same ion implantation process step that forms the first low voltage P-type well, whereas, the two third high voltage P-type wells are formed by the same ion implantation process step that forms the first high voltage P-type well; two fourth low voltage N-type wells and two fourth high voltage N-type wells, which are formed in the semiconductor layer in the high threshold device region, wherein the two fourth low voltage N-type wells are located beside and in contact with two sides of the first high voltage P-type well, respectively, whereas, the two fourth high voltage N-type wells are located beside and in contact with two sides of the first high voltage P-type well, respectively, wherein lower boundaries the two fourth high voltage N-type wells are in contact with the third N-type buried layer, wherein the two fourth low voltage N-type wells, the two fourth high voltage N-type wells and the third N-type buried layer constitute a third isolation region, which serves to electrically isolate the second NMOS device in the semiconductor layer, wherein the two fourth low voltage N-type wells are formed by the same ion implantation process step that forms the first low voltage N-type well, whereas, the two fourth high voltage N-type wells are formed by the same ion implantation process step that forms the first high voltage N-type well; two fourth low voltage P-type wells and two fourth high voltage P-type wells, which are formed in the semiconductor layer in the high threshold device region, wherein the two fourth low voltage P-type wells are located beside and in contact with two sides of the first high voltage N-type well, respectively, whereas, the two fourth high voltage P-type wells are located beside and in contact with two sides of the first high voltage N-type well, respectively, wherein lower boundaries the two fourth high voltage P-type wells are in contact with the fourth N-type buried layer, wherein the two fourth low voltage P-type wells, the two fourth high voltage P-type wells and the fourth N-type buried layer constitute a fourth isolation region, which serves to electrically isolate the second PMOS device in the semiconductor layer, wherein the two fourth low voltage P-type wells are formed by the same ion implantation process step that forms the first low voltage P-type well, whereas, the two fourth high voltage P-type wells are formed by the same ion implantation process step that forms the first high voltage P-type well; two fifth low voltage N-type wells and two fifth high voltage N-type wells, which are formed in the semiconductor layer in the middle threshold device region, wherein the two fifth low voltage N-type wells are located beside and in contact with two sides of the second low voltage P-type well, respectively, whereas, the two fifth high voltage N-type wells are located beside and in contact with two sides of the second low voltage P-type well, respectively, wherein lower boundaries the two fifth high voltage N-type wells are in contact with the fifth N-type buried layer, wherein the two fifth low voltage N-type wells, the two fifth high voltage N-type wells and the fifth N-type buried layer constitute a fifth isolation region, which serves to electrically isolate the third NMOS device in the semiconductor layer, wherein the two fifth low voltage N-type wells are formed by the same ion implantation process step that forms the first low voltage N-type well, whereas, the two fifth high voltage N-type wells are formed by the same ion implantation process step that forms the first high voltage N-type well; two fifth low voltage P-type wells and two fifth high voltage P-type wells, which are formed in the semiconductor layer in the middle threshold device region, wherein the two fifth low voltage P-type wells are located beside and in contact with two sides of the second low voltage N-type well, respectively, whereas, the two fifth high voltage P-type wells are located beside and in contact with two sides of the second low voltage N-type well, respectively, wherein lower boundaries the two fifth high voltage P-type wells are in contact with the sixth N-type buried layer, wherein the two fifth low voltage P-type wells, the two fifth high voltage P-type wells and the sixth N-type buried layer constitute a sixth isolation region, which serves to electrically isolate the third NMOS device in the semiconductor layer, wherein the two fifth low voltage P-type wells are formed by the same ion implantation process step that forms the first low voltage P-type well, whereas, the two fifth high voltage P-type wells are formed by the same ion implantation process step that forms the first high voltage P-type well; two sixth low voltage N-type wells and two sixth high voltage N-type wells, which are formed in the semiconductor layer in the low threshold device region, wherein the two sixth low voltage N-type wells are located beside and in contact with two sides of the fourth high voltage P-type well, respectively, whereas, the two sixth high voltage N-type wells are located beside and in contact with two sides of the fourth high voltage P-type well, respectively, wherein lower boundaries the two sixth high voltage N-type wells are in contact with the seventh N-type buried layer, wherein the two sixth low voltage N-type wells, the two sixth high voltage N-type wells and the seventh N-type buried layer constitute a seventh isolation region, which serves to electrically isolate the fourth NMOS device in the semiconductor layer, wherein the two sixth low voltage N-type wells are formed by the same ion implantation process step that forms the first low voltage N-type well, whereas, the two sixth high voltage N-type wells are formed by the same ion implantation process step that forms the first high voltage N-type well; two sixth high voltage N-type wells and two sixth high voltage P-type wells, which are formed in the semiconductor layer in the low threshold device region, wherein the two sixth high voltage N-type wells are located beside and in contact with two sides of the fourth high voltage N-type well, respectively, whereas, the two sixth high voltage P-type wells are located beside and in contact with two sides of the fourth high voltage N-type well, respectively, wherein lower boundaries the two sixth high voltage P-type wells are in contact with the eighth N-type buried layer, wherein the two sixth high voltage N-type wells, the two sixth high voltage P-type wells and the eighth N-type buried layer constitute an eighth isolation region, which serves to electrically isolate the fourth PMOS device in the semiconductor layer, wherein the two sixth high voltage N-type wells are formed by the same ion implantation process step that forms the first low voltage P-type well, whereas, the two sixth high voltage P-type wells are formed by the same ion implantation process step that forms the first high voltage P-type well.

In one embodiment, the integrated structure of complementary metal-oxide-semiconductor devices further comprises: a first N-type source and a first N-type drain, which are formed, by one same ion implantation process step, in the semiconductor layer of the ultra high threshold device region, wherein the first N-type source and the first N-type drain are located below and outside two sides of the first gate, respectively, wherein a side of the first gate which is closer to the first N-type source is a source side and a side of the first gate which is closer to the first N-type drain is a drain side, and wherein the first N-type source and the first N-type drain are located in the first low voltage P-type well at the source side and the drain side, respectively; a first P-type source and a first P-type drain, which are formed, by one same ion implantation process step, in the semiconductor layer of the ultra high threshold device region, wherein the first P-type source and the first P-type drain are located below and outside two sides of the second gate, respectively, wherein a side of the second gate which is closer to the first P-type source is a source side and a side of the second gate which is closer to the first P-type drain is a drain side, and wherein the first P-type source and the first P-type drain are located in the first low voltage N-type well at the source side and the drain side, respectively; a second N-type source and a second N-type drain, which are formed in the semiconductor layer of the high threshold device region by the one same ion implantation process step that forms the first N-type source and the first N-type drain, wherein the second N-type source and the second N-type drain are located below and outside two sides of the third gate, respectively, wherein a side of the third gate which is closer to the second N-type source is a source side and a side of the third gate which is closer to the second N-type drain is a drain side, and wherein the second N-type source and the second N-type drain are located in the first high voltage P-type well at the source side and the drain side, respectively; a second P-type source and a second P-type drain, which are formed in the semiconductor layer of the high threshold device region by the one same ion implantation process step that forms the first P-type source and the first P-type drain, wherein the second P-type source and the second P-type drain are located below and outside two sides of the fourth gate, respectively, wherein a side of the fourth gate which is closer to the second P-type source is a source side and a side of the fourth gate which is closer to the second P-type drain is a drain side, and wherein the second P-type source and the second P-type drain are located in the first high voltage N-type well at the source side and the drain side, respectively; a third N-type source and a third N-type drain, which are formed in the semiconductor layer of the middle threshold device region by the one same ion implantation process step that forms the first N-type source and the first N-type drain, wherein the third N-type source and the third N-type drain are located below and outside two sides of the fifth gate, respectively, wherein a side of the fifth gate which is closer to the third N-type source is a source side and a side of the fifth gate which is closer to the third N-type drain is a drain side, and wherein the third N-type source and the third N-type drain are located in the second low voltage P-type well at the source side and the drain side, respectively; a third P-type source and a third P-type drain, which are formed in the semiconductor layer of the middle threshold device region by the one same ion implantation process step that forms the first P-type source and the first P-type drain, wherein the third P-type source and the third P-type drain are located below and outside two sides of the sixth gate, respectively, wherein a side of the sixth gate which is closer to the third P-type source is a source side and a side of the sixth gate which is closer to the third P-type drain is a drain side, and wherein the third P-type source and the third P-type drain are located in the second low voltage N-type well at the source side and the drain side, respectively; a fourth N-type source and a fourth N-type drain, which are formed in the semiconductor layer of the low threshold device region by the one same ion implantation process step that forms the first N-type source and the first N-type drain, wherein the fourth N-type source and the fourth N-type drain are located below and outside two sides of the seventh gate, respectively, wherein a side of the seventh gate which is closer to the fourth N-type source is a source side and a side of the seventh gate which is closer to the fourth N-type drain is a drain side, and wherein the fourth N-type source and the fourth N-type drain are located in the second high voltage P-type well at the source side and the drain side, respectively; and a fourth P-type source and a fourth P-type drain, which are formed in the semiconductor layer of the low threshold device region by the one same ion implantation process step that forms the first P-type source and the first P-type drain, wherein the fourth P-type source and the fourth P-type drain are located below and outside two sides of the eighth gate, respectively, wherein a side of the eighth gate which is closer to the fourth P-type source is a source side and a side of the eighth gate which is closer to the fourth P-type drain is a drain side, and wherein the fourth P-type source and the fourth P-type drain are located in the second high voltage N-type well at the source side and the drain side, respectively.

In one embodiment, the integrated structure of complementary metal-oxide-semiconductor devices further comprises: a first P-type conductive region, which is formed in the first low voltage P-type well in the ultra high threshold device region, wherein the first P-type conductive region serves as an electrical contact of the first low voltage P-type well; a first N-type conductive region, which is formed in the first low voltage N-type well in the ultra high threshold device region, wherein the first N-type conductive region serves as an electrical contact of the first low voltage N-type well; a second P-type conductive region, which is formed in the first high voltage P-type well in the high threshold device region by the same ion implantation process step that forms the first P-type conductive region, wherein the second P-type conductive region serves as an electrical contact of the first high voltage P-type well; a second N-type conductive region, which is formed in the first high voltage N-type well in the high threshold device region by the same ion implantation process step that forms the first N-type conductive region, wherein the second N-type conductive region serves as an electrical contact of the first high voltage N-type well; a third P-type conductive region, which is formed in the second low voltage P-type well in the middle threshold device region by the same ion implantation process step that forms the first P-type conductive region, wherein the third P-type conductive region serves as an electrical contact of the second low voltage P-type well; a third N-type conductive region, which is formed in the second low voltage N-type well in the middle threshold device region by the same ion implantation process step that forms the first P-type conductive region, wherein the third N-type conductive region serves as an electrical contact of the second low voltage N-type well; a fourth P-type conductive region, which is formed in the second high voltage P-type well in the low threshold device region by the same ion implantation process step that forms the first P-type conductive region, wherein the fourth P-type conductive region serves as an electrical contact of the second high voltage P-type well; and a fourth N-type conductive region, which is formed in the second high voltage N-type well in the low threshold device region by the same ion implantation process step that forms the first P-type conductive region, wherein the fourth N-type conductive region serves as an electrical contact of the second high voltage N-type well.

In one embodiment, the integrated structure of complementary metal-oxide-semiconductor devices further comprises: a first high voltage P-type isolation region, which is formed in the semiconductor layer by the same ion implantation process step that forms the first high voltage P-type well; a first high voltage N-type isolation region, which is formed in the semiconductor layer by the same ion implantation process step that forms the first high voltage N-type well; a second high voltage P-type isolation region, which is formed in the semiconductor layer by the same ion implantation process step that forms the first high voltage P-type well; a second high voltage N-type isolation region, which is formed in the semiconductor layer by the same ion implantation process step that forms the second high voltage N-type well; wherein the first high voltage P-type isolation region is below and in contact with the first low voltage P-type well; wherein the first high voltage N-type isolation region is below and in contact with the first low voltage N-type well; wherein the second high voltage P-type isolation region is below and in contact with the second low voltage P-type well; wherein the second high voltage N-type isolation region is below and in contact with the second low voltage N-type well.

In one embodiment, the semiconductor layer is a P-type semiconductor epitaxial layer having a volume resistivity which is 45 Ohm-cm.

In one embodiment, each of the dielectric layer of the first gate, the dielectric layer of the second gate, the dielectric layer of the third gate, the dielectric layer of the fourth gate, the dielectric layer of the fifth gate, the dielectric layer of the sixth gate, the dielectric layer of the seventh gate and the dielectric layer of the eighth gate has a thickness ranging between 80 Å to 100 Å.

In one embodiment, the integrated structure of complementary metal-oxide-semiconductor devices has a minimum feature size which is 0.18 micrometer.

The present invention has such advantage that the present invention can form different CMOS devices having different threshold voltages at the same time by one integration process which adopts process steps that already exist.

The objectives, technical details, features, and effects of the present invention will be better understood with regard to the detailed description of the embodiments below, with reference to the attached drawings.

### BRIEF DESCRIPTION OF THE DRAWINGS

FIG. 1A and FIG. 1B in combination show a cross-section view of an integrated structure of complementary metal-oxide-semiconductor devices according to an embodiment of the present invention.

FIG. 2A and FIG. 2B in combination show a cross-section view of an integrated structure of complementary metal-oxide-semiconductor devices according to an embodiment of the present invention.

FIG. 3A to FIG. 3U show cross-section views of a manufacturing method of an integrated structure of complementary metal-oxide-semiconductor devices according to an embodiment of the present invention.

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

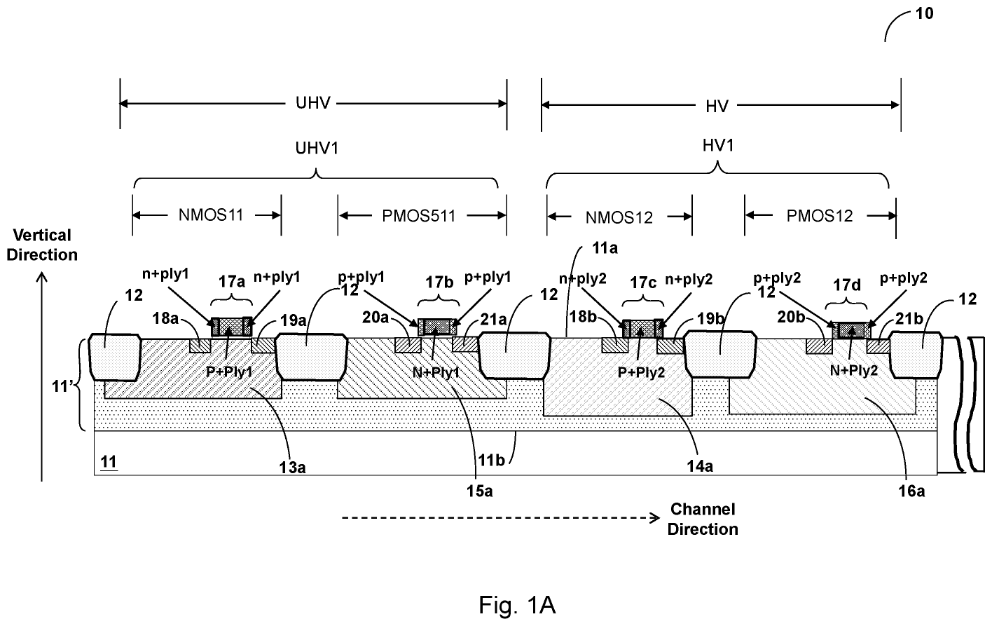

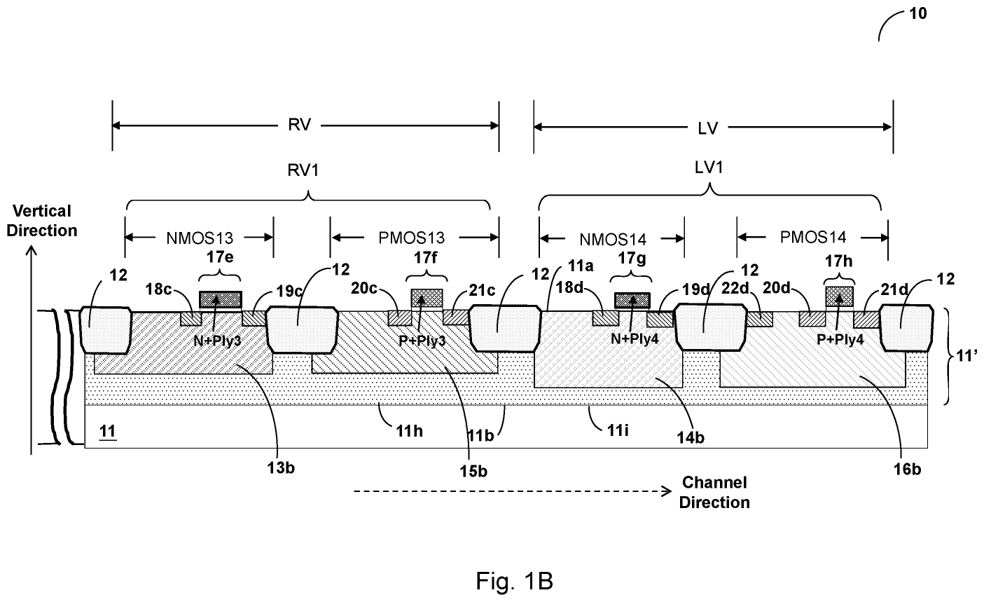

Please refer to FIG. 1A and FIG. 1B, which in combination show a cross-section view of an integrated structure 10 of complementary metal-oxide-semiconductor (CMOS) devices according to an embodiment of the present invention. For the sake of clarity, the integrated structure 10 of CMOS devices is shown by two figures in two pages (i.e., FIG. 1A and FIG. 1B are two parts of the integrated structure 10 of CMOS devices, which in combination show the complete structure), so that the structure is shown by a larger view. As shown in FIG. 1A and FIG. 1B, the integrated structure 10 of CMOS devices comprises: a semiconductor layer 11, insulation regions 12, a first low voltage P-type well 13a, a second low voltage P-type well 13b, a first high voltage P-type well 14a, a second high voltage P-type well 14b, a first low voltage N-type well 15a, a second low voltage N-type well 15b, a first high voltage N-type well 16a, a second high voltage N-type well 16b, a first gate 17a, a second gate 17b, a third gate 17c, a fourth gate 17d, a fifth gate 17e, a sixth gate 17f, a seventh gate 17g, an eighth gate 17h, a first N-type source 18a, a first N-type drain 19a, a first P-type source 20a, a first P-type drain 21a, a second N-type source 18b, a second N-type drain 19b, a second P-type source 20b, a second P-type drain 21b, a third N-type source 18c, a third N-type drain 19c, a third P-type source 20c, a third P-type drain 21c, a fourth N-type source 18d, a fourth N-type drain 19d, a fourth P-type source 20d and a fourth P-type drain 21d.

The semiconductor layer 11′ is formed on the substrate 11. The semiconductor layer 11′ has a top surface 11a and a bottom surface 11b opposite to the top surface 11a in a vertical direction (as indicated by the direction of the solid arrow in FIG. 1A and FIG. 1B, and all occurrences of the term “vertical direction” in this specification refer to the same direction hereinafter). The substrate 11 can be for example a P-type or an N-type semiconductor substrate. The semiconductor layer 11′, for example, is formed on the substrate 11 by an epitaxial process step, or is a part of the substrate 11. The semiconductor layer 11′ can be formed by various methods known to a person having ordinary skill in the art, so the details thereof are not redundantly explained here.

Please still refer to FIG. 1A and FIG. 1B. The insulation regions are formed on the semiconductor layer 11′, for defining an ultra high threshold device region UHV, a high threshold device region HV, a middle threshold device region RV and a low threshold device region LV. A CMOS device UHV1 having an ultra high threshold voltage is formed in the ultra high threshold device region UHV; a CMOS device HV1 having a high threshold voltage is formed in the high threshold device region HV; a CMOS device RV1 having a middle threshold voltage is formed in the middle threshold device region RV; and a CMOS device LV1 having a low threshold voltage is formed in the low threshold device region LV. The insulation regions 12 can be, for example but not limited to, a shallow trench isolation (STI) structure as shown in FIG. 1A and FIG. 1B.

The CMOS device UHV1 having an ultra high threshold voltage includes a first NMOS device NMOS11 and a first PMOS device PMOS11; the CMOS device HV1 having a high threshold voltage includes a second NMOS device NMOS12 and a second PMOS device PMOS12; the CMOS device RV1 having a middle threshold voltage includes a third NMOS device NMOS13 and a third PMOS device PMOS13; and the CMOS device LV1 having a low threshold voltage includes a fourth NMOS device NMOS14 and a fourth PMOS device PMOS14. The threshold voltage of the first NMOS device NMOS11 is higher than the threshold voltage of the second NMOS device NMOS12; the threshold voltage of the second NMOS device NMOS12 is higher than the threshold voltage of the third NMOS device NMOS13; and the threshold voltage of the third NMOS device NMOS13 is higher than the threshold voltage of the fourth NMOS device NMOS14. The absolute value of the threshold voltage of the first PMOS device PMOS11 is higher than the absolute value of the threshold voltage of the second PMOS device PMOS12; the absolute value of the threshold voltage of the second PMOS device PMOS12 is higher than the absolute value of the threshold voltage of the third PMOS device PMOS13; and the absolute value of the threshold voltage of the third PMOS device PMOS13 is higher than the absolute value of the threshold voltage of the fourth PMOS device PMOS14. Note that the terms “ultra high threshold”, “high threshold”, “middle threshold”, and “low threshold” refer to relative relationships among these threshold voltages.

In this embodiment, in the CMOS device UHV1 having an ultra high threshold voltage, the first NMOS device NMOS11 includes: the first low voltage P-type well 13a, the first gate 17a, the first N-type source 18a and the first N-type drain 19a, whereas, the first PMOS device PMOS11 includes: the first low voltage N-type well 15a, the second gate 17b, the first P-type source 20a and the first P-type drain 21a. In the CMOS device HV1 having a high threshold voltage, the second NMOS device NMOS12 includes: the first high voltage P-type well 14a, the third gate 17c, the second N-type source 18b and the second N-type drain 19b, whereas, the second PMOS device PMOS12 includes: the first high voltage N-type well 16a, the fourth gate 17d, the second P-type source 20b and the second P-type drain 21b. In the CMOS device RV1 having a middle threshold voltage, the third NMOS device NMOS13 includes: the second low voltage P-type well 13b, the fifth gate 17e, the third N-type source 18c and the third N-type drain 19c, whereas, the third PMOS device PMOS13 includes: the second low voltage N-type well 15b, the sixth gate 17f, the third P-type source 20c and the third P-type drain 21c. In the CMOS device LV1 having a low threshold voltage, the fourth NMOS device NMOS14 includes: the second high voltage P-type well 14b, the seventh gate 17g, the fourth N-type source 18d and the fourth N-type drain 19d, whereas, the fourth PMOS device PMOS14 includes: the second high voltage N-type well 16b, the eighth gate 17h, the fourth P-type source 20d and the fourth P-type drain 21d.

Please still refer to FIG. 1A and FIG. 1B. The first low voltage P-type well 13a and the second low voltage P-type well 13b are formed in the semiconductor layer 11′ in the ultra high threshold device region UHV and the semiconductor layer 11′ in the middle threshold device region RV, respectively, by one same ion implantation process step. The first low voltage P-type well 13a and the second low voltage P-type well 13b are below and in contact with the top surface 11a. Apart of the first low voltage P-type well 13a is located vertically below and in contact with the first gate 17a, which serves as an inversion current channel in an ON operation of the first NMOS device NMOS11. Besides, a part of the second low voltage P-type well 13b is located vertically below and in contact with the fifth gate 17e, which serves as an inversion current channel in an ON operation of the third NMOS device NMOS13.

Please still refer to FIG. 1A and FIG. 1B. The first low voltage N-type well 15a and the second low voltage N-type well 15b are formed in the semiconductor layer 11′ in the ultra high threshold device region UHV and the semiconductor layer 11′ in the middle threshold device region RV, respectively, by one same ion implantation process step. The first low voltage N-type well 15a and the second low voltage N-type well 15b are below and in contact with the top surface 11a. Apart of the first low voltage N-type well 15a is located vertically below and in contact with the second gate 17b, which serves as an inversion current channel in an ON operation of the first PMOS device PMOS11. Besides, a part of the second low voltage N-type well 15b is located vertically below and in contact with the sixth gate 17f, which serves as an inversion current channel in an ON operation of the third PMOS device PMOS13.

Please still refer to FIG. 1A and FIG. 1B. The first high voltage P-type well 14a and the second high voltage P-type well 14b are formed in the semiconductor layer 11′ in the high threshold device region HV and the semiconductor layer 11′ in the low threshold device region LV, respectively, by one same ion implantation process step. The first high voltage P-type well 14a and the second high voltage P-type well 14b are below and in contact with the top surface 11a. A part of the first high voltage P-type well 14a is located vertically below and in contact with the third gate 17c, which serves as an inversion current channel in an ON operation of the second NMOS device NMOS12. Besides, a part of the second high voltage P-type well 14b is located vertically below and in contact with the seventh gate 17g, which serves as an inversion current channel in an ON operation of the fourth NMOS device NMOS14.

Please still refer to FIG. 1A and FIG. 1B. The first high voltage N-type well 16a and the second high voltage N-type well 16b are formed in the semiconductor layer 11′ in the high threshold device region HV and the semiconductor layer 11′ in the low threshold device region LV, respectively, by one same ion implantation process step. The first high voltage N-type well 16a and the second high voltage N-type well 16b are below and in contact with the top surface 11a. A part of the first high voltage N-type well 16a is located vertically below and in contact with the fourth gate 17d, which serves as an inversion current channel in an ON operation of the second PMOS device PMOS12. Besides, a part of the second high voltage N-type well 16b is located vertically below and in contact with the eighth gate 17h, which serves as an inversion current channel in an ON operation of the fourth PMOS device PMOS14.

The first gate 17a is formed on the top surface 11a of the semiconductor layer 11′ in the ultra high threshold device region UHV. The first gate 17a has a first P-type polysilicon layer P+Ply1 and two first N-type polysilicon sub-layers n+ply1 and n+ply1, wherein the two first N-type polysilicon sub-layers n+ply1 and n+ply1 are located beside and in contact with two sides of the first P-type polysilicon layer P+Ply1, respectively. The first gate 17a includes: a conductive layer, a spacer layer and a dielectric layer, wherein the dielectric layer is located on and in contact with the top surface 11a, wherein the conductive layer includes the aforementioned first P-type polysilicon layer P+Ply1 and two first N-type polysilicon sub-layers n+ply1 and n+ply1, and wherein the spacer layer (not shown for simplicity of the drawing) overlays two sides of the conductive layer, which are known to a person having ordinary skill in the art, so the details thereof are not redundantly explained here.

The second gate 17b is formed on the top surface 11a of the semiconductor layer 11′ in the ultra high threshold device region UHV. The second gate 17b has a first N-type polysilicon layer N+Ply1 and two first P-type polysilicon sub-layers p+Ply1 and p+Ply1, wherein the two first P-type polysilicon sub-layers p+Ply1 and p+Ply1 are located beside and in contact with two sides of the first N-type polysilicon layer N+Ply1, respectively. The second gate 17b includes: a conductive layer, a spacer layer and a dielectric layer, wherein the dielectric layer is located on and in contact with the top surface 11a, wherein the conductive layer includes the aforementioned first N-type polysilicon layer N+Ply1 and two first P-type polysilicon sub-layers p+Ply1 and p+Ply, and wherein the spacer layer (not shown for simplicity of the drawing) overlays two sides of the conductive layer, which are known to a person having ordinary skill in the art, so the details thereof are not redundantly explained here.

The third gate 17c is formed on the top surface 11a of the semiconductor layer 11′ in the high threshold device region HV. The third gate 17c has a second P-type polysilicon layer P+Ply2 and two second N-type polysilicon sub-layers n+ply2 and n+ply2, wherein the two second N-type polysilicon sub-layers n+ply2 and n+ply2 are located beside and in contact with two sides of the second P-type polysilicon layer P+Ply2, respectively. The third gate 17c includes: a conductive layer, a spacer layer and a dielectric layer, wherein the dielectric layer is located on and in contact with the top surface 11a, wherein the conductive layer includes the aforementioned second P-type polysilicon layer P+Ply2 and two second N-type polysilicon sub-layers n+ply2 and n+ply2, and wherein the spacer layer (not shown for simplicity of the drawing) overlays two sides of the conductive layer, which are known to a person having ordinary skill in the art, so the details thereof are not redundantly explained here.

The fourth gate 17d is formed on the top surface 11a of the semiconductor layer 11′ in the high threshold device region HV. The fourth gate 17d has a second N-type polysilicon layer N+Ply2 and two second P-type polysilicon sub-layers p+ply2 and p+ply2, wherein the two second P-type polysilicon sub-layers p+ply2 and p+ply2 are located beside and in contact with two sides of the second N-type polysilicon layer N+Ply2, respectively. The fourth gate 17d includes: a conductive layer, a spacer layer and a dielectric layer, wherein the dielectric layer is located on and in contact with the top surface 11a, wherein the conductive layer includes the aforementioned second N-type polysilicon layer N+Ply2 and two second P-type polysilicon sub-layers p+ply2 and p+ply2, and wherein the spacer layer (not shown for simplicity of the drawing) overlays two sides of the conductive layer, which are known to a person having ordinary skill in the art, so the details thereof are not redundantly explained here.

The fifth gate 17e is formed on the top surface 11a of the semiconductor layer 11′ in the middle threshold device region RV. the fifth gate has a third N-type polysilicon layer N+Ply3. The fifth gate 17e includes: a conductive layer, a spacer layer and a dielectric layer, wherein the dielectric layer is located on and in contact with the top surface 11a, wherein the conductive layer includes the aforementioned third N-type polysilicon layer N+Ply3, and wherein the spacer layer (not shown for simplicity of the drawing) overlays two sides of the conductive layer, which are known to a person having ordinary skill in the art, so the details thereof are not redundantly explained here.

The sixth gate 17f is formed on the top surface 11a of the semiconductor layer 11′ in the middle threshold device region RV. The sixth gate 17f has a third P-type polysilicon layer P+Ply3. The sixth gate 17f includes: a conductive layer, a spacer layer and a dielectric layer, wherein the dielectric layer is located on and in contact with the top surface 11a, wherein the conductive layer includes the aforementioned third P-type polysilicon layer P+Ply3, and wherein the spacer layer (not shown for simplicity of the drawing) overlays two sides of the conductive layer, which are known to a person having ordinary skill in the art, so the details thereof are not redundantly explained here.

The seventh gate 17g is formed on the top surface 11a of the semiconductor layer 11′ in the low threshold device region LV. The seventh gate 17g has a fourth N-type polysilicon layer N+Ply4. The seventh gate 17g includes: a conductive layer, a spacer layer and a dielectric layer, wherein the dielectric layer is located on and in contact with the top surface 11a, wherein the conductive layer includes the aforementioned fourth N-type polysilicon layer N+Ply4, and wherein the spacer layer (not shown for simplicity of the drawing) overlays two sides of the conductive layer, which are known to a person having ordinary skill in the art, so the details thereof are not redundantly explained here.

The eighth gate 17h is formed on the top surface 11a of the semiconductor layer 11′ in the low threshold device region LV. The eighth gate 17h has a fourth P-type polysilicon layer P+Ply4. The eighth gate 17h includes: a conductive layer, a spacer layer and a dielectric layer, wherein the dielectric layer is located on and in contact with the top surface 11a, wherein the conductive layer includes the aforementioned fourth P-type polysilicon layer P+Ply4, and wherein the spacer layer (not shown for simplicity of the drawing) overlays two sides of the conductive layer, which are known to a person having ordinary skill in the art, so the details thereof are not redundantly explained here.

The first N-type source 18a and the first N-type drain 19a are formed, by one same ion implantation process step, in the semiconductor layer 11′ of the ultra high threshold device region UHV, wherein the first N-type source 18a and the first N-type drain 19a are located below and outside two sides of the first gate 17a in a channel direction (as indicated by the direction of the dashed arrow shown in FIG. 1A and FIG. 1B, and all occurrences of the term “channel direction” in this specification refer to the same direction hereinafter), respectively, wherein the side of the first gate 17a which is closer to the first N-type source 18a is a source side and the side of the first gate 17a which is closer to the first N-type drain 19a is a drain side, and wherein the first N-type source 18a is located in the first low voltage P-type well 13a, and the first N-type drain 19a is located in the first low voltage P-type well 13a. In the vertical direction, the first N-type source 18a and the first N-type drain 19a are formed on and in contact with the top surface 11a.

The first P-type source 20a and the first P-type drain 21a are formed, by one same ion implantation process step, in the semiconductor layer 11′ of the ultra high threshold device region UHV, wherein the first P-type source 20a and the first P-type drain 21a are located below and outside two sides of the second gate 17b in the channel direction, respectively, wherein the side of the second gate 17b which is closer to the first P-type source 20a is a source side and the side of the second gate 17b which is closer to the first P-type drain 21a is a drain side, and wherein the first P-type source 20a and the first P-type drain 21a are located in the first low voltage N-type well 15a at the source side and the drain side, respectively. In the vertical direction, the first P-type source 20a and the first P-type drain 21a are formed on and in contact with the top surface 11a.

The second N-type source 18b and the second N-type drain 19b are formed in the semiconductor layer 11′ of the high threshold device region HV by the one same ion implantation process step that forms the first N-type source 18a and the first N-type drain 19b, wherein the second N-type source 18b and the second N-type drain 19b are located below and outside two sides of the third gate 17c in the channel direction, respectively, wherein the side of the third gate 17c which is closer to the second N-type source 18b is a source side and the side of the third gate 17c which is closer to the second N-type drain 19b is a drain side, and wherein the second N-type source 18b and the second N-type drain 19b are located in the first high voltage P-type well 14a at the source side and the drain side, respectively. In the vertical direction, the second N-type source 18b and the second N-type drain 19b are formed on and in contact with the top surface 11a.

The second P-type source 20b and the second P-type drain 21b are formed in the semiconductor layer 11′ of the high threshold device region HV by the one same ion implantation process step that forms the first P-type source 20a and the first P-type drain 21a, wherein the second P-type source 20b and the second P-type drain 21b are located below and outside two sides of the fourth gate 17d in the channel direction, respectively, wherein the side of the fourth gate 17d which is closer to the second P-type source 20b is a source side and the side of the fourth gate 17d which is closer to the second P-type drain 21b is a drain side, and wherein the second P-type source 20b and the second P-type drain 21b are located in the first high voltage N-type well 16a at the source side and the drain side, respectively. In the vertical direction, the second P-type source 20b and the second P-type drain 21b are formed on and in contact with the top surface 11a.

The third N-type source 18c and the third N-type drain 19c are formed in the semiconductor layer 11′ of the middle threshold device region RV by the one same ion implantation process step that forms the first N-type source 18a and the first N-type drain 19a, wherein the third N-type source 18c and the third N-type drain 19c are located below and outside two sides of the fifth gate 17e in the channel direction, respectively, wherein the side of the fifth gate 17e which is closer to the third N-type source 18c is a source side and the side of the fifth gate 17e which is closer to the third N-type drain 19c is a drain side, and wherein the third N-type source 18c and the third N-type drain 19c are located in the second low voltage P-type well 13b at the source side and the drain side, respectively. In the vertical direction, the third N-type source 18c and the third N-type drain 19c are formed on and in contact with the top surface 11a.

The third P-type source 20c and the third P-type drain 21c are formed in the semiconductor layer 11′ of the middle threshold device region RV by the one same ion implantation process step that forms the first P-type source 20a and the first P-type drain 21a, wherein the third P-type source 20c and the third P-type drain 21c are located below and outside two sides of the sixth gate 17f in the channel direction, respectively, wherein the side of the sixth gate 17f which is closer to the third P-type source 20c is a source side and the side of the sixth gate 17f which is closer to the third P-type drain 21c is a drain side, and wherein the third P-type source 20c and the third P-type drain 21c are located in the second low voltage N-type well 15b at the source side and the drain side, respectively. In the vertical direction, the third P-type source 20c and the third P-type drain 21c are formed on and in contact with the top surface 11a.

The fourth N-type source 18d and the fourth N-type drain 19d are formed in the semiconductor layer 11′ of the low threshold device region LV by the one same ion implantation process step that forms the first N-type source 18a and the first N-type drain 19a, wherein the fourth N-type source 18d and the fourth N-type drain 19d are located below and outside two sides of the seventh gate 17g in the channel direction, respectively, wherein the side of the seventh gate 17g which is closer to the fourth N-type source 18d is a source side and the side of the seventh gate 17g which is closer to the fourth N-type drain 19d is a drain side, and wherein the fourth N-type source 18d, and the fourth N-type drain 19d are located in the second high voltage P-type well 14b at the source side and the drain side, respectively. In the vertical direction, the fourth N-type source 18d and the fourth N-type drain 19d are formed on and in contact with the top surface 11a.

The fourth P-type source 20d and the fourth P-type drain 21d, which are formed in the semiconductor layer 11′ of the low threshold device region LV by the one same ion implantation process step that forms the first P-type source 20a and the first P-type drain 21a, wherein the fourth P-type source 20d and the fourth P-type drain 21d are located below and outside two sides of the eighth gate 17h in the channel direction, respectively, wherein the side of the eighth gate 17h which is closer to the fourth P-type source 20d is a source side and the side of the eighth gate 17h which is closer to the fourth P-type drain 21d is a drain side, and wherein the fourth P-type source 20d and the fourth P-type drain 21d are located in the second high voltage N-type well 16b at the source side and the drain side, respectively.

It is worthwhile noting that, in this embodiment, because the P-type doped impurities concentration of the first low voltage P-type well 13a and the second low voltage P-type well 13b is higher than the P-type doped impurities concentration of the first high voltage P-type well 14a and the second high voltage P-type well 14b, the inverse channel region (i.e., a part of the first high voltage P-type well 14a which is vertically below the gate) of the first NMOS device NMOS11 and the inverse channel region (i.e., a part of the second high voltage P-type well 14b which is vertically below the gate) of the third NMOS device NMOS13 have a relatively higher P-type doped impurities concentration, as compared to the inverse channel region of the second NMOS device NMOS12 and the inverse channel region of the fourth NMOS device NMOS14. As a result, the first NMOS device NMOS11 and the third NMOS device NMOS13 have a relatively higher threshold voltage. Besides, because the N-type doped impurities concentration of the first low voltage N-type well 15a and the second low voltage N-type well 15b is higher than the N-type doped impurities concentration of the first high voltage N-type well 16a and the second high voltage N-type well 16b, the inverse channel region (i.e., a part of the first high voltage N-type well 16a which is vertically below the gate) of the first PMOS device PMOS11 and the inverse channel region (i.e., a part of the second high voltage N-type well 16b which is vertically below the gate) of the third PMOS device PMOS13 have a relatively higher N-type doped impurities concentration, as compared to the inverse channel region of the second PMOS device PMOS12 and the inverse channel region of the fourth PMOS device PMOS14. As a result, the first PMOS device PMOS11 and the third PMOS device PMOS13 have a relatively higher absolute value of the threshold voltage.

In addition, the NMOS device which adopts a P-type polysilicon layer to form the conductive layer of the gate has a relatively higher threshold voltage, as compared to the NMOS device which adopts an N-type polysilicon layer to form the conductive layer of the gate. The PMOS device which adopts an N-type polysilicon layer to form the conductive layer of the gate has a relatively higher absolute value of the threshold voltage, as compared to the PMOS device which adopts a P-type polysilicon layer to form the conductive layer of the gate. Consequently, in light of the above, the threshold voltage of the first NMOS device NMOS11 is higher than the threshold voltage of the second NMOS device NMOS12, the threshold voltage of the second NMOS device NMOS12 is higher than the threshold voltage of the third NMOS device NMOS13, and the threshold voltage of the third NMOS device NMOS13 is higher than the threshold voltage of the fourth NMOS device NMOS14.

In one embodiment, the semiconductor layer 11′ is a P-type semiconductor epitaxial layer having a volume resistivity which is 45 Ohm-cm.

In one embodiment, each of the dielectric layer of the first gate 17a, the dielectric layer of the second gate 17b, the dielectric layer of the third gate 17c, the dielectric layer of the fourth gate 17d, the dielectric layer of the fifth gate 17e, the dielectric layer of the sixth gate 17f, the dielectric layer of the seventh gate 17g and the dielectric layer of the eighth gate 17h has a thickness ranging between 80 Å to 100 Å.

In one embodiment, the integrated structure 10 of complementary metal-oxide-semiconductor devices has a minimum feature size which is 0.18 micrometer.

It is noteworthy that, in the present invention, the process steps that form the semiconductor layer 11, insulation regions 12, the first low voltage P-type well 13a, the second low voltage P-type well 13b, the first high voltage P-type well 14a, the second high voltage P-type well 14b, the first low voltage N-type well 15a, the second low voltage N-type well 15b, the first high voltage N-type well 16a, the second high voltage N-type well 16b, the first gate 17a, the second gate 17b, the third gate 17c, the fourth gate 17d, the fifth gate 17e, the sixth gate 17f, the seventh gate 17g, an eighth gate 17h, the first N-type source 18a and the first N-type drain 19a, the second N-type source 18b and the second N-type drain 19b, the third N-type source 18c and the third N-type drain 19c, the fourth N-type source 18d and the fourth N-type drain 19d, the first P-type source 20a and the first P-type drain 21a, the second P-type source 20b and the second P-type drain 21b, the third P-type source 20c and the third P-type drain 21c, the fourth P-type source 20d and the fourth P-type drain 21d are all adoptable to form other semiconductor devices (e.g., other MOS devices) on the substrate 11. That is, the process steps that form the integrated structure 10 of CMOS devices of the present invention are currently available process steps for forming semiconductor devices. Because the present invention can manufacture different CMOS devices having different threshold voltages by adopting currently available process steps for forming semiconductor devices without requiring any new extra process step, as compared to the prior art, the manufacturing of the integrated structure 10 of CMOS devices of the present invention can save considerable manufacturing cost.

Note that the term “inversion current channel” means thus. Taking this embodiment as an example, when the first NMOS device NMOS11, the first PMOS device PMOS11, the second NMOS device NMOS12, the second PMOS device PMOS12, the third NMOS device NMOS13, the third PMOS device PMOS13, the fourth NMOS device NMOS14 and the fourth PMOS device PMOS14 operate in ON operation due to the voltages applied to the first gate 17a, the second gate 17b, the third gate 17c, the fourth gate 17d, the fifth gate 17e, the sixth gate 17f, the seventh gate 17g and the eighth gate 17h, an inversion layer is formed below the first gate 17a, the second gate 17b, the third gate 17c, the fourth gate 17d, the fifth gate 17e, the sixth gate 17f, the seventh gate 17g and the eighth gate 17h, so that a conduction current flows through the region of the inversion layer, which is the inverse current channel known to a person having ordinary skill in the art, so the details thereof are not redundantly explained here.

Note that the top surface 11a as referred to does not mean a completely flat plane but refers to the surface of the semiconductor layer 11′. In the present embodiment, for example, a part of the top surface 11a where the insulation region 12 is in contact with the semiconductor layer 11′ has a recessed portion.

Note that the above-mentioned “N-type” and “P-type” mean that impurities of corresponding conductivity types are doped in regions of the integrated structure 10 of CMOS devices (for example but not limited to the aforementioned first high voltage N-type well 14a and second high voltage N-type well 14b, the aforementioned first low voltage P-type well 13a and second low voltage P-type well 13b, the aforementioned first N-type source 18a and first N-type drain 19a, etc.), so that the regions have the corresponding “N-type” or “P-type”, wherein “N-type” and “P-type” are opposite conductivity types.

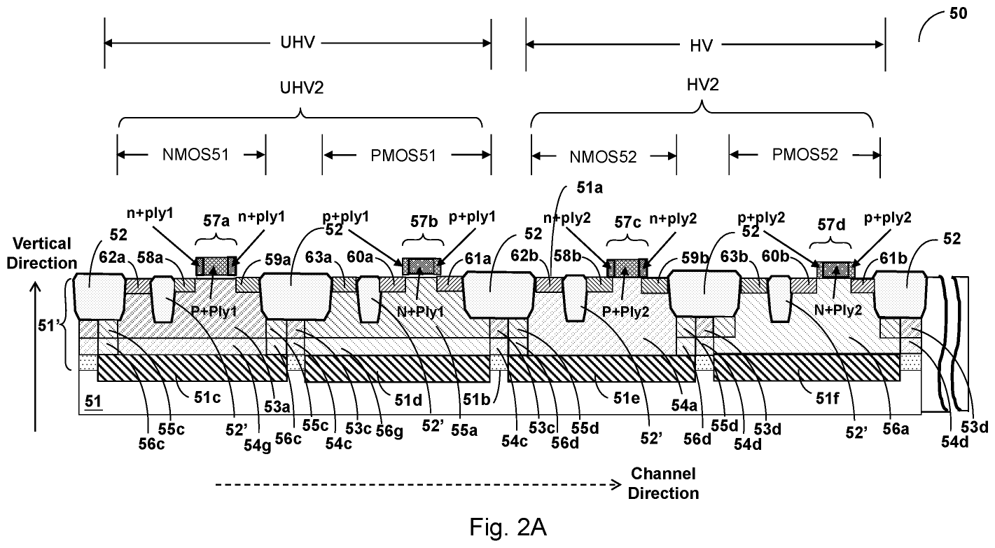

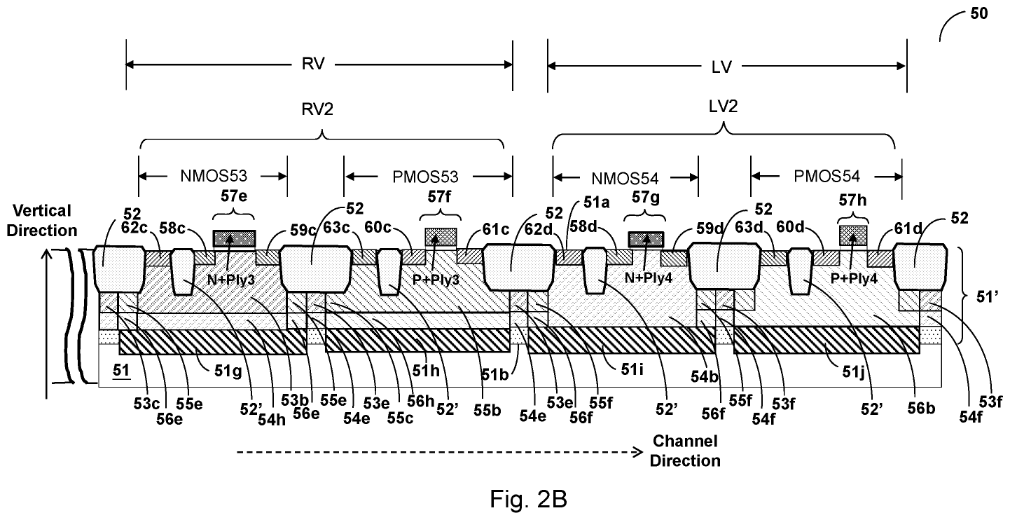

FIG. 2A and FIG. 2B in combination show a cross-section view of an integrated structure 50 of CMOS devices according to an embodiment of the present invention. As shown in FIG. 2A and FIG. 2B, the integrated structure 50 of CMOS comprises: a semiconductor layer 51′, a first N-type buried layer 51c, a second N-type buried layer 51d, a third N-type buried layer 51e, a fourth N-type buried layer 51f, a fifth N-type buried layer 51g, a sixth N-type buried layer 51h, a seventh N-type buried layer 51i, an eighth N-type buried layer 51j, insulation regions 52 and 52′, a first low voltage P-type well 53a, a second low voltage P-type well 53b, a first high voltage P-type well 54a, a second high voltage P-type well 54b, a first low voltage N-type well 55a, a second low voltage N-type well 55b, a first high voltage N-type well 56a, a second high voltage N-type well 56b, a first gate 57a, a second gate 57b, a third gate 57c, a fourth gate 57d, a fifth gate 57e, a sixth gate 57f, a seventh gate 57g, an eighth gate 57h, a first N-type source 58a, a first N-type drain 59a, a first P-type source 60a, a first P-type drain 61a, a second N-type source 58b, a second N-type drain 59b, a second P-type source 60b, a second P-type drain 61b, a third N-type source 58c, a third N-type drain 59c, a third P-type source 60c, a third P-type drain 61c, a fourth N-type source 58d, a fourth N-type drain 59d, a fourth P-type source 60d, a fourth P-type drain 61d, a first P-type conductive region 62a, a first N-type conductive region 63a, a second P-type conductive region 62b, a second N-type conductive region 63b, a third P-type conductive region 62c, a third N-type conductive region 63c, a fourth P-type conductive region 62d, a fourth N-type conductive region 63d, two third low voltage N-type wells 55c, two third high voltage N-type wells 56c, two third low voltage P-type wells 53c, two third high voltage P-type wells 54c, two fourth low voltage N-type wells 55d, two fourth high voltage N-type wells 56d, two fourth low voltage P-type wells 53d, two fourth high voltage P-type wells 54d, two fifth low voltage N-type wells 55e, two fifth high voltage N-type wells 56e, two fifth low voltage P-type wells 53e, two fifth high voltage P-type wells 54e, two sixth low voltage N-type wells 55f, two sixth high voltage N-type wells 56f, two sixth high voltage N-type wells 53f, two sixth high voltage P-type wells 54f, a first high voltage P-type isolation region 54g, a first high voltage N-type isolation region 56g, a second high voltage P-type isolation region 54h and a second high voltage N-type isolation region 56h.

The semiconductor layer 51′ is formed on the substrate 51. The semiconductor layer 51′ has a top surface 51a and a bottom surface 51b opposite to the top surface 51a in the vertical direction. The substrate 51 can be for example a P-type or an N-type semiconductor substrate. The semiconductor layer 51′, for example, is formed on the substrate 51 by an epitaxial process step, or is a part of the substrate 51. The semiconductor layer 51′ can be formed by various methods known to a person having ordinary skill in the art, so the details thereof are not redundantly explained here.

Please still refer to FIG. 2A and FIG. 2B. The insulation regions 52 are formed on the semiconductor layer 51′, for defining an ultra high threshold device region UHV, a high threshold device region HV, a middle threshold device region RV and a low threshold device region LV. A CMOS device UHV2 having an ultra high threshold voltage is formed in the ultra high threshold device region UHV; a CMOS device HV2 having a high threshold voltage is formed in the high threshold device region HV; a CMOS device RV2 having a middle threshold voltage is formed in the middle threshold device region RV; and a CMOS device LV2 having a low threshold voltage is formed in the low threshold device region LV. The insulation regions 52 can be, for example but not limited to, a shallow trench isolation (STI) structure as shown in FIG. 2A and FIG. 2B.

The insulation regions 52′ are formed on the semiconductor layer 51′ by one same process step that forms the insulation regions 52. The insulation regions 52′ serves to electrically isolate N-type sources from P-type conductive regions. That is, to be more specific, the insulation regions 52′ serve to electrically isolate the first N-type source 58a from the first P-type conductive region 62a, to electrically isolate the second N-type source 58b from the second P-type conductive region 62b, to electrically isolate the third N-type source 58c from the third P-type conductive region 62c, and to electrically isolate the fourth N-type source 58d from the fourth P-type conductive region 62d; and/or, the insulation regions 52′ serve to electrically isolate P-type sources from N-type conductive regions, that is, to be more specific, the insulation regions 52′ serve to electrically isolate the first P-type source 60a from the first N-type conductive region 63a, to electrically isolate the second P-type source 60b from the second N-type conductive region 63b, to electrically isolate the third P-type source 60c from the third N-type conductive region 63c and to electrically isolate the fourth P-type source 60d from the fourth N-type conductive region 63d.

The CMOS device UHV2 having an ultra high threshold voltage includes: a first NMOS device NMOS51 and a first PMOS device PMOS51; the CMOS device HV2 having a high threshold voltage includes: a second NMOS device NMOS52 and a second PMOS device PMOS52; the CMOS device RV2 having a middle threshold voltage includes: a third NMOS device NMOS53 and a third PMOS device PMOS53; and the CMOS device LV2 having a low threshold voltage includes: a fourth NMOS device NMOS54 and a fourth PMOS device PMOS54. The threshold voltage of the first NMOS device NMOS51 is higher than the threshold voltage of the second NMOS device NMOS52; the threshold voltage of the second NMOS device NMOS52 is higher than the threshold voltage of the third NMOS device NMOS53; and the threshold voltage of the third NMOS device NMOS53 is higher than the threshold voltage of the fourth NMOS device NMOS54. The absolute value of the threshold voltage of the first PMOS device PMOS51 is higher than the absolute value of the threshold voltage of the second PMOS device PMOS52; the absolute value of the threshold voltage of the second PMOS device PMOS52 is higher than the absolute value of the threshold voltage of the third PMOS device PMOS53; and the absolute value of the threshold voltage of the third PMOS device PMOS53 is higher than the absolute value of the threshold voltage of the fourth PMOS device PMOS54. The terms “ultra high threshold”, “high threshold”, “middle threshold” and “low threshold” refer to: relative relationships among the threshold voltages of these above-mentioned MOS devices.

In this embodiment, in the CMOS device UHV2 having an ultra high threshold voltage, the first NMOS device NMOS51 includes: the insulation regions 52′, the first low voltage P-type well 53a, the first gate 57a, the first N-type source 58a, the first N-type drain 59a and the first P-type conductive region 62a, whereas, the first PMOS device PMOS51 includes: the insulation regions 52′, the first low voltage N-type well 55a, the second gate 57b, the first P-type source 60a, the first P-type drain 61a and the first N-type conductive region 63a. In the CMOS device HV2 having a high threshold voltage, the second NMOS device NMOS52 includes: the insulation regions 52′, the first high voltage P-type well 54a, the third gate 57c, the second N-type source 58b, the second N-type drain 59b and the second P-type conductive region 62b, whereas, the second PMOS device PMOS52 includes: the insulation regions 52′, the first high voltage N-type well 56a, the fourth gate 57d, the second P-type source 60b, the second P-type drain 61b and the second N-type conductive region 63b. In the CMOS device RV2 having a middle threshold voltage, the third NMOS device NMOS53 includes: the insulation regions 52′, the second low voltage P-type well 53b, the fifth gate 57e, the third N-type source 58c, the third N-type drain 59c and the third P-type conductive region 62c, whereas, the third PMOS device PMOS53 includes: the insulation regions 52′, the second low voltage N-type well 55b, the sixth gate 57f, the third P-type source 60c, the third P-type drain 61c and the third N-type conductive region 63c. In the CMOS device LV2 having a low threshold voltage, the fourth NMOS device NMOS54 includes: the insulation regions 52′, the second high voltage P-type well 54b, the seventh gate 57g, the fourth N-type source 58d, the fourth N-type drain 59d and the fourth P-type conductive region 62d, whereas, the fourth PMOS device PMOS54 includes: the insulation regions 52′, the second high voltage N-type well 56b, the eighth gate 57h, the fourth P-type source 60d, the fourth P-type drain 61d and the fourth N-type conductive region 63d.

Please still refer to FIG. 2A and FIG. 2B. The first low voltage P-type well 53a and the second low voltage P-type well 53b are formed in the semiconductor layer 51′ in the ultra high threshold device region UHV and the semiconductor layer 51′ in the middle threshold device region RV, respectively, by one same ion implantation process step. The first low voltage P-type well 53a and the second low voltage P-type well 53b are below and in contact with the top surface 51a. Apart of the first low voltage P-type well 53a is located vertically below and in contact with the first gate 57a, which serves as an inversion current channel in an ON operation of the first NMOS device NMOS51. Besides, a part of the second low voltage P-type well 53b is located vertically below and in contact with the fifth gate 57e, which serves as an inversion current channel in an ON operation of the third NMOS device NMOS53.

Please still refer to FIG. 2A and FIG. 2B. The first high voltage P-type well 55a and the second high voltage P-type well 55b are formed in the semiconductor layer 51′ in the ultra high threshold device region UHV and the semiconductor layer 51′ in the middle threshold device region RV, respectively, by one same ion implantation process step. The first high voltage P-type well 55a and the second high voltage P-type well 55b are below and in contact with the top surface 51a. A part of the first high voltage P-type well 55a is located vertically below and in contact with the second gate 57b, which serves as an inversion current channel in an ON operation of the first PMOS device PMOS51. Besides, a part of the second high voltage P-type well 55b is located vertically below and in contact with the sixth gate 57f, which serves as an inversion current channel in an ON operation of the third PMOS device PMOS53.

Please still refer to FIG. 2A and FIG. 2B. The first high voltage P-type well 54a and the second high voltage P-type well 54b are formed in the semiconductor layer 51′ in the high threshold device region HV and the semiconductor layer 51′ in the low threshold device region LV, respectively, by one same ion implantation process step. The first high voltage P-type well 54a and the second high voltage P-type well 54b are below and in contact with the top surface 51a. A part of the first high voltage P-type well 54a is located vertically below and in contact with the third gate 57c, which serves as an inversion current channel in an ON operation of the second NMOS device NMOS52. Besides, a part of the second high voltage P-type well 54b is located vertically below and in contact with the seventh gate 57g, which serves as an inversion current channel in an ON operation of the fourth NMOS device NMOS54.

Please still refer to FIG. 2A and FIG. 2B. The first high voltage N-type well 56a and the second high voltage N-type well 56b are formed in the semiconductor layer 51′ in the high threshold device region HV and the semiconductor layer 51′ in the low threshold device region LV, respectively, by one same ion implantation process step. The first high voltage N-type well 56a and the second high voltage N-type well 56b are below and in contact with the top surface 51a. A part of the first high voltage N-type well 56a is located vertically below and in contact with the fourth gate 57d, which serves as an inversion current channel in an ON operation of the second PMOS device PMOS52. Besides, a part of the second high voltage N-type well 16b is located vertically below and in contact with the eighth gate 57h, which serves as an inversion current channel in an ON operation of the fourth PMOS device PMOS54.

The first gate 57a is formed on the top surface 51a of the semiconductor layer 51′ in the ultra high threshold device region UHV. The first gate 57a has a first P-type polysilicon layer P+Ply1 and two first N-type polysilicon sub-layers n+ply1 and n+ply1, wherein the two first N-type polysilicon sub-layers n+ply1 and n+ply1 are located beside and in contact with two sides of the first P-type polysilicon layer P+Ply1, respectively. The first gate 57a includes: a conductive layer, a spacer layer and a dielectric layer, wherein the dielectric layer is located on and in contact with the top surface 51a, wherein the conductive layer includes the aforementioned first P-type polysilicon layer P+Ply1 and two first N-type polysilicon sub-layers n+ply1 and n+ply1, and wherein the spacer layer (not shown for simplicity of the drawing) overlays two sides of the conductive layer, which are known to a person having ordinary skill in the art, so the details thereof are not redundantly explained here.

The second gate 57b is formed on the top surface 51a of the semiconductor layer 51′ in the ultra high threshold device region UHV. The second gate 57b has a first N-type polysilicon layer N+Ply1 and two first P-type polysilicon sub-layers p+Ply1 and p+Ply1, wherein the two first P-type polysilicon sub-layers p+Ply1 and p+Ply1 are located beside and in contact with two sides of the first N-type polysilicon layer N+Ply1, respectively. The second gate 57b includes: a conductive layer, a spacer layer and a dielectric layer, wherein the dielectric layer is located on and in contact with the top surface 51a, wherein the conductive layer includes the aforementioned first N-type polysilicon layer N+Ply1 and two first P-type polysilicon sub-layers p+Ply1 and p+Ply, and wherein the spacer layer (not shown for simplicity of the drawing) overlays two sides of the conductive layer, which are known to a person having ordinary skill in the art, so the details thereof are not redundantly explained here.

The third gate 57c is formed on the top surface 51a of the semiconductor layer 51′ in the high threshold device region HV. The third gate 57c has a second P-type polysilicon layer P+Ply2 and two second N-type polysilicon sub-layers n+ply2 and n+ply2, wherein the two second N-type polysilicon sub-layers n+ply2 and n+ply2 are located beside and in contact with two sides of the second P-type polysilicon layer P+Ply2, respectively. The third gate 57c includes: a conductive layer, a spacer layer and a dielectric layer, wherein the dielectric layer is located on and in contact with the top surface 51a, wherein the conductive layer includes the aforementioned second P-type polysilicon layer P+Ply2 and two second N-type polysilicon sub-layers n+ply2 and n+ply2, and wherein the spacer layer (not shown for simplicity of the drawing) overlays two sides of the conductive layer, which are known to a person having ordinary skill in the art, so the details thereof are not redundantly explained here.

The fourth gate 57d is formed on the top surface 51a of the semiconductor layer 51′ in the high threshold device region HV. The fourth gate 57d has a second N-type polysilicon layer N+Ply2 and two second P-type polysilicon sub-layers p+ply2 and p+ply2, wherein the two second P-type polysilicon sub-layers p+ply2 and p+ply2 are located beside and in contact with two sides of the second N-type polysilicon layer N+Ply2, respectively. The fourth gate 57d includes: a conductive layer, a spacer layer and a dielectric layer, wherein the dielectric layer is located on and in contact with the top surface 51a, wherein the conductive layer includes the aforementioned second N-type polysilicon layer N+Ply2 and two second P-type polysilicon sub-layers p+ply2 and p+ply2, and wherein the spacer layer (not shown for simplicity of the drawing) overlays two sides of the conductive layer, which are known to a person having ordinary skill in the art, so the details thereof are not redundantly explained here.

The fifth gate 57e is formed on the top surface 51a of the semiconductor layer 51′ in the middle threshold device region RV. the fifth gate has a third N-type polysilicon layer N+Ply3. The fifth gate 57e includes: a conductive layer, a spacer layer and a dielectric layer, wherein the dielectric layer is located on and in contact with the top surface 51a, wherein the conductive layer includes the aforementioned third N-type polysilicon layer N+Ply3, and wherein the spacer layer (not shown for simplicity of the drawing) overlays two sides of the conductive layer, which are known to a person having ordinary skill in the art, so the details thereof are not redundantly explained here.

The sixth gate 57f is formed on the top surface 51a of the semiconductor layer 51′ in the middle threshold device region RV. The sixth gate 57f has a third P-type polysilicon layer P+Ply3. The sixth gate 57f includes: a conductive layer, a spacer layer and a dielectric layer, wherein the dielectric layer is located on and in contact with the top surface 51a, wherein the conductive layer includes the aforementioned third P-type polysilicon layer P+Ply3, and wherein the spacer layer (not shown for simplicity of the drawing) overlays two sides of the conductive layer, which are known to a person having ordinary skill in the art, so the details thereof are not redundantly explained here.

The seventh gate 57g is formed on the top surface 51a of the semiconductor layer 51′ in the low threshold device region LV. The seventh gate 57g has a fourth N-type polysilicon layer N+Ply4. The seventh gate 57g includes: a conductive layer, a spacer layer and a dielectric layer, wherein the dielectric layer is located on and in contact with the top surface 51a, wherein the conductive layer includes the aforementioned fourth N-type polysilicon layer N+Ply4, and wherein the spacer layer (not shown for simplicity of the drawing) overlays two sides of the conductive layer, which are known to a person having ordinary skill in the art, so the details thereof are not redundantly explained here.

The eighth gate 57h is formed on the top surface 51a of the semiconductor layer 51′ in the low threshold device region LV. The eighth gate 57h has a fourth P-type polysilicon layer P+Ply4. The eighth gate 57h includes: a conductive layer, a spacer layer and a dielectric layer, wherein the dielectric layer is located on and in contact with the top surface 51a, wherein the conductive layer includes the aforementioned fourth P-type polysilicon layer P+Ply4, and wherein the spacer layer (not shown for simplicity of the drawing) overlays two sides of the conductive layer, which are known to a person having ordinary skill in the art, so the details thereof are not redundantly explained here.

The first N-type source 58a and the first N-type drain 59a are formed, by one same ion implantation process step, in the semiconductor layer 51′ of the ultra high threshold device region UHV, wherein the first N-type source 58a and the first N-type drain 59a are located below and outside two sides of the first gate 57a in the channel direction, respectively, wherein the side of the first gate 57a which is closer to the first N-type source 58a is a source side and the side of the first gate 57a which is closer to the first N-type drain 59a is a drain side, and wherein the first N-type source 58a and the first N-type drain 59a are located in the first low voltage P-type well 53a at the source side and the drain side, respectively. In the vertical direction, the first N-type source 58a and the first N-type drain 59a are formed on and in contact with the top surface 51a.

The first P-type source 60a and a first P-type drain 61a are formed, by one same ion implantation process step, in the semiconductor layer 51′ of the ultra high threshold device region UHV, wherein the first P-type source 60a and the first P-type drain 61a are located below and outside two sides of the second gate 57b in the channel direction, respectively, wherein the side of the second gate 57b which is closer to the first P-type source 60a is a source side and the side of the second gate 57b which is closer to the first P-type drain 61a is a drain side, and wherein the first P-type source 60a and the first P-type drain 61a are located in the first low voltage N-type well 55a at the source side and the drain side, respectively. In the vertical direction (as indicated by a solid arrow shown in FIG. 2A), the first P-type source 60a and a first P-type drain 61a are formed on and in contact with the top surface 51a.

The second N-type source 58b and the second N-type drain 59b are formed in the semiconductor layer 51′ of the high threshold device region HV by the one same ion implantation process step that forms the first N-type source 58a and the first N-type drain 59b, wherein the second N-type source 58b and the second N-type drain 59b are located below and outside two sides of the third gate 57c in the channel direction, respectively, wherein the side of the third gate 57c which is closer to the second N-type source 58b is a source side and the side of the third gate 57c which is closer to the second N-type drain 59b is a drain side, and wherein the second N-type source 58b and the second N-type drain 59b are located in the first high voltage P-type well 54a at the source side and the drain side, respectively. In the vertical direction, the second N-type source 58b and the second N-type drain 59b are formed on and in contact with the top surface 51a.

The second P-type source 60b and the second P-type drain 61b are formed in the semiconductor layer 51′ of the high threshold device region HV by the one same ion implantation process step that forms the first P-type source 60a and the first P-type drain 61a, wherein the second P-type source 60b and the second P-type drain 61b are located below and outside two sides of the fourth gate 57d in the channel direction, respectively, wherein the side of the fourth gate 57d which is closer to the second P-type source 60b is a source side and the side of the fourth gate 57d which is closer to the second P-type drain 61b is a drain side, and wherein the second P-type source 60b and the second P-type drain 61b are located in the first high voltage N-type well 56a at the source side and the drain side, respectively. In the vertical direction, the second P-type source 60b and the second P-type drain 61b are formed on and in contact with the top surface 51a.

The third N-type source 58c and the third N-type drain 59c are formed in the semiconductor layer 51′ of the middle threshold device region RV by the one same ion implantation process step that forms the first N-type source 58a and the first N-type drain 59a, wherein the third N-type source 58c and the third N-type drain 59c are located below and outside two sides of the fifth gate 57e in the channel direction, respectively, wherein the side of the fifth gate 57e which is closer to the third N-type source 58c is a source side and the side of the fifth gate 57e which is closer to the third N-type drain 59c is a drain side, and wherein the third N-type source 58c and the third N-type drain 59c are located in the second low voltage P-type well 53b at the source side and the drain side, respectively. In the vertical direction, the third N-type source 58c and the third N-type drain 59c are formed on and in contact with the top surface 51a.

The third P-type source 60c and the third P-type drain 61c are formed in the semiconductor layer 51′ of the middle threshold device region RV by the one same ion implantation process step that forms the first P-type source 60a and the first P-type drain 61a, wherein the third P-type source 60c and the third P-type drain 61c are located below and outside two sides of the sixth gate 57f in the channel direction, respectively, wherein the side of the sixth gate 57f which is closer to the third P-type source 60c is a source side and the side of the sixth gate 57f which is closer to the third P-type drain 61c is a drain side, and wherein the third P-type source 60c and the third P-type drain 61c are located in the second low voltage N-type well 55b at the source side and the drain side, respectively. In the vertical direction, the third P-type source 60c and the third P-type drain 61c are formed on and in contact with the top surface 51a.

The fourth N-type source 58d and the fourth N-type drain 59d are formed in the semiconductor layer 51′ of the low threshold device region LV by the one same ion implantation process step that forms the first N-type source 58a and the first N-type drain 59a, wherein the fourth N-type source 58d and the fourth N-type drain 59d are located below and outside two sides of the seventh gate 57g in the channel direction, respectively, wherein the side of the seventh gate 57g which is closer to the fourth N-type source 58d is a source side and the side of the seventh gate 57g which is closer to the fourth N-type drain 59d is a drain side, and wherein the fourth N-type source 58d and the fourth N-type drain 59d are located in the second high voltage P-type well 54b at the source side and the drain side, respectively. In the vertical direction, the fourth N-type source 58d and the fourth N-type drain 59d are formed on and in contact with the top surface 51a.

The fourth P-type source 60d and the fourth P-type drain 61d are formed in the semiconductor layer 51′ of the low threshold device region LV by the one same ion implantation process step that forms the first P-type source 60a and the first P-type drain 61a, wherein the fourth P-type source 60d and the fourth P-type drain 61d are located below and outside two sides of the eighth gate 57h in the channel direction, respectively, wherein the side of the eighth gate 57h which is closer to the fourth P-type source 60d is a source side and the side of the eighth gate 57h which is closer to the fourth P-type drain 61d is a drain side, and wherein the fourth P-type source 60d and the fourth P-type drain 61d are located in the second high voltage N-type well 56b at the source side and the drain side, respectively. In the vertical direction, the fourth P-type source 60d and the fourth P-type drain 61d are formed on and in contact with the top surface 51a.

The first P-type conductive region 62a is formed in the first low voltage P-type well 53a in the ultra high threshold device region UHV, wherein the first P-type conductive region 62a serves as an electrical contact of the first low voltage P-type well 53a. In the vertical direction, the first P-type conductive region 62a is formed on and in contact with the top surface 51a. The second P-type conductive region 62b is formed in the first high voltage P-type well 54a in the high threshold device region HV by one same ion implantation process step that forms the first P-type conductive region 62a, wherein the second P-type conductive region 62b serves as an electrical contact of the first high voltage P-type well 54a. In the vertical direction, the second P-type conductive region 62b is formed on and in contact with the top surface 51a. The third P-type conductive region 62c is formed in the second low voltage P-type well 53b in the middle threshold device region RV by the one same ion implantation process step that forms the first P-type conductive region 62a, wherein the third P-type conductive region 62c serves as an electrical contact of the second low voltage P-type well 53b. In the vertical direction, the third P-type conductive region 62c is formed on and in contact with the top surface 51a. The fourth P-type conductive region 62d is formed in the second high voltage P-type well 54b in the low threshold device region LV by the one same ion implantation process step that forms the first P-type conductive region 62a, wherein the fourth P-type conductive region 62d serves as an electrical contact of the second high voltage P-type well 54b. In the vertical direction, the fourth P-type conductive region 62d is formed on and in contact with the top surface 51a.

The first N-type conductive region 63a is formed in the first low voltage N-type well 55a in the ultra high threshold device region UHV, wherein the first N-type conductive region 63a serves as an electrical contact of the first low voltage N-type well 55a. In the vertical direction, the first N-type conductive region 63a is formed on and in contact with the top surface 51a. The second N-type conductive region 63b is formed in the first high voltage N-type well 56a in the high threshold device region HV by one same ion implantation process step that forms the first N-type conductive region 63a, wherein the second N-type conductive region 63b serves as an electrical contact of the first high voltage N-type well 56a. In the vertical direction, the second N-type conductive region 63b is formed on and in contact with the top surface 51a. The third N-type conductive region 63c is formed in the second low voltage N-type well 55b in the middle threshold device region RV by the one same ion implantation process step that forms the first P-type conductive region 63a, wherein the third N-type conductive region 63c serves as an electrical contact of the second low voltage N-type well 55b. In the vertical direction, the third N-type conductive region 63c is formed on and in contact with the top surface 51a. The fourth N-type conductive region 63d is formed in the second high voltage N-type well 56b in the low threshold device region LV by the one same ion implantation process step that forms the first P-type conductive region 63a, wherein the fourth N-type conductive region 63d serves as an electrical contact of the second high voltage N-type well 56b. In the vertical direction, the fourth N-type conductive region 63d is formed on and in contact with the top surface 51a.

A first N-type buried layer 51c, a second N-type buried layer 51d, a third N-type buried layer 51e, a fourth N-type buried layer 51f, a fifth N-type buried layer 51g, a sixth N-type buried layer 51h, a seventh N-type buried layer 51i and an eighth N-type buried layer 51j are formed, by one same process step, in the semiconductor layer 51′ and the substrate 51 which are below the first low voltage P-type well 53a in the ultra high threshold device region UHV, in the semiconductor layer 51′ and the substrate 51 which are below the first low voltage N-type well 55a in the ultra high threshold device region UHV, in the semiconductor layer 51′ and the substrate 51 which are below the first high voltage P-type well 54a in the high threshold device region HV, in the semiconductor layer 51′ and in the substrate 51 which are below the first high voltage N-type well 56a in the high threshold device region HV, in the semiconductor layer 51′ and the substrate 51 which are below the second low voltage P-type well 53b in the middle threshold device region RV, in the semiconductor layer 51′ and the substrate 51 which are below the second low voltage N-type well 55b in the middle threshold device region RV, in the semiconductor layer 51′ and the substrate 51 which are below the second high voltage P-type well 54b in the low threshold device region LV, and in the semiconductor layer 51′ and the substrate 51 which are below the second high voltage N-type well 56b in the low threshold device region LV, respectively.

The first N-type buried layer 51c is formed vertically below the first low voltage P-type well 53a. The second N-type buried layer 51d is formed vertically below the first low voltage N-type well 55a. The third N-type buried layer 51e is formed vertically below and in contact with the first high voltage P-type well 54a. The fourth N-type buried layer 51f is formed vertically below and in contact with the first high voltage N-type well 56a. The fifth N-type buried layer 51g is formed vertically below the second low voltage P-type well 53b. The sixth N-type buried layer 51h is formed vertically below the second low voltage N-type well 55b. The seventh N-type buried layer 51i is formed vertically below and in contact with the second high voltage P-type well 54b. The eighth N-type buried layer 51j is formed vertically below and in contact with the second high voltage N-type well 56b.

The two third low voltage N-type wells 55c and the two third high voltage N-type wells 56c are formed in the semiconductor layer 51′ in the ultra high threshold device region UHV, wherein the two third low voltage N-type wells 55c are located beside and in contact with two sides of the first low voltage P-type well 53a, respectively, whereas, the two third high voltage N-type wells 56c are located beside and in contact with two sides of the first low voltage P-type well 53a, respectively. The lower boundaries of the two third high voltage N-type wells 56c are in contact with the first N-type buried layer 51c, wherein the two third low voltage N-type wells 55c, the two third high voltage N-type wells 56c and the first N-type buried layer 51c constitute a first isolation region, which serves to electrically isolate the first NMOS device NMOS51 in the semiconductor layer 51′. The two third low voltage N-type wells 55c are formed by the same ion implantation process step that forms the first low voltage N-type well 55a, whereas, the two third high voltage N-type wells 56c are formed by the same ion implantation process step that forms the first high voltage N-type well 56a.

The two third low voltage P-type wells 53c and the two third high voltage P-type wells 54c are formed in the semiconductor layer 51′ in the ultra high threshold device region UHV, wherein the two third low voltage P-type wells 53c are located beside and in contact with two sides of the first low voltage N-type well 55a, respectively, whereas, the two third high voltage P-type wells 54c are located beside and in contact with two sides of the first low voltage N-type well 55a, respectively. The lower boundaries of the two third high voltage P-type wells 54c are in contact with the second N-type buried layer 51d, wherein the two third low voltage P-type wells 53c, the two third high voltage P-type wells 54c and the second N-type buried layer 51d constitute a second isolation region, which serves to electrically isolate the first PMOS device PMOS51 in the semiconductor layer 51′. The two third low voltage P-type wells 53c are formed by the same ion implantation process step that forms the first low voltage P-type well 53a, whereas, the two third high voltage P-type wells 54c are formed by the same ion implantation process step that forms the first high voltage P-type well 54a.

The two fourth low voltage N-type wells 55d and the two fourth high voltage N-type wells 56d are formed in the semiconductor layer 51′ in the high threshold device region HV, wherein the two fourth low voltage N-type wells 55d are located beside and in contact with two sides of the first high voltage P-type well 54a, respectively, whereas, the two fourth high voltage N-type wells 56d are located beside and in contact with two sides of the first high voltage P-type well 54a, respectively. The lower boundaries of the two fourth high voltage N-type wells 56d are in contact with the third N-type buried layer 51e, wherein the two fourth low voltage N-type wells 55d, the two fourth high voltage N-type wells 56d and the third N-type buried layer 51e constitute a third isolation region, which serves to electrically isolate the second NMOS device NMOS52 in the semiconductor layer 51′. The two fourth low voltage N-type wells 55d are formed by the same ion implantation process step that forms the first low voltage N-type well 55a, whereas, the two fourth high voltage N-type wells 56d are formed by the same ion implantation process step that forms the first high voltage N-type well 56a.

The two fourth low voltage P-type wells 53d and the two fourth high voltage P-type wells 54d are formed in the semiconductor layer 51′ in the high threshold device region HV, wherein the two fourth low voltage P-type wells 53d are located beside and in contact with two sides of the first high voltage N-type well 56a, respectively, whereas, the two fourth high voltage P-type wells 54d are located beside and in contact with two sides of the first high voltage N-type well 56a, respectively. The lower boundaries of the two fourth high voltage P-type wells 54d are in contact with the fourth N-type buried layer 51f, wherein the two fourth low voltage P-type wells 53d, the two fourth high voltage P-type wells 54d and the fourth N-type buried layer 51f constitute a fourth isolation region, which serves to electrically isolate the second PMOS device PMOS52 in the semiconductor layer 51′. The two fourth low voltage P-type wells 53d are formed by the same ion implantation process step that forms the first low voltage P-type well 53a, whereas, the two fourth high voltage P-type wells 54d are formed by the same ion implantation process step that forms the first high voltage P-type well 54a.

The two fifth low voltage N-type wells 55e and the two fifth high voltage N-type wells 56e are formed in the semiconductor layer 51′ in the middle threshold device region RV, wherein the two fifth low voltage N-type wells 55e are located beside and in contact with two sides of the second low voltage P-type well 53b, respectively, whereas, the two fifth high voltage N-type wells 56e are located beside and in contact with two sides of the second low voltage P-type well 53b, respectively. The lower boundaries the two fifth high voltage N-type wells 56e are in contact with the fifth N-type buried layer 51g, wherein the two fifth low voltage N-type wells 55e, the two fifth high voltage N-type wells 56e and the fifth N-type buried layer 51g constitute a fifth isolation region, which serves to electrically isolate the third NMOS device NMOS53 in the semiconductor layer 51′. The two fifth low voltage N-type wells 55e are formed by the same ion implantation process step that forms the first low voltage N-type well 55a, whereas, the two fifth high voltage N-type wells 56e are formed by the same ion implantation process step that forms the first high voltage N-type well 56a.

The two fifth low voltage P-type wells 53e and the two fifth high voltage P-type wells 54e are formed in the semiconductor layer 51′ in the middle threshold device region RV, wherein the two fifth low voltage P-type wells 53e are located beside and in contact with two sides of the second low voltage N-type well 55b, respectively, whereas, the two fifth high voltage P-type wells 54e are located beside and in contact with two sides of the second low voltage N-type well 55b, respectively. The lower boundaries the two fifth high voltage P-type wells 54e are in contact with the sixth N-type buried layer 51h, wherein the two fifth low voltage P-type wells 53e, the two fifth high voltage P-type wells 54e and the sixth N-type buried layer 51h constitute a sixth isolation region, which serves to electrically isolate the third NMOS device PMOS53 in the semiconductor layer 51′. The two fifth low voltage P-type wells 53e are formed by the same ion implantation process step that forms the first low voltage P-type well 53a, whereas, the two fifth high voltage P-type wells 54e are formed by the same ion implantation process step that forms the first high voltage P-type well 54a.

The two sixth low voltage N-type wells 55f and the two sixth high voltage N-type wells 56f are formed in the semiconductor layer 51′ in the low threshold device region LV, wherein the two sixth low voltage N-type wells 55f are located beside and in contact with two sides of the fourth high voltage P-type well 54b, respectively, whereas, the two sixth high voltage N-type wells 56f are located beside and in contact with two sides of the fourth high voltage P-type well 54b, respectively. The lower boundaries the two sixth high voltage N-type wells 56f are in contact with the seventh N-type buried layer 51i, wherein the two sixth low voltage N-type wells 55f, the two sixth high voltage N-type wells 56f and the seventh N-type buried layer 51i constitute a seventh isolation region, which serves to electrically isolate the fourth NMOS device NMOS54 in the semiconductor layer 51′. The two sixth low voltage N-type wells 55f are formed by the same ion implantation process step that forms the first low voltage N-type well 55a, whereas, the two sixth high voltage N-type wells 56f are formed by the same ion implantation process step that forms the first high voltage N-type well 56a.

The two sixth high voltage N-type wells 53f and the two sixth high voltage P-type wells 54f are formed in the semiconductor layer 51′ in the low threshold device region LV, wherein the two sixth high voltage N-type wells 53f are located beside and in contact with two sides of the fourth high voltage N-type well 56b, respectively, whereas, the two sixth high voltage P-type wells 54f are located beside and in contact with two sides of the fourth high voltage N-type well 56b, respectively. The lower boundaries the two sixth high voltage P-type wells 54f are in contact with the eighth N-type buried layer 51j, wherein the two sixth high voltage N-type wells 53f, the two sixth high voltage P-type wells 54f and the eighth N-type buried layer 51j constitute an eighth isolation region, which serves to electrically isolate the fourth PMOS device PMOS54 in the semiconductor layer 51′. The two sixth high voltage N-type wells 53f are formed by the same ion implantation process step that forms the first low voltage P-type well 53a, whereas, the two sixth high voltage P-type wells 54f are formed by the same ion implantation process step that forms the first high voltage P-type well 54a.

It is worthwhile noting that, in this embodiment, because the P-type doped impurities concentration of the first low voltage P-type well 53a and the second low voltage P-type well 53b is higher than the P-type doped impurities concentration of the first high voltage P-type well 54a and the second high voltage P-type well 54b, the inverse channel region (i.e., a part of the first high voltage P-type well 54a which is vertically below the gate) of the first NMOS device NMOS51 and the inverse channel region (i.e., a part of the second high voltage P-type well 54b which is vertically below the gate) of the third NMOS device NMOS53 have a relatively higher P-type doped impurities concentration, as compared to the inverse channel region of the second NMOS device NMOS52 and the inverse channel region of the fourth NMOS device NMOS54. As the result, the first NMOS device NMOS51 and the third NMOS device NMOS53 have a relatively higher threshold voltage. Besides, because the N-type doped impurities concentration of the first low voltage N-type well 55a and the second low voltage N-type well 55b is higher than the N-type doped impurities concentration of the first high voltage N-type well 56a and the second high voltage N-type well 56b, the inverse channel region (i.e., a part of the first high voltage N-type well 56a which is vertically below the gate) of the first PMOS device PMOS51 and the inverse channel region (i.e., a part of the second high voltage N-type well 56b which is vertically below the gate) of the third PMOS device PMOS53 have a relatively higher N-type doped impurities concentration, as compared to the inverse channel region of the second PMOS device PMOS52 and the inverse channel region of the fourth PMOS device PMOS54. As the result, the first PMOS device PMOS51 and the third PMOS device PMOS53 have a relatively higher absolute value of the threshold voltage.

In addition, the NMOS device which adopts a P-type polysilicon layer to form the conductive layer of the gate has a relatively higher threshold voltage, as compared to the NMOS device which adopts an N-type polysilicon layer to form the conductive layer of the gate. The PMOS device which adopts an N-type polysilicon layer to form the conductive layer of the gate has a relatively higher absolute value of the threshold voltage, as compared to the PMOS device which adopts a P-type polysilicon layer to form the conductive layer of the gate. Consequently, in light of the above, the threshold voltage of the first NMOS device NMOS51 is higher than the threshold voltage of the second NMOS device NMOS52; the threshold voltage of the second NMOS device NMOS52 is higher than the threshold voltage of the third NMOS device NMOS53; and the threshold voltage of the third NMOS device NMOS53 is higher than the threshold voltage of the fourth NMOS device NMOS54.

The first high voltage P-type isolation region 54g is formed in the semiconductor layer 51′ by the same ion implantation process step that forms the first high voltage P-type well 54a. The first high voltage N-type isolation region 56g is formed in the semiconductor layer 51′ by the same ion implantation process step that forms the first high voltage N-type well 56a. The second high voltage P-type isolation region 54h is formed in the semiconductor layer 51′ by the same ion implantation process step that forms the first high voltage P-type well 54a. The second high voltage N-type isolation region 56h is formed in the semiconductor layer 51′ by the same ion implantation process step that forms the second high voltage N-type well 56a. The first high voltage P-type isolation region 54g is below and in contact with the first low voltage P-type well 53a. The first high voltage N-type isolation region 56g is below and in contact with the first low voltage N-type well 55a. The second high voltage P-type isolation region 54h is below and in contact with the second low voltage P-type well 53b. The second high voltage N-type isolation region 56h is below and in contact with the second low voltage N-type well 55b.

In one embodiment, the semiconductor layer 51′ is a P-type semiconductor epitaxial layer having a volume resistivity which is 45 Ohm-cm.

In one embodiment, each of the dielectric layer of the first gate 57a, the dielectric layer of the second gate 57b, the dielectric layer of the third gate 57c, the dielectric layer of the fourth gate 57d, the dielectric layer of the fifth gate 57e, the dielectric layer of the sixth gate 57f, the dielectric layer of the seventh gate 57g and the dielectric layer of the eighth gate 57h has a thickness ranging between 80 Å to 100 Å.

In one embodiment, the integrated structure 50 of CMOS devices has a minimum feature size which is 0.18 micrometer.

It is noteworthy that, in the present invention, the process steps that form the semiconductor layer 51′, the first N-type buried layer 51c, the second N-type buried layer 51d, the third N-type buried layer 51e, the fourth N-type buried layer 51f, the fifth N-type buried layer 51g, the sixth N-type buried layer 51h, the seventh N-type buried layer 51i, the eighth N-type buried layer 51j, insulation regions 52 and 52′, the first low voltage P-type well 53a, the second low voltage P-type well 53b, the first high voltage P-type well 54a, the second high voltage P-type well 54b, the first low voltage N-type well 55a, the second low voltage N-type well 55b, the first high voltage N-type well 56a, the second high voltage N-type well 56b, the first gate 57a, the second gate 57b, the third gate 57c, the fourth gate 57d, the fifth gate 57e, the sixth gate 57f, the seventh gate 57g, the eighth gate 57h, the first N-type source 58a, the first N-type drain 59a, the first P-type source 60a, the first P-type drain 61a, the second N-type source 58b, the second N-type drain 59b, the second P-type source 60b, the second P-type drain 61b, the third N-type source 58c, the third N-type drain 59c, the third P-type source 60c, the third P-type drain 61c, the fourth N-type source 58d, the fourth N-type drain 59d, the fourth P-type source 60d, the fourth P-type drain 61d, the first P-type conductive region 62a, the first N-type conductive region 63a, the second P-type conductive region 62b, the second N-type conductive region 63b, the third P-type conductive region 62c, the third N-type conductive region 63c, the fourth P-type conductive region 62d, the fourth N-type conductive region 63d, the two third low voltage N-type wells 55c, the two third high voltage N-type wells 56c, the two third low voltage P-type wells 53c, the two third high voltage P-type wells 54c, the two fourth low voltage N-type wells 55d, the two fourth high voltage N-type wells 56d, the two fourth low voltage P-type wells 53d, the two fourth high voltage P-type wells 54d, the two fifth low voltage N-type wells 55e, the two fifth high voltage N-type wells 56e, the two fifth low voltage P-type wells 53e, the two fifth high voltage P-type wells 54e, the two sixth low voltage N-type wells 55f, the two sixth high voltage N-type wells 56f, the two sixth high voltage N-type wells 53f, the two sixth high voltage P-type wells 54f, the first high voltage P-type isolation region 54g, the first high voltage N-type isolation region 56g, the second high voltage P-type isolation region 54h and the second high voltage N-type isolation region 56h are all adoptable to form other semiconductor devices (e.g., other MOS devices) in the substrate 51. That is, the process steps that form the integrated structure 50 of CMOS devices are currently available process steps for forming semiconductor devices. Because the present invention can manufacture different CMOS devices having different threshold voltages by adopting currently available process steps for forming semiconductor devices without requiring any new extra process step, as compared to the prior art, the manufacturing of the integrated structure 50 of CMOS devices of the present invention can save considerable manufacturing cost.

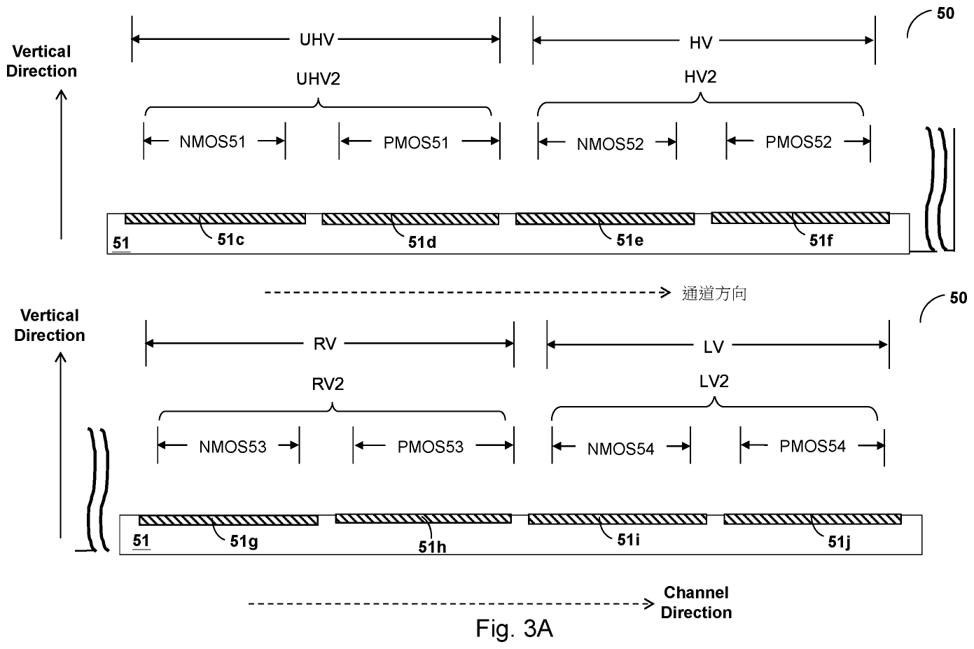

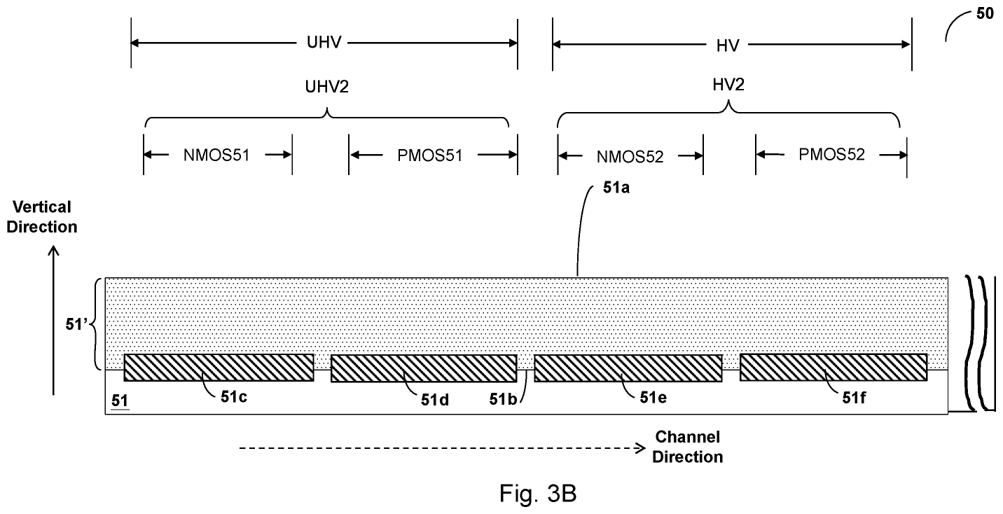

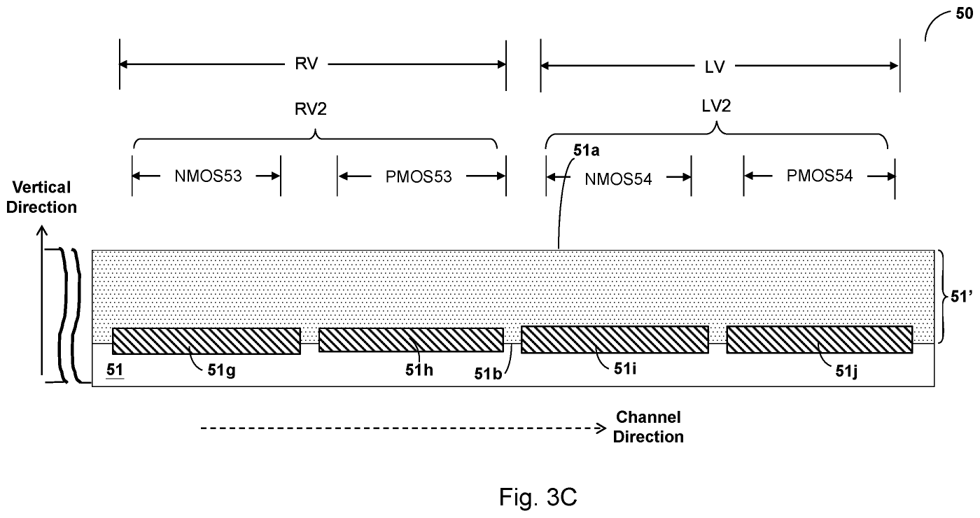

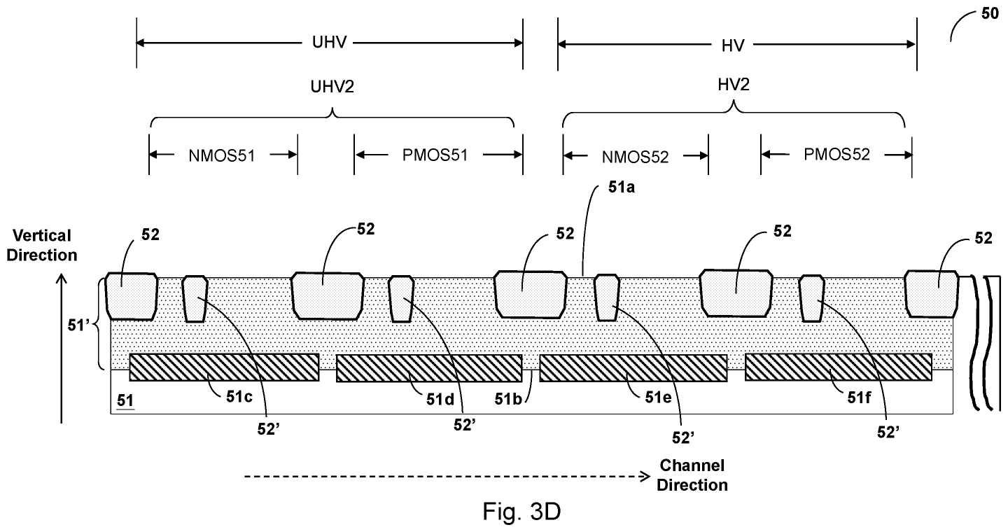

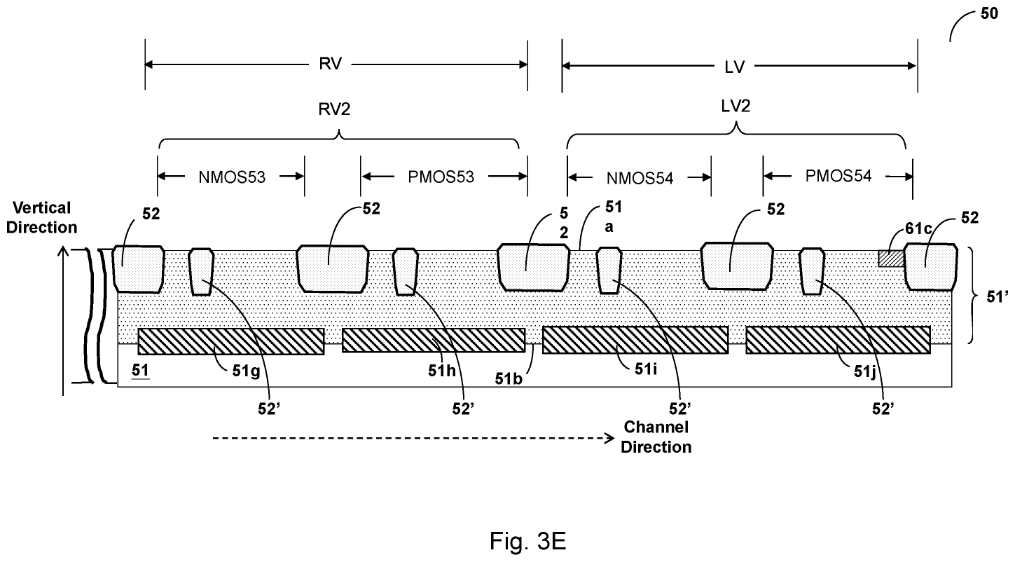

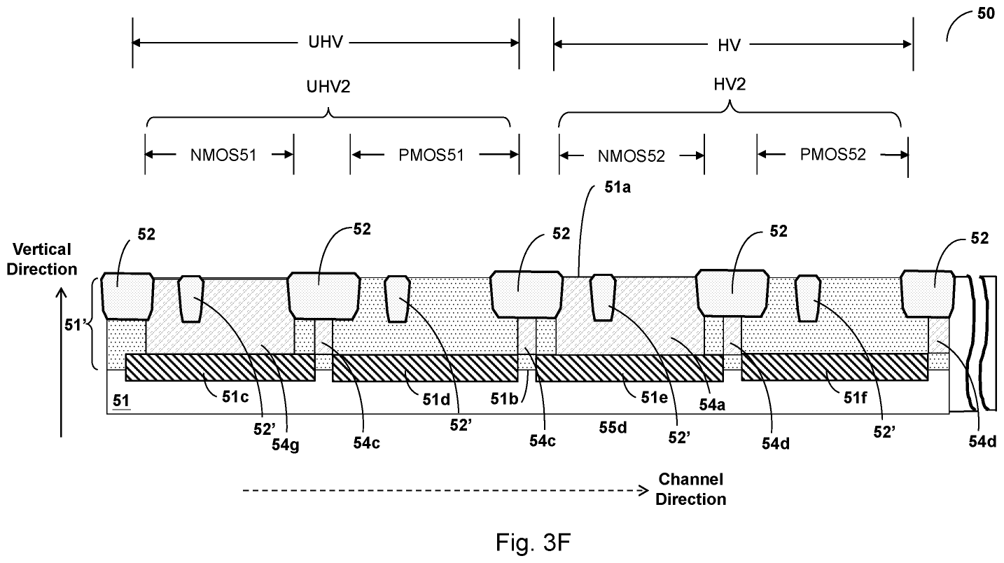

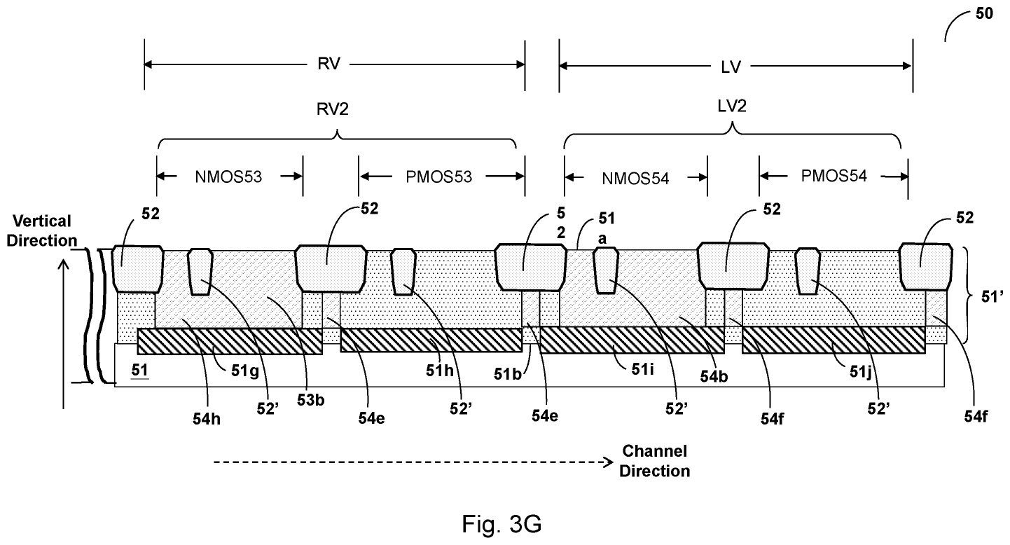

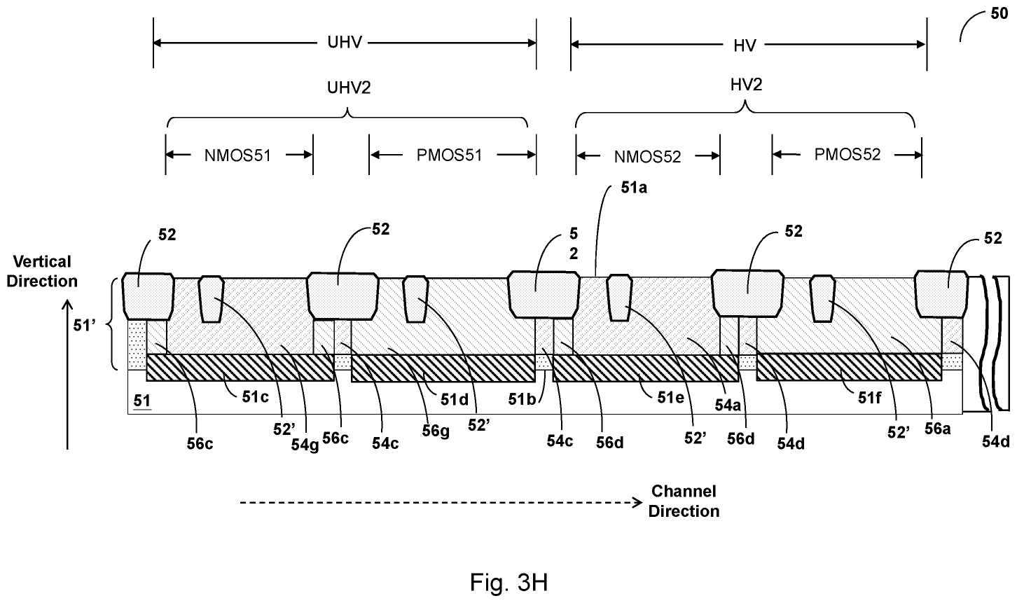

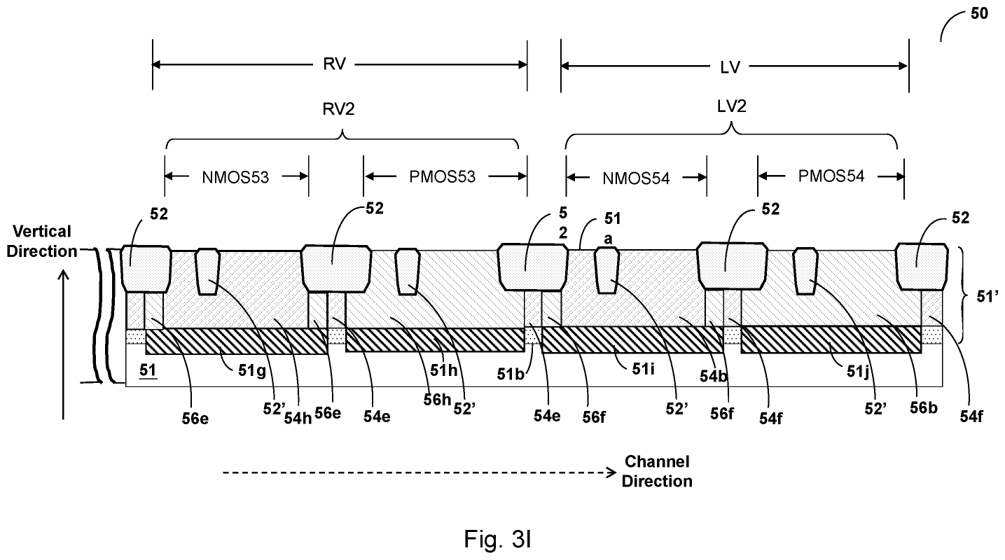

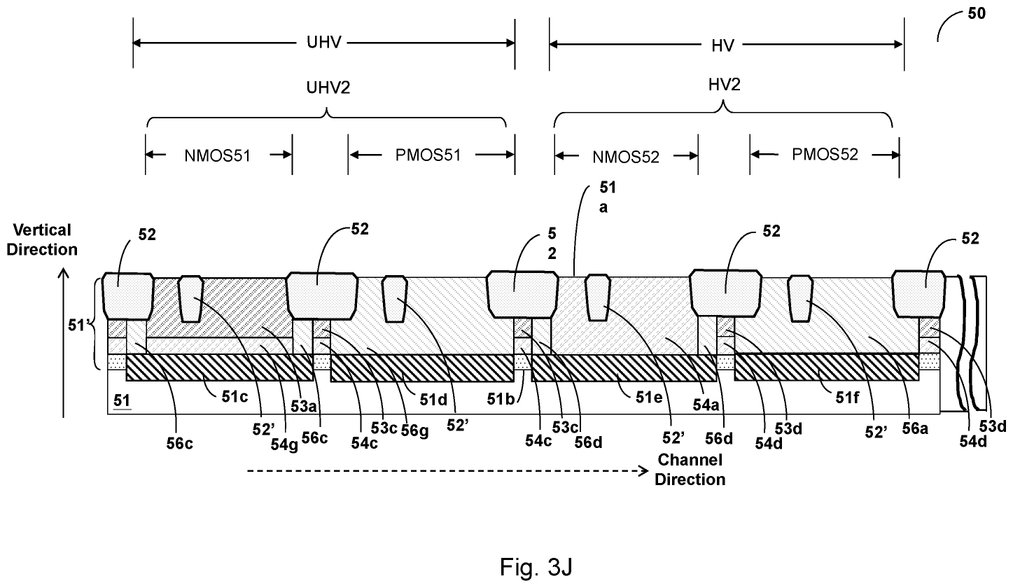

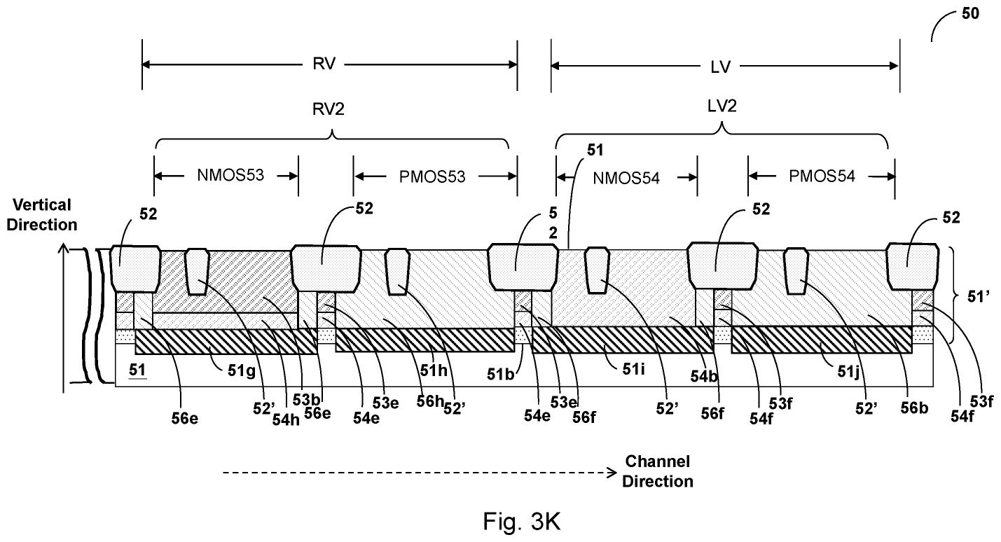

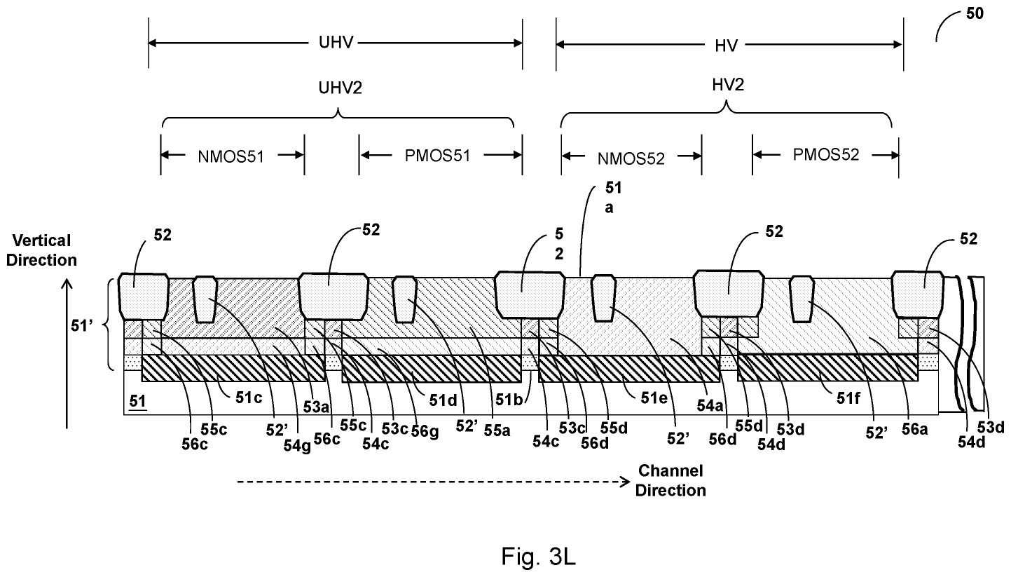

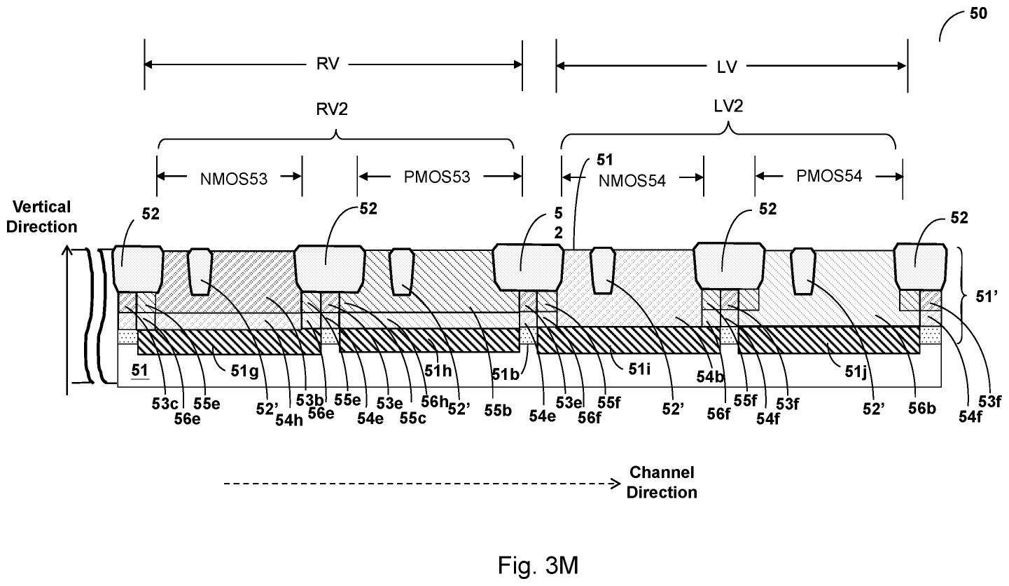

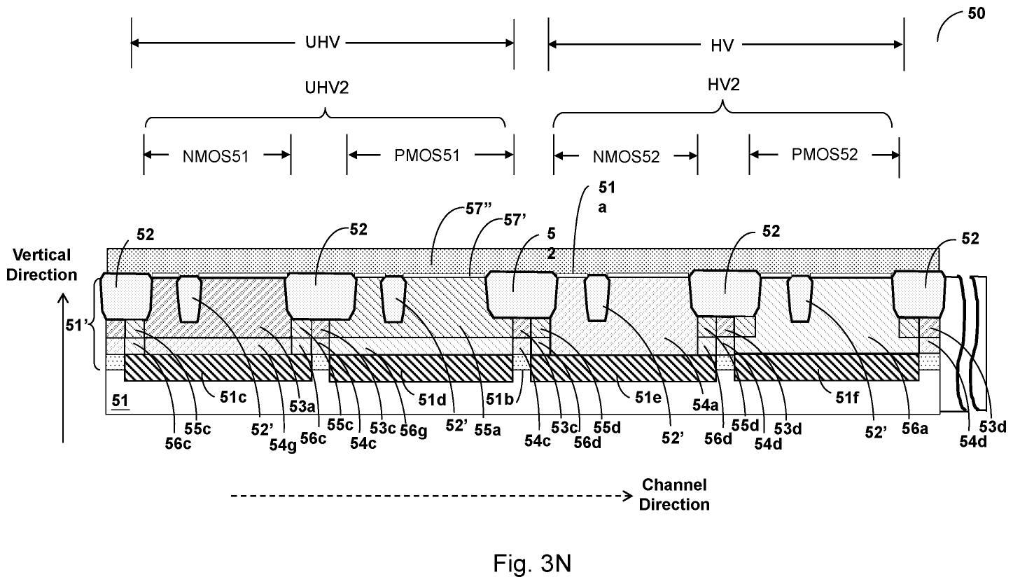

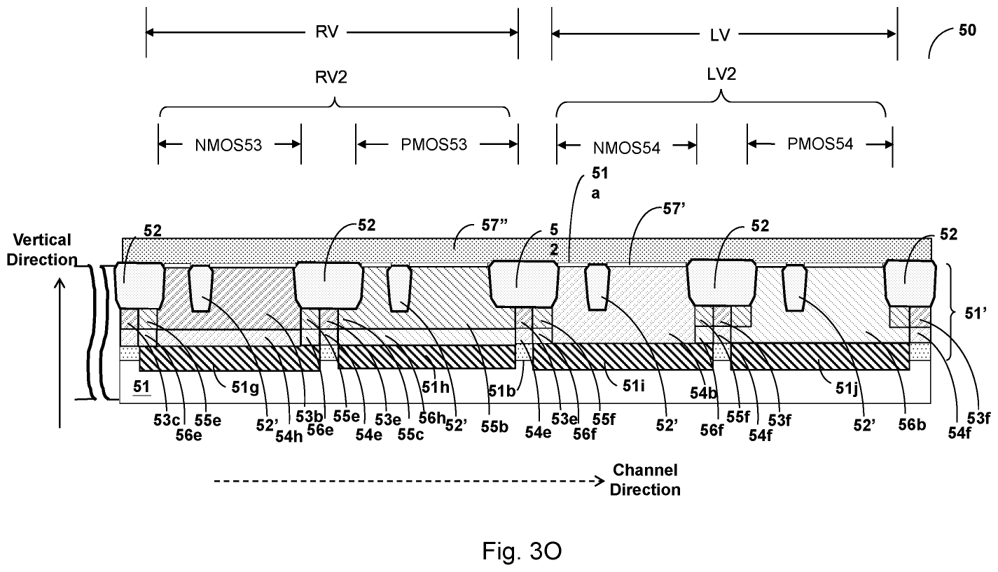

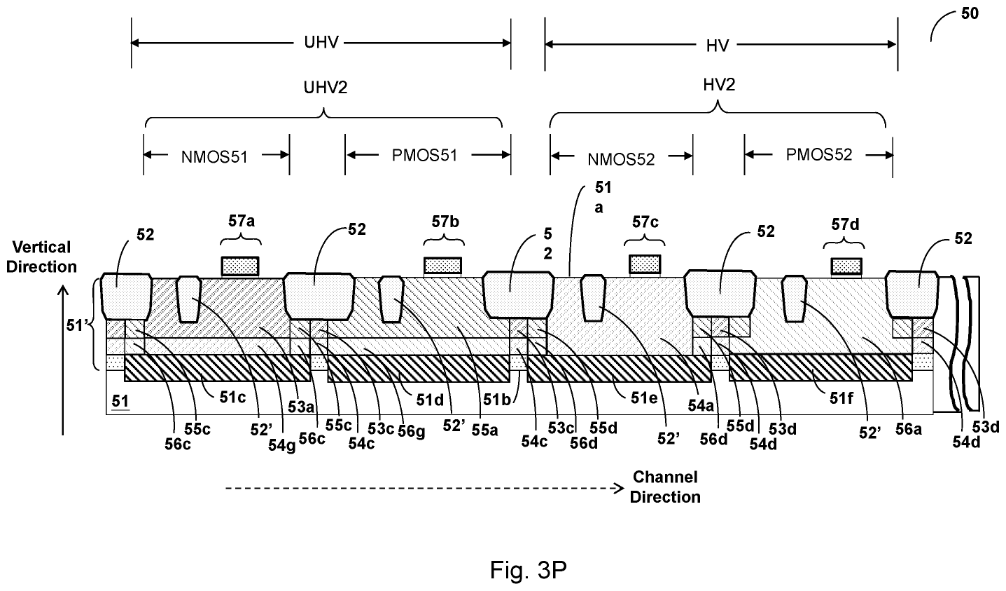

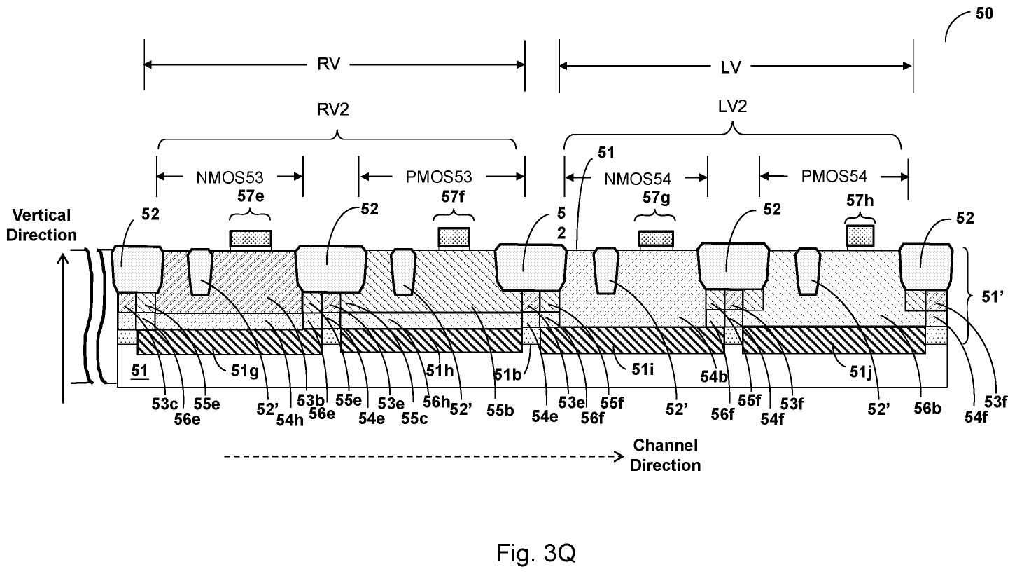

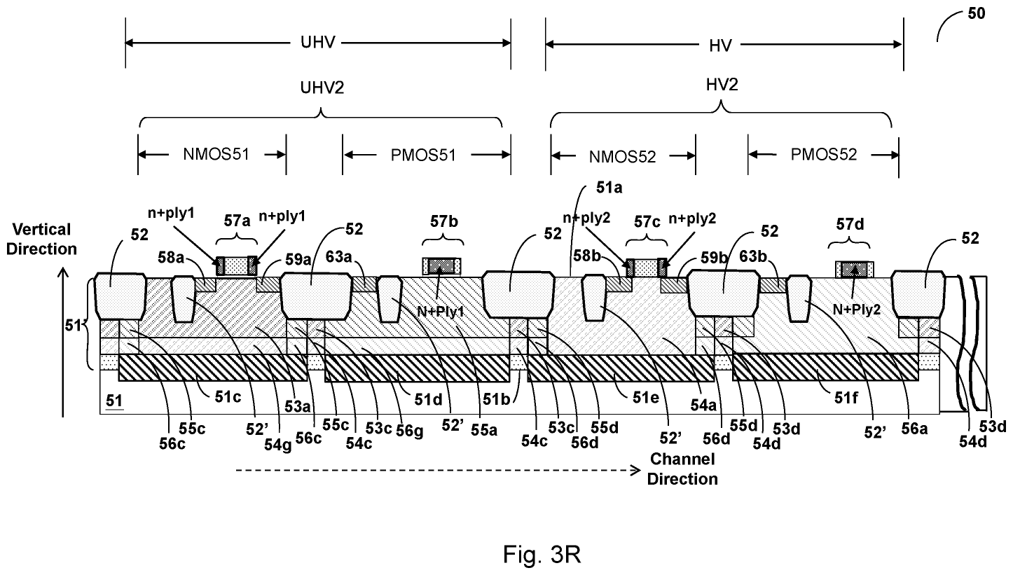

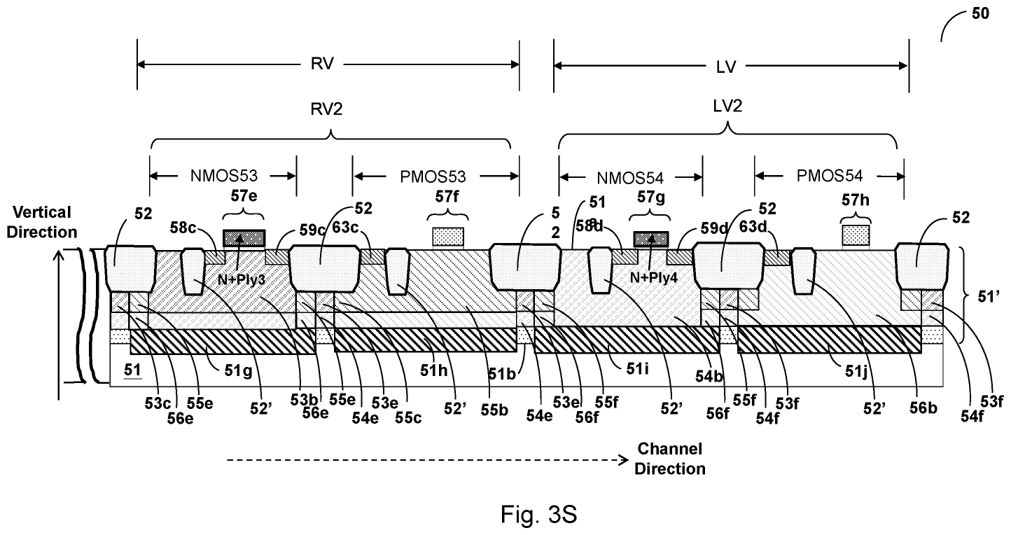

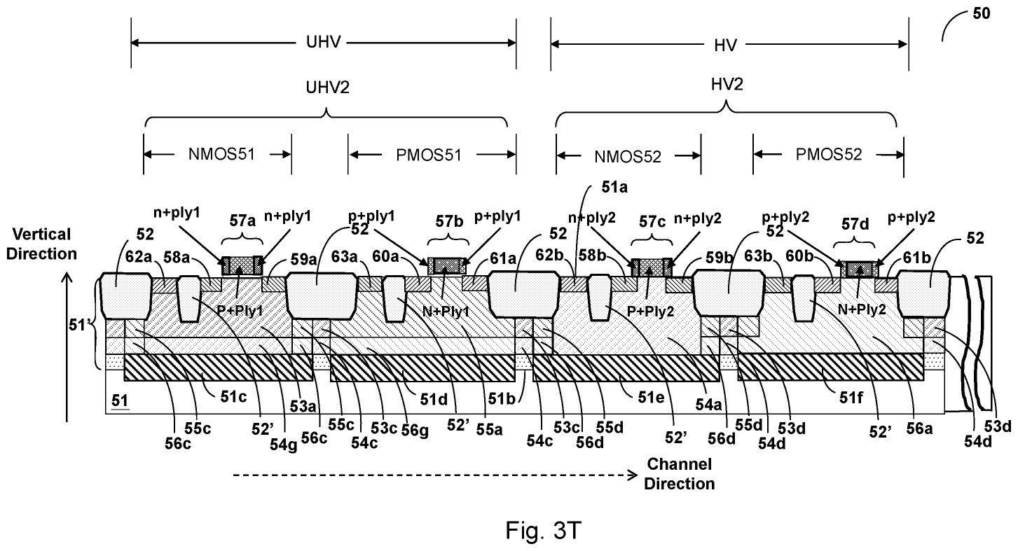

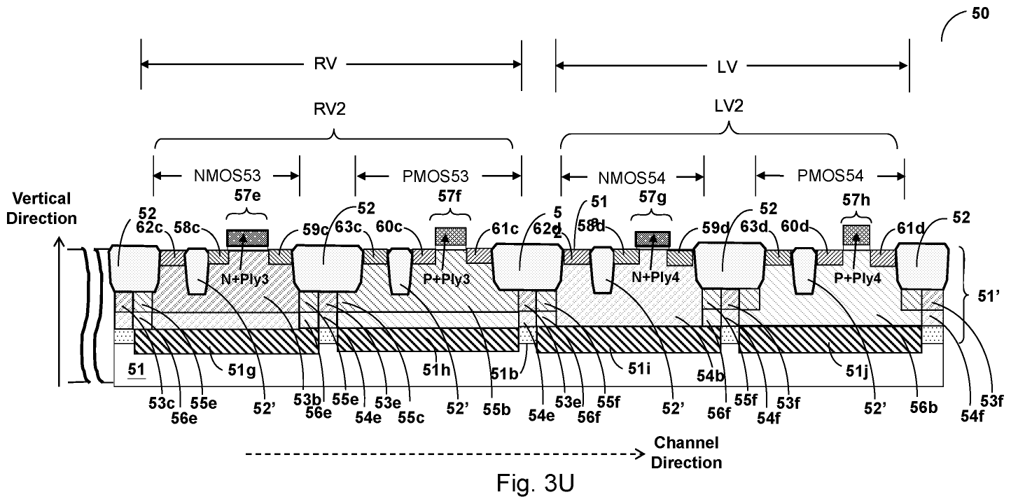

Please refer to FIG. 3A to FIG. 3U, which show cross-section views of a manufacturing method of the integrated structure 50 of CMOS devices according to an embodiment of the present invention. It is worthwhile mentioning that, for the sake of clarity of the figures, each stage of the manufacturing method of the integrated structure 50 of CMOS devices 50 is shown by two pages of figures (e.g., FIG. 3B and FIG. 3C show one stage) except FIG. 3A.

As shown in FIG. 3A, a substrate 51 is provided. A first N-type buried layer 51c, a second N-type buried layer 51d, a third N-type buried layer 51e, a fourth N-type buried layer 51f, a fifth N-type buried layer 51g, a sixth N-type buried layer 51h, a seventh N-type buried layer 51i and an eighth N-type buried layer 51j are formed, for example, first by an ion implantation process step which implants N conductivity type impurities in the substrate 51 in the form of accelerated ions, and next, during or subsequent to the formation of the semiconductor layer 51′ (as shown in FIG. 3B and FIG. 3C), the first N-type buried layer 51c, the second N-type buried layer 51d, the third N-type buried layer 51e, the fourth N-type buried layer 51f, the fifth N-type buried layer 51g, the sixth N-type buried layer 51h, the seventh N-type buried layer 51i and the eighth N-type buried layer 51j are completely formed by thermal diffusion.

Next, referring to FIG. 3B and FIG. 3C, the semiconductor layer 51′ is formed on the substrate 51. The semiconductor layer 51′, for example, is formed on the substrate 51 by an epitaxial process step, or is a part of the substrate 51. As mentioned above, during or subsequent to the formation of the semiconductor layer 51′, the first N-type buried layer 51c, the second N-type buried layer 51d, the third N-type buried layer 51e, the fourth N-type buried layer 51f, the fifth N-type buried layer 51g, the sixth N-type buried layer 51h, the seventh N-type buried layer 51i and the eighth N-type buried layer 51j are completely formed by thermal diffusion. The semiconductor layer 51′ has a top surface 51a and a bottom surface 51b opposite to the top surface 51a in a vertical direction. The semiconductor layer 51′ can be formed by various methods known to a person having ordinary skill in the art, so the details thereof are not redundantly explained here. The substrate 51 can be for example a P-type or an N-type semiconductor substrate.

Next, referring to FIG. 3D and FIG. 3E, insulation regions 52 and insulation regions 52′ are formed on the semiconductor layer 51′ for example by one same process step. The insulation regions 52 and the insulation regions 52′ can be, for example but not limited to, a shallow trench isolation (STI) structure shown in FIG. 3C and FIG. 3E. The insulation regions 52 are formed on the semiconductor layer 51′, for defining an ultra high threshold device region UHV, a high threshold device region HV, a middle threshold device region RV and a low threshold device region LV. A CMOS device UHV2 having an ultra high threshold voltage is formed in the ultra high threshold device region UHV; a CMOS device HV2 having a high threshold voltage is formed in the high threshold device region HV; a CMOS device RV2 having a middle threshold voltage is formed in the middle threshold device region RV; and a CMOS device LV2 having a low threshold voltage is formed in the low threshold device region LV.

The insulation regions 52′ serve to electrically isolate N-type sources from P-type conductive regions; that is, to be more specific, the insulation regions 52′ serve to electrically isolate the first N-type source 58a from the first P-type conductive region 62a, to electrically isolate the second N-type source 58b from the second P-type conductive region 62b, to electrically isolate the third N-type source 58c from the third P-type conductive region 62c, and to electrically isolate the fourth N-type source 58d from the fourth P-type conductive region 62d. And/or, the insulation regions 52′ serves to electrically isolate P-type sources from N-type conductive regions; that is, to be more specific, the insulation regions 52′ serves to electrically isolate the first P-type source 60a from the first N-type conductive region 63a, to electrically isolate the second P-type source 60b from the second N-type conductive region 63b, to electrically isolate the third P-type source 60c from the third N-type conductive region 63c, and to electrically isolate the fourth P-type source 60d from the fourth N-type conductive region 63d.

Next, referring to FIG. 3F and FIG. 3G, a first high voltage P-type well 54a, a second high voltage P-type well 54b, two third high voltage P-type wells 54c, two fourth high voltage P-type wells 54d, two fifth high voltage P-type wells 54e and two sixth high voltage P-type wells 54f, a first high voltage P-type isolation region 54g and a second high voltage P-type isolation region 54h are formed by one same ion implantation process step. It is worthwhile noting that, the first high voltage P-type isolation region 54g and the second high voltage P-type isolation region 54h overlap a first low voltage P-type well 53a and a second low voltage P-type well 53b which will be formed subsequently, at a region near the top surface 51a. Because the first low voltage P-type well 53a and the second low voltage P-type well 53b have a relatively higher concentration of P-type impurities, the overlapped regions regarded as belong to the first low voltage P-type well 53a and the second low voltage P-type well 53b; that is, the portions of the first high voltage P-type isolation region 54g and the second high voltage P-type isolation region 54h at the overlapped regions can be ignored.

The first high voltage P-type well 54a is formed in the semiconductor layer 51′ of the second NMOS device NMOS52 in the high threshold device region HV. The second high voltage P-type well 54b is formed in the semiconductor layer 51′ in the low threshold device region LV. The two third high voltage P-type wells 54c are formed in the semiconductor layer 51′ in the ultra high threshold device region UHV, wherein the two third high voltage P-type wells 54c are located beside and in contact with two sides of a first low voltage N-type well 55a which will be subsequently formed, respectively. And, The lower boundaries the two third high voltage P-type wells 54c are in contact with the second N-type buried layer 51d. Two fourth high voltage P-type wells 54d are formed in the semiconductor layer 51′ in the high threshold device region HV, wherein the two fourth high voltage P-type wells 54d are located beside and in contact with two sides of the first high voltage N-type well 56a which will be subsequently formed, respectively. And, The lower boundaries the two fourth high voltage P-type wells 54d are in contact with the fourth N-type buried layer 51f. The two fifth high voltage P-type wells 54e are formed in the semiconductor layer 51′ in the middle threshold device region RV, wherein the two fifth high voltage P-type wells 54e are located beside and in contact with two sides of the second low voltage N-type well 55b which will be subsequently formed, respectively. And, the lower boundaries the two fifth high voltage P-type wells 54e are in contact with the sixth N-type buried layer 51h. The two sixth high voltage P-type wells 54f are formed in the semiconductor layer 51′ in the low threshold device region LV, wherein the two sixth high voltage P-type wells 54f are located beside and in contact with two sides of the fourth high voltage N-type well 56b which will be subsequently formed, respectively. The lower boundaries the two sixth high voltage P-type wells 54f are in contact with the eighth N-type buried layer 51j. The first high voltage P-type isolation region 54g is below and in contact with the first low voltage P-type well 53a which will be subsequently formed. The second high voltage P-type isolation region 54h is below and in contact with the second low voltage P-type well 53b which will be subsequently formed.

Next, referring to FIG. 3H and FIG. 3I, a first high voltage N-type well 56a, a second high voltage N-type well 56b, two third high voltage N-type wells 56c, two fourth high voltage N-type wells 56d, two fifth high voltage N-type wells 56e, two sixth high voltage N-type wells 56f, a first high voltage N-type isolation region 56g, and a second high voltage N-type isolation region 56h are formed by one same ion implantation process step. It is worthwhile noting that, the first high voltage N-type isolation region 56g and the second high voltage N-type isolation region 56h overlap a first low voltage N-type well 55a and a second low voltage N-type well 55b which will be formed subsequently, at a region near the top surface 51a. Because the first low voltage N-type well 55a and the second low voltage N-type well 55b have a relatively higher concentration of N-type impurities, the overlapped regions are regarded as belong to the first low voltage N-type well 55a and the second low voltage N-type well 55b; that is, the portions of the first high voltage N-type isolation region 56g and the second high voltage N-type isolation region 56h at the overlapped regions can be ignored.

The first high voltage N-type well 56a and the second high voltage N-type well 56b are formed in the semiconductor layer 51′ in the high threshold device region HV and the semiconductor layer 51′ in the low threshold device region LV, respectively. The first high voltage N-type well 56a and the second high voltage N-type well 56b are below and in contact with the top surface 51a. A part of the first high voltage N-type well 56a is located vertically below and in contact with the fourth gate 57d which will be subsequently formed, which serves as an inversion current channel in an ON operation of the second PMOS device PMOS52. Besides, a part of the second high voltage N-type well 16b is located vertically below and in contact with the eighth gate 57h which will be subsequently formed, which serves as an inversion current channel in an ON operation of the fourth PMOS device PMOS54. The two third high voltage N-type wells 56c are formed in the semiconductor layer 51′ in the ultra high threshold device region UHV, wherein the two third high voltage N-type wells 56c are located beside and in contact with two sides of the first low voltage P-type well 53a which will be subsequently formed, respectively. And, the lower boundaries the two third high voltage N-type wells 56c are in contact with the first N-type buried layer 51c. The two fourth high voltage N-type wells 56d are formed in the semiconductor layer 51′ in the high threshold device region HV, wherein the two fourth high voltage N-type wells 56d are located beside and in contact with two sides of the first high voltage P-type well 54a which will be subsequently formed, respectively. And, the lower boundaries the two fourth high voltage N-type wells 56d are in contact with the third N-type buried layer 51e. The two fifth high voltage N-type wells 56e are formed in the semiconductor layer 51′ in the middle threshold device region RV, wherein the two fifth high voltage N-type wells 56e are located beside and in contact with two sides of the second low voltage P-type well 53b which will be subsequently formed, respectively. And, the lower boundaries the two fifth high voltage N-type wells 56e are in contact with the fifth N-type buried layer 51g. The two sixth high voltage N-type wells 56f are formed in the semiconductor layer 51′ in the low threshold device region LV, wherein the two sixth high voltage N-type wells 56f are located beside and in contact with two sides of the fourth high voltage P-type well 54b which will be subsequently formed, respectively. And, the lower boundaries the two sixth high voltage N-type wells 56f are in contact with the seventh N-type buried layer 51i. The first high voltage N-type isolation region 56g is below and in contact with the first low voltage N-type well 55a which will be subsequently formed. The second high voltage N-type isolation region 56h is below and in contact with the second low voltage N-type well 55b which will be subsequently formed.

Next, referring to FIG. 3J and FIG. 3K, a first low voltage P-type well 53a, a second low voltage P-type well 53b, two third low voltage P-type wells 53c, two fourth low voltage P-type wells 53d, two fifth low voltage P-type wells 53e and two sixth high voltage N-type wells 53f are formed by one same ion implantation process step.

The first low voltage P-type well 53a and the second low voltage P-type well 53b are formed in the semiconductor layer 51′ in the ultra high threshold device region UHV and the semiconductor layer 51′ in the middle threshold device region RV, respectively. The first low voltage P-type well 53a and the second low voltage P-type well 53b are below and in contact with the top surface 51a. A part of the first low voltage P-type well 53a is located vertically below and in contact with the first gate 57a which will be subsequently formed, which serves as an inversion current channel in an ON operation of the first NMOS device NMOS51. Besides, a part of the second low voltage P-type well 53b is located vertically below and in contact with the fifth gate 57e which will be subsequently formed, which serves as an inversion current channel in an ON operation of the third NMOS device NMOS53. The two third low voltage P-type wells 53c are formed in the semiconductor layer 51′ in the ultra high threshold device region UHV, wherein the two third low voltage P-type wells 53c are located beside and in contact with two sides of the first low voltage N-type well 55a which will be subsequently formed, respectively. The two fourth low voltage P-type wells 53d are formed in the semiconductor layer 51′ in the high threshold device region HV, wherein the two fourth low voltage P-type wells 53d are located beside and in contact with two sides of the first high voltage N-type well 56a which will be subsequently formed, respectively. The two fifth low voltage P-type wells 53e are formed in the semiconductor layer 51′ in the middle threshold device region RV, wherein the two fifth low voltage P-type wells 53e are located beside and in contact with two sides of the second low voltage N-type well 55b which will be subsequently formed, respectively. The two sixth high voltage N-type wells 53f are formed in the semiconductor layer 51′ in the low threshold device region LV, wherein the two sixth high voltage N-type wells 53f are located beside and in contact with two sides of the fourth high voltage N-type well 56b which will be subsequently formed, respectively.

Next, referring to FIG. 3L and FIG. 3M, a first low voltage N-type well 55a, a second low voltage N-type well 55b, two third low voltage N-type wells 55c, two fourth low voltage N-type wells 55d, two fifth low voltage N-type wells 55e and two sixth low voltage N-type wells 55f are formed by one same ion implantation process step.

The first high voltage P-type well 55a and the second high voltage P-type well 55b are formed in the semiconductor layer 51′ in the ultra high threshold device region UHV and the semiconductor layer 51′ in the middle threshold device region RV, respectively. The first high voltage P-type well 55a and the second high voltage P-type well 55b are below and in contact with the top surface 51a. A part of the first high voltage P-type well 55a is located vertically below and in contact with the second gate 57b which will be subsequently formed, which serves as an inversion current channel in an ON operation of the first PMOS device PMOS51. Besides, a part of the second high voltage P-type well 55b is located vertically below and in contact with the sixth gate 57f which will be subsequently formed, which serves as an inversion current channel in an ON operation of the third PMOS device PMOS53. The two third low voltage N-type wells 55c are formed in the semiconductor layer 51′ in the ultra high threshold device region UHV, wherein the two third low voltage N-type wells 55c are located beside and in contact with two sides of the first low voltage P-type well 53a which will be subsequently formed, respectively. The two fourth low voltage N-type wells 55d are formed in the semiconductor layer 51′ in the high threshold device region HV, wherein the two fourth low voltage N-type wells 55d are located beside and in contact with two sides of the first high voltage P-type well 54a which will be subsequently formed, respectively. The two fifth low voltage N-type wells 55e are formed in the semiconductor layer 51′ in the middle threshold device region RV, wherein the two fifth low voltage N-type wells 55e are located beside and in contact with two sides of the second low voltage P-type well 53b which will be subsequently formed, respectively. The two sixth low voltage N-type wells 55f are formed in the semiconductor layer 51′ in the low threshold device region LV, wherein the two sixth low voltage N-type wells 55f are located beside and in contact with two sides of the fourth high voltage P-type well 54b which will be subsequently formed, respectively.

Next, referring to FIG. 3N and FIG. 3O, a gate dielectric layer 57′ is formed on the semiconductor layer 51′, wherein the gate dielectric layer 57′ overlays the ultra high threshold device region UHV, the high threshold device region HV, the middle threshold device region RV and the low threshold device region LV. The gate dielectric layer 57′ will be split into different parts in a subsequent etching process step, to individually serve as a dielectric layer of the first gate 57a, a dielectric layer of the second gate 57b, a dielectric layer of the third gate 57c, a dielectric layer of the fourth gate 57d, a dielectric layer of the fifth gate 57e, a dielectric layer of the sixth gate 57f, a dielectric layer of the seventh gate 57g and a dielectric layer of the eighth gate 57h. In one embodiment, the gate dielectric layer 57′ has a thickness ranging between 80 Å to 100 Å.

Next, referring still to FIG. 3N and FIG. 3O, subsequent to the formation of the gate dielectric layer 57′, a polysilicon layer 57″ is formed on the gate dielectric layer 57′ by for example but not limited to a deposition process step, wherein the polysilicon layer 57″ overlays the ultra high threshold device region UHV, the high threshold device region HV, the middle threshold device region RV and the low threshold device region LV.

Next, referring to FIG. 3P and FIG. 3Q, subsequent to the formation of the polysilicon layer 57″, the polysilicon layer 57″ are etched to form a first gate 57a, a second gate 57b, a third gate 57c, a fourth gate 57d, a fifth gate 57e, a sixth gate 57f, a seventh gate 57g and an eighth gate 57h by one same etching process step.

Next, referring to FIG. 3R and FIG. 3S, subsequent to the formation of the first gate 57a, the second gate 57b, the third gate 57c, the fourth gate 57d, the fifth gate 57e, the sixth gate 57f, the seventh gate 57g and an eighth gate 57h, by one same ion implantation process step, a first N-type source 58a and a first N-type drain 59a, a second N-type source 58b and a second N-type drain 59b, a third N-type source 58c and a third N-type drain 59c, a fourth N-type source 58d and a fourth N-type drain 59d, a first N-type conductive region 63a, a second N-type conductive region 63b, a third N-type conductive region 63c, a fourth N-type conductive region 63d, two first N-type polysilicon sub-layers n+ply1 and n+ply1, two second N-type polysilicon sub-layers n+ply2 and n+ply2, a first N-type polysilicon layer N+Ply1, a second N-type polysilicon layer N+Ply2, a third N-type polysilicon layer N+Ply3 and a fourth N-type polysilicon layer N+Ply4 are forme, wherein the first N-type source 58a and the first N-type drain 59a are formed in the semiconductor layer 51′ of the ultra high threshold device region UHV; the second N-type source 58b and the second N-type drain 59b are formed in the semiconductor layer 51′ of the high threshold device region HV; the third N-type source 58c and the third N-type drain 59c are formed in the semiconductor layer 51′ of the middle threshold device region RV; the fourth N-type source 58d and the fourth N-type drain 59d are formed in the semiconductor layer 51′ of the low threshold device region LV; the first N-type conductive region 63a is formed in the first low voltage N-type well 55a in the ultra high threshold device region UHV; the second N-type conductive region 63b is formed in the first high voltage N-type well 56a in the high threshold device region HV; the third N-type conductive region 63c is formed in the second low voltage N-type well 55b in the middle threshold device region RV; the fourth N-type conductive region 63d is formed in the second high voltage N-type well 56b in the low threshold device region LV; the two first N-type polysilicon sub-layers n+ply1 and n+ply1 are formed to be located beside and in contact with two sides of the first P-type polysilicon layer P+Ply1 which will be subsequently formed; respectively; the two second N-type polysilicon sub-layers n+ply2 and n+ply2 are formed to be located beside and in contact with two sides of the second P-type polysilicon layer P+Ply2 which will be subsequently formed; respectively; and the first N-type polysilicon layer N+Ply1; the second N-type polysilicon layer N+Ply2; the third N-type polysilicon layer N+Ply3 and the fourth N-type polysilicon layer N+Ply4 are respectively formed in the second gate 57b; the fourth gate 57d; the fifth gate 57e and the seventh gate 57g; all being formed by one same process step.

Next, referring to FIG. 3T and FIG. 3U, by one same ion implantation process step, a first P-type source 60a and a first P-type drain 61a, a second P-type source 60b and a second P-type drain 61b, a third P-type source 60c and a third P-type drain 61c, a fourth P-type source 60d and a fourth P-type drain 61d, a first P-type conductive region 62a, a second P-type conductive region 62b, a third P-type conductive region 62c, a fourth P-type conductive region 62d, two first P-type polysilicon sub-layers p+Ply1 and p+Ply1, two second P-type polysilicon sub-layers p+ply2 and p+ply2, a first P-type polysilicon layer P+Ply1, a second P-type polysilicon layer P+Ply2, a third P-type polysilicon layer P+Ply3 and a fourth P-type polysilicon layer P+Ply4, are formed in a first gate 57a, a third gate 57c, a sixth gate 57f and a eighth gate 17h, wherein the first P-type source 60a and the first P-type drain 61a are formed in the semiconductor layer 51′ of the ultra high threshold device region UHV; the second P-type source 60b and the second P-type drain 61b are formed in the semiconductor layer 51′ of the high threshold device region HV; the third P-type source 60c and the third P-type drain 61c are formed in the semiconductor layer 51′ of the middle threshold device region RV; the fourth P-type source 60d and the fourth P-type drain 61d are formed in the semiconductor layer 51′ of the low threshold device region LV; the first P-type conductive region 62a is formed in the first low voltage P-type well 53a in the ultra high threshold device region UHV; the second P-type conductive region 62b is formed in the first high voltage P-type well 54a in the high threshold device region HV; the third P-type conductive region 62c is formed in the second low voltage P-type well 53b in the middle threshold device region RV; the fourth P-type conductive region 62d is formed in the second high voltage P-type well 54b in the low threshold device region LV; the two first P-type polysilicon sub-layers p+Ply1 and p+Ply1 are formed to be located beside and in contact with two sides of the first N-type polysilicon layer N+Ply1, respectively; the two second P-type polysilicon sub-layers p+ply2 and p+ply2 are formed to be located beside and in contact with two sides of the second N-type polysilicon layer N+Ply2, respectively; the first P-type polysilicon layer P+Ply1, the second P-type polysilicon layer P+Ply2, the third P-type polysilicon layer P+Ply3 and the fourth P-type polysilicon layer P+Ply4 are formed in the first gate 57a, the third gate 57c, the sixth gate 57f and the eighth gate 57h, respectively; all being formed by one same process step.

The first N-type source 58a and the first N-type drain 59a are located below and outside two sides of the first gate 57a in the channel direction, respectively, wherein the side of the first gate 57a which is closer to the first N-type source 58a is a source side and the side of the first gate 57a which is closer to the first N-type drain 59a is a drain side, and wherein the first N-type source 58a and the first N-type drain 59a are located in the first low voltage P-type well 53a at the source side and the drain side, respectively. In the vertical direction, the first N-type source 58a and the first N-type drain 59a are formed on and in contact with the top surface 51a.

The second N-type source 58b and the second N-type drain 59b are located below and outside two sides of the third gate 57c in the channel direction, respectively, wherein the side of the third gate 57c which is closer to the second N-type source 58b is a source side and the side of the third gate 57c which is closer to the second N-type drain 59b is a drain side, and wherein the second N-type source 58b and the second N-type drain 59b are located in the first high voltage P-type well 54a at the source side and the drain side, respectively. In the vertical direction, the second N-type source 58b and the second N-type drain 59b are formed on and in contact with the top surface 51a.

The third N-type source 58c and the third N-type drain 59c are located below and outside two sides of the fifth gate 57e in the channel direction, respectively, wherein the side of the fifth gate 57e which is closer to the third N-type source 58c is a source side and the side of the fifth gate 57e which is closer to the third N-type drain 59c is a drain side, and wherein the third N-type source 58c and the third N-type drain 59c are located in the second low voltage P-type well 53b at the source side and the drain side, respectively. In the vertical direction, the third N-type source 58c and the third N-type drain 59c are formed on and in contact with the top surface 51a.

The fourth N-type source 58d and the fourth N-type drain 59d are located below and outside two sides of the seventh gate 57g in the channel direction, respectively, wherein the side of the seventh gate 57g which is closer to the fourth N-type source 58d is a source side and the side of the seventh gate 57g which is closer to the fourth N-type drain 59d is a drain side, and wherein the fourth N-type source 58d and the fourth N-type drain 59d are located in the second high voltage P-type well 54b at the source side and the drain side, respectively. In the vertical direction, the fourth N-type source 58d and the fourth N-type drain 59d are formed on and in contact with the top surface 51a.

The first P-type source 60a and the first P-type drain 61a are located below and outside two sides of the second gate 57b in the channel direction, respectively, wherein the side of the second gate 57b which is closer to the first P-type source 60a is a source side and the side of the second gate 57b which is closer to the first P-type drain 61a is a drain side, and wherein the first P-type source 60a and the first P-type drain 61a are located in the first low voltage N-type well 55a at the source side and the drain side, respectively. In the vertical direction (as indicated by a solid arrow shown in FIG. 3T), the first P-type source 60a and a first P-type drain 61a are formed on and in contact with the top surface 51a.

The second P-type source 60b and the second P-type drain 61b are located below and outside two sides of the fourth gate 57d in the channel direction, respectively, wherein the side of the fourth gate 57d which is closer to the second P-type source 60b is a source side and the side of the fourth gate 57d which is closer to the second P-type drain 61b is a drain side, and wherein the second P-type source 60b and the second P-type drain 61b are located in the first high voltage N-type well 56a at the source side and the drain side, respectively. In the vertical direction, the second P-type source 60b and the second P-type drain 61b are formed on and in contact with the top surface 51a.

The third P-type source 60c and the third P-type drain 61c are located below and outside two sides of the sixth gate 57f in the channel direction, respectively, wherein the side of the sixth gate 57f which is closer to the third P-type source 60c is a source side and the side of the sixth gate 57f which is closer to the third P-type drain 61c is a drain side, and wherein the third P-type source 60c and the third P-type drain 61c are located in the second low voltage N-type well 55b at the source side and the drain side, respectively. In the vertical direction, the third P-type source 60c and the third P-type drain 61c are formed on and in contact with the top surface 51a.

The fourth P-type source 60d and the fourth P-type drain 61d are located below and outside two sides of the eighth gate 57h in the channel direction, respectively, wherein the side of the eighth gate 57h which is closer to the fourth P-type source 60d is a source side and the side of the eighth gate 57h which is closer to the fourth P-type drain 61d is a drain side, and wherein the fourth P-type source 60d and the fourth P-type drain 61d are located in the second high voltage N-type well 56b at the source side and the drain side, respectively. In the vertical direction, the fourth P-type source 60d and the fourth P-type drain 61d are formed on and in contact with the top surface 51a.

The first P-type conductive region 62a serves as an electrical contact of the first low voltage P-type well 53a. In the vertical direction, the first P-type conductive region 62a is formed on and in contact with the top surface 51a. The second P-type conductive region 62b serves as an electrical contact of the first high voltage P-type well 54a. In the vertical direction, the second P-type conductive region 62b is formed on and in contact with the top surface 51a. The third P-type conductive region 62c serves as an electrical contact of the second low voltage P-type well 53b. In the vertical direction, the third P-type conductive region 62c is formed on and in contact with the top surface 51a. The fourth P-type conductive region 62d serves as an electrical contact of the second high voltage P-type well 54b. In the vertical direction, the fourth P-type conductive region 62d is formed on and in contact with the top surface 51a.

The first N-type conductive region 63a serves as an electrical contact of the first low voltage N-type well 55a. In the vertical direction, the first N-type conductive region 63a is formed on and in contact with the top surface 51a. The second N-type conductive region 63b serves as an electrical contact of the first high voltage N-type well 56a. In the vertical direction, the second N-type conductive region 63b is formed on and in contact with the top surface 51a. The third N-type conductive region 63c serves as an electrical contact of the second low voltage N-type well 55b. In the vertical direction, the third N-type conductive region 63c is formed on and in contact with the top surface 51a. The fourth N-type conductive region 63d serves as an electrical contact of the second high voltage N-type well 56b. In the vertical direction, the fourth N-type conductive region 63d is formed on and in contact with the top surface 51a.

The first gate 57a is formed on the top surface 51a of the semiconductor layer 51′ in the ultra high threshold device region UHV. The first gate 57a has a first P-type polysilicon layer P+Ply1 and two first N-type polysilicon sub-layers n+ply1 and n+ply1, wherein the two first N-type polysilicon sub-layers n+ply1 and n+ply1 are located beside and in contact with two sides of the first P-type polysilicon layer P+Ply1, respectively. The first gate 57a includes: a conductive layer, a spacer layer and a dielectric layer, wherein the dielectric layer is located on and in contact with the top surface 51a, wherein the conductive layer includes the aforementioned first P-type polysilicon layer P+Ply1 and two first N-type polysilicon sub-layers n+ply1 and n+ply1, and wherein the spacer layer (not shown for simplicity of the drawing) overlays two sides of the conductive layer, which are known to a person having ordinary skill in the art, so the details thereof are not redundantly explained here.

The second gate 57b is formed on the top surface 51a of the semiconductor layer 51′ in the ultra high threshold device region UHV. The second gate 57b has a first N-type polysilicon layer N+Ply1 and two first P-type polysilicon sub-layers p+Ply1 and p+Ply1, wherein the two first P-type polysilicon sub-layers p+Ply1 and p+Ply1 are located beside and in contact with two sides of the first N-type polysilicon layer N+Ply1, respectively. The second gate 57b includes: a conductive layer, a spacer layer and a dielectric layer, wherein the dielectric layer is located on and in contact with the top surface 51a, wherein the conductive layer includes the aforementioned first N-type polysilicon layer N+Ply1 and two first P-type polysilicon sub-layers p+Ply1 and p+Ply, and wherein the spacer layer (not shown for simplicity of the drawing) overlays two sides of the conductive layer, which are known to a person having ordinary skill in the art, so the details thereof are not redundantly explained here.

The third gate 57c is formed on the top surface 51a of the semiconductor layer 51′ in the high threshold device region HV. The third gate 57c has a second P-type polysilicon layer P+Ply2 and two second N-type polysilicon sub-layers n+ply2 and n+ply2, wherein the two second N-type polysilicon sub-layers n+ply2 and n+ply2 are located beside and in contact with two sides of the second P-type polysilicon layer P+Ply2, respectively. The third gate 57c includes: a conductive layer, a spacer layer and a dielectric layer, wherein the dielectric layer is located on and in contact with the top surface 51a, wherein the conductive layer includes the aforementioned second P-type polysilicon layer P+Ply2 and two second N-type polysilicon sub-layers n+ply2 and n+ply2, and wherein the spacer layer (not shown for simplicity of the drawing) overlays two sides of the conductive layer, which are known to a person having ordinary skill in the art, so the details thereof are not redundantly explained here.

The fourth gate 57d is formed on the top surface 51a of the semiconductor layer 51′ in the high threshold device region HV. The fourth gate 57d has a second N-type polysilicon layer N+Ply2 and two second P-type polysilicon sub-layers p+ply2 and p+ply2, wherein the two second P-type polysilicon sub-layers p+ply2 and p+ply2 are located beside and in contact with two sides of the second N-type polysilicon layer N+Ply2, respectively. The fourth gate 57d includes: a conductive layer, a spacer layer and a dielectric layer, wherein the dielectric layer is located on and in contact with the top surface 51a, wherein the conductive layer includes the aforementioned second N-type polysilicon layer N+Ply2 and two second P-type polysilicon sub-layers p+ply2 and p+ply2, and wherein the spacer layer (not shown for simplicity of the drawing) overlays two sides of the conductive layer, which are known to a person having ordinary skill in the art, so the details thereof are not redundantly explained here.

The fifth gate 57e is formed on the top surface 51a of the semiconductor layer 51′ in the middle threshold device region RV. the fifth gate has a third N-type polysilicon layer N+Ply3. The fifth gate 57e includes: a conductive layer, a spacer layer and a dielectric layer, wherein the dielectric layer is located on and in contact with the top surface 51a, wherein the conductive layer includes the aforementioned third N-type polysilicon layer N+Ply3, and wherein the spacer layer (not shown for simplicity of the drawing) overlays two sides of the conductive layer, which are known to a person having ordinary skill in the art, so the details thereof are not redundantly explained here.

The sixth gate 57f is formed on the top surface 51a of the semiconductor layer 51′ in the middle threshold device region RV. The sixth gate 57f has a third P-type polysilicon layer P+Ply3. The sixth gate 57f includes: a conductive layer, a spacer layer and a dielectric layer, wherein the dielectric layer is located on and in contact with the top surface 51a, wherein the conductive layer includes the aforementioned third P-type polysilicon layer P+Ply3, and wherein the spacer layer (not shown for simplicity of the drawing) overlays two sides of the conductive layer, which are known to a person having ordinary skill in the art, so the details thereof are not redundantly explained here.

The seventh gate 57g is formed on the top surface 51a of the semiconductor layer 51′ in the low threshold device region LV. The seventh gate 57g has a fourth N-type polysilicon layer N+Ply4. The seventh gate 57g includes: a conductive layer, a spacer layer and a dielectric layer, wherein the dielectric layer is located on and in contact with the top surface 51a, wherein the conductive layer includes the aforementioned fourth N-type polysilicon layer N+Ply4, and wherein the spacer layer (not shown for simplicity of the drawing) overlays two sides of the conductive layer, which are known to a person having ordinary skill in the art, so the details thereof are not redundantly explained here.

The eighth gate 57h is formed on the top surface 51a of the semiconductor layer 51′ in the low threshold device region LV. The eighth gate 57h has a fourth P-type polysilicon layer P+Ply4. The eighth gate 57h includes: a conductive layer, a spacer layer and a dielectric layer, wherein the dielectric layer is located on and in contact with the top surface 51a, wherein the conductive layer includes the aforementioned fourth P-type polysilicon layer P+Ply4, and wherein the spacer layer (not shown for simplicity of the drawing) overlays two sides of the conductive layer, which are known to a person having ordinary skill in the art, so the details thereof are not redundantly explained here.

It is worthwhile mentioning that the thickness of the gate dielectric layer 57′ is far thinner than the thickness of the polysilicon layer 57″, which is known to a person having ordinary skill in the art, so the details thereof are not redundantly explained here.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a lightly doped drain (LDD) may be added. For another example, the lithography process step is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. An integrated structure of complementary metal-oxide-semiconductor (CMOS) devices, comprising:
a semiconductor layer, which is formed on a substrate;
a plurality of insulation regions, which are formed on the semiconductor layer, for defining an ultra high threshold device region, a high threshold device region, a middle threshold device region and a low threshold device region, wherein a CMOS device having an ultra high threshold voltage is formed in the ultra high threshold device region, wherein a CMOS device having a high threshold voltage is formed in the high threshold device region, wherein a CMOS device having a middle threshold voltage is formed in the middle threshold device region, and wherein a CMOS device having a low threshold voltage is formed in the low threshold device region;
a first low voltage P-type well and a second low voltage P-type well, which are formed in the semiconductor layer, for a first NMOS device in the ultra high threshold device region and for a third NMOS device in the middle threshold device region, respectively, by one same ion implantation process step;
a first high voltage P-type well and a second high voltage P-type well, which are formed in the semiconductor layer, for a second NMOS device in the high threshold device region and for a fourth NMOS device in the low threshold device region, respectively, by one same ion implantation process step;
a first low voltage N-type well and a second low voltage N-type well, which are formed in the semiconductor layer, for a first PMOS device in the ultra high threshold device region and for a third PMOS device in the middle threshold device region, respectively, by one same ion implantation process step;
a first high voltage N-type well and a second high voltage N-type well, which are formed in the semiconductor layer, for a second PMOS device in the high threshold device region and for a fourth PMOS device in the low threshold device region, respectively, by one same ion implantation process step;
a first gate, which is formed on the semiconductor layer of the first NMOS device in the ultra high threshold device region, wherein the first gate has a first P-type polysilicon layer and two first N-type polysilicon sub-layers, wherein the two first N-type polysilicon sub-layers are located beside and in contact with two sides of the first P-type polysilicon layer, respectively;
a second gate, which is formed on the semiconductor layer of the first PMOS device in the ultra high threshold device region, wherein the second gate has a first N-type polysilicon layer and two first P-type polysilicon sub-layers, wherein the two first P-type polysilicon sub-layers are located beside and in contact with two sides of the first N-type polysilicon layer, respectively;
a third gate, which is formed on the semiconductor layer of the second NMOS device in the high threshold device region, wherein the third gate has a second P-type polysilicon layer and two second N-type polysilicon sub-layers, wherein the two second N-type polysilicon sub-layers are located beside and in contact with two sides of the second P-type polysilicon layer, respectively;
a fourth gate, which is formed on the semiconductor layer of the second PMOS device in the ultra high threshold device region, wherein the fourth gate has a second N-type polysilicon layer and two second P-type polysilicon sub-layers, wherein the two second P-type polysilicon sub-layers are located beside and in contact with two sides of the second N-type polysilicon layer, respectively;
a fifth gate, which is formed on the semiconductor layer of the third NMOS device in the middle threshold device region, wherein the fifth gate has a third N-type polysilicon layer;
a sixth gate, which is formed on the semiconductor layer of the third PMOS device in the middle threshold device region, wherein the sixth gate has a third P-type polysilicon layer;
a seventh gate, which is formed on the semiconductor layer of the fourth NMOS device in the low threshold device region, wherein the seventh gate has a fourth N-type polysilicon layer; and
an eighth gate, which is formed on the semiconductor layer of the fourth PMOS device in the low threshold device region, wherein the eighth gate has a fourth P-type polysilicon layer;
wherein a threshold voltage of the first NMOS device is higher than a threshold voltage of the second NMOS device; the threshold voltage of the second NMOS device is higher than a threshold voltage of the third NMOS device; and the threshold voltage of the third NMOS device is higher than a threshold voltage of the fourth NMOS device;
wherein an absolute value of a threshold voltage of the first PMOS device is higher than an absolute value of a threshold voltage of the second PMOS device; the absolute value of the threshold voltage of the second PMOS device is higher than an absolute value of a threshold voltage of the third PMOS device; and the absolute value of the threshold voltage of the third PMOS device is higher than an absolute value of a threshold voltage of the fourth PMOS device;
wherein the CMOS device having an ultra high threshold voltage includes: the first NMOS device and the first PMOS device; the CMOS device having a high threshold voltage includes: the second NMOS device and the second PMOS device; the CMOS device having a middle threshold voltage includes: the third NMOS device and the third PMOS device; and the CMOS device having a low threshold voltage includes: the fourth NMOS device and the fourth PMOS device;
wherein a P-type doped impurities concentration of the first low voltage P-type well and the second low voltage P-type well is higher than a P-type doped impurities concentration of the first high voltage P-type well and the second high voltage P-type well;
wherein an N-type doped impurities concentration of the first low voltage N-type well and the second low voltage N-type well is higher than an N-type doped impurities concentration of the first high voltage N-type well and the second high voltage N-type well.

2. The integrated structure of complementary metal-oxide-semiconductor devices of claim 1, further comprising:
a first N-type buried layer, a second N-type buried layer, a third N-type buried layer, a fourth N-type buried layer, a fifth N-type buried layer, a sixth N-type buried layer, a seventh N-type buried layer and an eighth N-type buried layer, which are formed in the semiconductor layer and in the substrate which are below the first low voltage P-type well in the ultra high threshold device region, in the semiconductor layer and in the substrate which are below the first low voltage N-type well in the ultra high threshold device region, in the semiconductor layer and in the substrate which are below the first high voltage P-type well in the high threshold device region, in the semiconductor layer and in the substrate which are below the first high voltage N-type well in the high threshold device region, in the semiconductor layer and in the substrate which are below the second low voltage P-type well in the middle threshold device region, in the semiconductor layer and in the substrate which are below the second low voltage N-type well in the middle threshold device region, in the semiconductor layer and in the substrate which are below the second high voltage P-type well in the low threshold device region and in the semiconductor layer and in the substrate which are below the second high voltage N-type well in the low threshold device region, respectively, by one same process step;
two third low voltage N-type wells and two third high voltage N-type wells, which are formed in the semiconductor layer in the ultra high threshold device region, wherein the two third low voltage N-type wells are located beside and in contact with two sides of the first low voltage P-type well, respectively, whereas, the two third high voltage N-type wells are located beside and in contact with two sides of the first low voltage P-type well, respectively, wherein lower boundaries the two third high voltage N-type wells are in contact with the first N-type buried layer, wherein the two third low voltage N-type wells, the two third high voltage N-type wells and the first N-type buried layer constitute a first isolation region, which serves to electrically isolate the first NMOS device in the semiconductor layer, wherein the two third low voltage N-type wells are formed by the same ion implantation process step that forms the first low voltage N-type well, whereas, the two third high voltage N-type wells are formed by the same ion implantation process step that forms the first high voltage N-type well;
two third low voltage P-type wells and two third high voltage P-type wells, which are formed in the semiconductor layer in the ultra high threshold device region, wherein the two third low voltage P-type wells are located beside and in contact with two sides of the first low voltage N-type well, respectively, whereas, the two third high voltage P-type wells are located beside and in contact with two sides of the first low voltage N-type well, respectively, wherein lower boundaries the two third high voltage P-type wells are in contact with the second N-type buried layer, wherein the two third low voltage P-type wells, the two third high voltage P-type wells and the second N-type buried layer constitute a second isolation region, which serves to electrically isolate the first PMOS device in the semiconductor layer, wherein the two third low voltage P-type wells are formed by the same ion implantation process step that forms the first low voltage P-type well, whereas, the two third high voltage P-type wells are formed by the same ion implantation process step that forms the first high voltage P-type well;
two fourth low voltage N-type wells and two fourth high voltage N-type wells, which are formed in the semiconductor layer in the high threshold device region, wherein the two fourth low voltage N-type wells are located beside and in contact with two sides of the first high voltage P-type well, respectively, whereas, the two fourth high voltage N-type wells are located beside and in contact with two sides of the first high voltage P-type well, respectively, wherein lower boundaries the two fourth high voltage N-type wells are in contact with the third N-type buried layer, wherein the two fourth low voltage N-type wells, the two fourth high voltage N-type wells and the third N-type buried layer constitute a third isolation region, which serves to electrically isolate the second NMOS device in the semiconductor layer, wherein the two fourth low voltage N-type wells are formed by the same ion implantation process step that forms the first low voltage N-type well, whereas, the two fourth high voltage N-type wells are formed by the same ion implantation process step that forms the first high voltage N-type well;
two fourth low voltage P-type wells and two fourth high voltage P-type wells, which are formed in the semiconductor layer in the high threshold device region, wherein the two fourth low voltage P-type wells are located beside and in contact with two sides of the first high voltage N-type well, respectively, whereas, the two fourth high voltage P-type wells are located beside and in contact with two sides of the first high voltage N-type well, respectively, wherein lower boundaries the two fourth high voltage P-type wells are in contact with the fourth N-type buried layer, wherein the two fourth low voltage P-type wells, the two fourth high voltage P-type wells and the fourth N-type buried layer constitute a fourth isolation region, which serves to electrically isolate the second PMOS device in the semiconductor layer, wherein the two fourth low voltage P-type wells are formed by the same ion implantation process step that forms the first low voltage P-type well, whereas, the two fourth high voltage P-type wells are formed by the same ion implantation process step that forms the first high voltage P-type well;
two fifth low voltage N-type wells and two fifth high voltage N-type wells, which are formed in the semiconductor layer in the middle threshold device region, wherein the two fifth low voltage N-type wells are located beside and in contact with two sides of the second low voltage P-type well, respectively, whereas, the two fifth high voltage N-type wells are located beside and in contact with two sides of the second low voltage P-type well, respectively, wherein lower boundaries the two fifth high voltage N-type wells are in contact with the fifth N-type buried layer, wherein the two fifth low voltage N-type wells, the two fifth high voltage N-type wells and the fifth N-type buried layer constitute a fifth isolation region, which serves to electrically isolate the third NMOS device in the semiconductor layer, wherein the two fifth low voltage N-type wells are formed by the same ion implantation process step that forms the first low voltage N-type well, whereas, the two fifth high voltage N-type wells are formed by the same ion implantation process step that forms the first high voltage N-type well;
two fifth low voltage P-type wells and two fifth high voltage P-type wells, which are formed in the semiconductor layer in the middle threshold device region, wherein the two fifth low voltage P-type wells are located beside and in contact with two sides of the second low voltage N-type well, respectively, whereas, the two fifth high voltage P-type wells are located beside and in contact with two sides of the second low voltage N-type well, respectively, wherein lower boundaries the two fifth high voltage P-type wells are in contact with the sixth N-type buried layer, wherein the two fifth low voltage P-type wells, the two fifth high voltage P-type wells and the sixth N-type buried layer constitute a sixth isolation region, which serves to electrically isolate the third NMOS device in the semiconductor layer, wherein the two fifth low voltage P-type wells are formed by the same ion implantation process step that forms the first low voltage P-type well, whereas, the two fifth high voltage P-type wells are formed by the same ion implantation process step that forms the first high voltage P-type well;
two sixth low voltage N-type wells and two sixth high voltage N-type wells, which are formed in the semiconductor layer in the low threshold device region, wherein the two sixth low voltage N-type wells are located beside and in contact with two sides of the fourth high voltage P-type well, respectively, whereas, the two sixth high voltage N-type wells are located beside and in contact with two sides of the fourth high voltage P-type well, respectively, wherein lower boundaries the two sixth high voltage N-type wells are in contact with the seventh N-type buried layer, wherein the two sixth low voltage N-type wells, the two sixth high voltage N-type wells and the seventh N-type buried layer constitute a seventh isolation region, which serves to electrically isolate the fourth PMOS device in the semiconductor layer, wherein the two sixth low voltage N-type wells are formed by the same ion implantation process step that forms the first low voltage N-type well, whereas, the two sixth high voltage N-type wells are formed by the same ion implantation process step that forms the first high voltage N-type well;
two sixth high voltage N-type wells and two sixth high voltage P-type wells, which are formed in the semiconductor layer in the low threshold device region, wherein the two sixth high voltage N-type wells are located beside and in contact with two sides of the fourth high voltage N-type well, respectively, whereas, the two sixth high voltage P-type wells are located beside and in contact with two sides of the fourth high voltage N-type well, respectively, wherein lower boundaries the two sixth high voltage P-type wells are in contact with the eighth N-type buried layer, wherein the two sixth high voltage N-type wells, the two sixth high voltage P-type wells and the eighth N-type buried layer constitute an eighth isolation region, which serves to electrically isolate the fourth NMOS device in the semiconductor layer, wherein the two sixth high voltage N-type wells are formed by the same ion implantation process step that forms the first low voltage P-type well, whereas, the two sixth high voltage P-type wells are formed by the same ion implantation process step that forms the first high voltage P-type well.

3. The integrated structure of complementary metal-oxide-semiconductor devices of claim 1, further comprising:
a first N-type source and a first N-type drain, which are formed, by one same ion implantation process step, in the semiconductor layer of the ultra high threshold device region, wherein the first N-type source and the first N-type drain are located below and outside two sides of the first gate, respectively, wherein a side of the first gate which is closer to the first N-type source is a source side and a side of the first gate which is closer to the first N-type drain is a drain side, and wherein the first N-type source and the first N-type drain are located in the first low voltage P-type well at the source side and the drain side, respectively;
a first P-type source and a first P-type drain, which are formed, by one same ion implantation process step, in the semiconductor layer of the ultra high threshold device region, wherein the first P-type source and the first P-type drain are located below and outside two sides of the second gate, respectively, wherein a side of the second gate which is closer to the first P-type source is a source side and a side of the second gate which is closer to the first P-type drain is a drain side, and wherein the first P-type source and the first P-type drain are located in the first low voltage N-type well at the source side and the drain side, respectively;
a second N-type source and a second N-type drain, which are formed in the semiconductor layer of the high threshold device region by the one same ion implantation process step that forms the first N-type source and the first N-type drain, wherein the second N-type source and the second N-type drain are located below and outside two sides of the third gate, respectively, wherein a side of the third gate which is closer to the second N-type source is a source side and a side of the third gate which is closer to the second N-type drain is a drain side, and wherein the second N-type source and the second N-type drain are located in the first high voltage P-type well at the source side and the drain side, respectively;
a second P-type source and a second P-type drain, which are formed in the semiconductor layer of the high threshold device region by the one same ion implantation process step that forms the first P-type source and the first P-type drain, wherein the second P-type source and the second P-type drain are located below and outside two sides of the fourth gate, respectively, wherein a side of the fourth gate which is closer to the second P-type source is a source side and a side of the fourth gate which is closer to the second P-type drain is a drain side, and wherein the second P-type source and the second P-type drain are located in the first high voltage N-type well at the source side and the drain side, respectively;
a third N-type source and a third N-type drain, which are formed in the semiconductor layer of the middle threshold device region by the one same ion implantation process step that forms the first N-type source and the first N-type drain, wherein the third N-type source and the third N-type drain are located below and outside two sides of the fifth gate, respectively, wherein a side of the fifth gate which is closer to the third N-type source is a source side and a side of the fifth gate which is closer to the third N-type drain is a drain side, and wherein the third N-type source and the third N-type drain are located in the second low voltage P-type well at the source side and the drain side, respectively;
a third P-type source and a third P-type drain, which are formed in the semiconductor layer of the middle threshold device region by the one same ion implantation process step that forms the first P-type source and the first P-type drain, wherein the third P-type source and the third P-type drain are located below and outside two sides of the sixth gate, respectively, wherein a side of the sixth gate which is closer to the third P-type source is a source side and a side of the sixth gate which is closer to the third P-type drain is a drain side, and wherein the third P-type source and the third P-type drain are located in the second low voltage N-type well at the source side and the drain side, respectively;
a fourth N-type source and a fourth N-type drain, which are formed in the semiconductor layer of the low threshold device region by the one same ion implantation process step that forms the first N-type source and the first N-type drain, wherein the fourth N-type source and the fourth N-type drain are located below and outside two sides of the seventh gate, respectively, wherein a side of the seventh gate which is closer to the fourth N-type source is a source side and a side of the seventh gate which is closer to the fourth N-type drain is a drain side, and wherein the fourth N-type source and the fourth N-type drain are located in the second high voltage P-type well at the source side and the drain side, respectively; and
a fourth P-type source and a fourth P-type drain, which are formed in the semiconductor layer of the low threshold device region by the one same ion implantation process step that forms the first P-type source and the first P-type drain, wherein the fourth P-type source and the fourth P-type drain are located below and outside two sides of the eighth gate, respectively, wherein a side of the eighth gate which is closer to the fourth P-type source is a source side and a side of the eighth gate which is closer to the fourth P-type drain is a drain side, and wherein the fourth P-type source and the fourth P-type drain are located in the second high voltage N-type well at the source side and the drain side, respectively.

4. The integrated structure of complementary metal-oxide-semiconductor devices of claim 1, further comprising:
a first P-type conductive region, which is formed in the first low voltage P-type well in the ultra high threshold device region, wherein the first P-type conductive region serves as an electrical contact of the first low voltage P-type well;
a first N-type conductive region, which is formed in the first low voltage N-type well in the ultra high threshold device region, wherein the first N-type conductive region serves as an electrical contact of the first low voltage N-type well;
a second P-type conductive region, which is formed in the first high voltage P-type well in the high threshold device region by the same ion implantation process step that forms the first P-type conductive region, wherein the second P-type conductive region serves as an electrical contact of the first high voltage P-type well;
a second N-type conductive region, which is formed in the first high voltage N-type well in the high threshold device region by the same ion implantation process step that forms the first N-type conductive region, wherein the second N-type conductive region serves as an electrical contact of the first high voltage N-type well;
a third P-type conductive region, which is formed in the second low voltage P-type well in the middle threshold device region by the same ion implantation process step that forms the first P-type conductive region, wherein the third P-type conductive region serves as an electrical contact of the second low voltage P-type well;
a third N-type conductive region, which is formed in the second low voltage N-type well in the middle threshold device region by the same ion implantation process step that forms the first P-type conductive region, wherein the third N-type conductive region serves as an electrical contact of the second low voltage N-type well;
a fourth P-type conductive region, which is formed in the second high voltage P-type well in the low threshold device region by the same ion implantation process step that forms the first P-type conductive region, wherein the fourth P-type conductive region serves as an electrical contact of the second high voltage P-type well; and
a fourth N-type conductive region, which is formed in the second high voltage N-type well in the low threshold device region by the same ion implantation process step that forms the first P-type conductive region, wherein the fourth N-type conductive region serves as an electrical contact of the second high voltage N-type well.

5. The integrated structure of complementary metal-oxide-semiconductor devices of claim 1, further comprising:
a first high voltage P-type isolation region, which is formed in the semiconductor layer by the same ion implantation process step that forms the first high voltage P-type well;
a first high voltage N-type isolation region, which is formed in the semiconductor layer by the same ion implantation process step that forms the first high voltage N-type well;
a second high voltage P-type isolation region, which is formed in the semiconductor layer by the same ion implantation process step that forms the first high voltage P-type well;
a second high voltage N-type isolation region, which is formed in the semiconductor layer by the same ion implantation process step that forms the second high voltage N-type well;
wherein the first high voltage P-type isolation region is below and in contact with the first low voltage P-type well;
wherein the first high voltage N-type isolation region is below and in contact with the first low voltage N-type well;
wherein the second high voltage P-type isolation region is below and in contact with the second low voltage P-type well;
wherein the second high voltage N-type isolation region is below and in contact with the second low voltage N-type well.

6. The integrated structure of complementary metal-oxide-semiconductor devices of claim 1, wherein the semiconductor layer is a P-type semiconductor epitaxial layer having a volume resistivity which is 45 Ohm-cm.

7. The integrated structure of complementary metal-oxide-semiconductor devices of claim 1, wherein each of the dielectric layer of the first gate, the dielectric layer of the second gate, the dielectric layer of the third gate, the dielectric layer of the fourth gate, the dielectric layer of the fifth gate, the dielectric layer of the sixth gate, the dielectric layer of the seventh gate and the dielectric layer of the eighth gate has a thickness ranging between 80 Å to 100 Å.

8. The integrated structure of complementary metal-oxide-semiconductor devices of claim 1, wherein the integrated structure of complementary metal-oxide-semiconductor devices has a minimum feature size which is 0.18 micrometer.

9. A manufacturing method of an integrated structure of complementary metal-oxide-semiconductor (CMOS) devices, comprising:
forming a semiconductor layer on a substrate;
forming a plurality of insulation regions on the semiconductor layer, for defining an ultra high threshold device region, a high threshold device region, a middle threshold device region and a low threshold device region, wherein a CMOS device having an ultra high threshold voltage is formed in the ultra high threshold device region, wherein a CMOS device having a high threshold voltage is formed in the high threshold device region, wherein a CMOS device having a middle threshold voltage is formed in the middle threshold device region, and wherein a CMOS device having a low threshold voltage is formed in the low threshold device region;
forming a first low voltage P-type well and a second low voltage P-type well in the semiconductor layer, for a first NMOS device in the ultra high threshold device region and for a third NMOS device in the middle threshold device region, respectively, by one same ion implantation process step;
forming a first high voltage P-type well and a second high voltage P-type well in the semiconductor layer, for a second NMOS device in the high threshold device region and for a fourth NMOS device in the low threshold device region, respectively, by one same ion implantation process step;
forming a first low voltage N-type well and a second low voltage N-type well in the semiconductor layer, for a first PMOS device in the ultra high threshold device region and for a third PMOS device in the middle threshold device region, respectively, by one same ion implantation process step;
forming a first high voltage N-type well and a second high voltage N-type well in the semiconductor layer, for a second PMOS device in the high threshold device region and for a fourth PMOS device in the low threshold device region, respectively, by one same ion implantation process step;
forming a first gate on the semiconductor layer for the first NMOS device in the ultra high threshold device region, wherein the first gate has a first P-type polysilicon layer and two first N-type polysilicon sub-layers, wherein the two first N-type polysilicon sub-layers are located beside and in contact with two sides of the first P-type polysilicon layer, respectively;
forming a second gate on the semiconductor layer for the first PMOS device in the ultra high threshold device region, wherein the second gate has a first N-type polysilicon layer and two first P-type polysilicon sub-layers, wherein the two first P-type polysilicon sub-layers are located beside and in contact with two sides of the first N-type polysilicon layer, respectively;
forming a third gate on the semiconductor layer for the second NMOS device in the high threshold device region, wherein the third gate has a second P-type polysilicon layer and two second N-type polysilicon sub-layers, wherein the two second N-type polysilicon sub-layers are located beside and in contact with two sides of the second P-type polysilicon layer, respectively;
forming a fourth gate on the semiconductor layer for the second PMOS device in the ultra high threshold device region, wherein the fourth gate has a second N-type polysilicon layer and two second P-type polysilicon sub-layers, wherein the two second P-type polysilicon sub-layers are located beside and in contact with two sides of the second N-type polysilicon layer, respectively;
forming a fifth gate on the semiconductor layer for the third NMOS device in the middle threshold device region, wherein the fifth gate has a third N-type polysilicon layer;
forming a sixth gate on the semiconductor layer for the third PMOS device in the middle threshold device region, wherein the sixth gate has a third P-type polysilicon layer;
forming a seventh gate on the semiconductor layer for the fourth NMOS device in the low threshold device region, wherein the seventh gate has a fourth N-type polysilicon layer; and
forming an eighth gate on the semiconductor layer for the fourth PMOS device in the low threshold device region, wherein the eighth gate has a fourth P-type polysilicon layer;
wherein a threshold voltage of the first NMOS device is higher than a threshold voltage of the second NMOS device; the threshold voltage of the second NMOS device is higher than a threshold voltage of the third NMOS device; and the threshold voltage of the third NMOS device is higher than a threshold voltage of the fourth NMOS device;
wherein an absolute value of a threshold voltage of the first PMOS device is higher than an absolute value of a threshold voltage of the second PMOS device; the absolute value of the threshold voltage of the second PMOS device is higher than an absolute value of a threshold voltage of the third PMOS device; and the absolute value of the threshold voltage of the third PMOS device is higher than an absolute value of a threshold voltage of the fourth PMOS device;
wherein the CMOS device having an ultra high threshold voltage includes: the first NMOS device and the first PMOS device; the CMOS device having a high threshold voltage includes: the second NMOS device and the second PMOS device; the CMOS device having a middle threshold voltage includes: the third NMOS device and the third PMOS device; and the CMOS device having a low threshold voltage includes: the fourth NMOS device and the fourth PMOS device;
wherein a P-type doped impurities concentration of the first low voltage P-type well and the second low voltage P-type well is higher than a P-type doped impurities concentration of the first high voltage P-type well and the second high voltage P-type well;
wherein an N-type doped impurities concentration of the first low voltage N-type well and the second low voltage N-type well is higher than an N-type doped impurities concentration of the first high voltage N-type well and the second high voltage N-type well.

10. The manufacturing method of claim 9, further comprising:
forming a first N-type buried layer, a second N-type buried layer, a third N-type buried layer, a fourth N-type buried layer, a fifth N-type buried layer, a sixth N-type buried layer, a seventh N-type buried layer and an eighth N-type buried layer in the semiconductor layer and in the substrate which are below the first low voltage P-type well in the ultra high threshold device region, in the semiconductor layer and in the substrate which are below the first low voltage N-type well in the ultra high threshold device region, in the semiconductor layer and in the substrate which are below the first high voltage P-type well in the high threshold device region, in the semiconductor layer and in the substrate which are below the first high voltage N-type well in the high threshold device region, in the semiconductor layer and in the substrate which are below the second low voltage P-type well in the middle threshold device region, in the semiconductor layer and in the substrate which are below the second low voltage N-type well in the middle threshold device region, in the semiconductor layer and in the substrate which are below the second high voltage P-type well in the low threshold device region and in the semiconductor layer and in the substrate which are below the second high voltage N-type well in the low threshold device region, respectively, by one same process step;
forming two third low voltage N-type wells and two third high voltage N-type wells in the semiconductor layer in the ultra high threshold device region, wherein the two third low voltage N-type wells are located beside and in contact with two sides of the first low voltage P-type well, respectively, whereas, the two third high voltage N-type wells are located beside and in contact with two sides of the first low voltage P-type well, respectively, wherein lower boundaries the two third high voltage N-type wells are in contact with the first N-type buried layer, wherein the two third low voltage N-type wells, the two third high voltage N-type wells and the first N-type buried layer constitute a first isolation region, which serves to electrically isolate the first NMOS device in the semiconductor layer, wherein the two third low voltage N-type wells are formed by the same ion implantation process step that forms the first low voltage N-type well, whereas, the two third high voltage N-type wells are formed by the same ion implantation process step that forms the first high voltage N-type well;
forming two third low voltage P-type wells and two third high voltage P-type wells in the semiconductor layer in the ultra high threshold device region, wherein the two third low voltage P-type wells are located beside and in contact with two sides of the first low voltage N-type well, respectively, whereas, the two third high voltage P-type wells are located beside and in contact with two sides of the first low voltage N-type well, respectively, wherein lower boundaries the two third high voltage P-type wells are in contact with the second N-type buried layer, wherein the two third low voltage P-type wells, the two third high voltage P-type wells and the second N-type buried layer constitute a second isolation region, which serves to electrically isolate the first PMOS device in the semiconductor layer, wherein the two third low voltage P-type wells are formed by the same ion implantation process step that forms the first low voltage P-type well, whereas, the two third high voltage P-type wells are formed by the same ion implantation process step that forms the first high voltage P-type well;
forming two fourth low voltage N-type wells and two fourth high voltage N-type wells in the semiconductor layer in the high threshold device region, wherein the two fourth low voltage N-type wells are located beside and in contact with two sides of the first high voltage P-type well, respectively, whereas, the two fourth high voltage N-type wells are located beside and in contact with two sides of the first high voltage P-type well, respectively, wherein lower boundaries the two fourth high voltage N-type wells are in contact with the third N-type buried layer, wherein the two fourth low voltage N-type wells, the two fourth high voltage N-type wells and the third N-type buried layer constitute a third isolation region, which serves to electrically isolate the second NMOS device in the semiconductor layer, wherein the two fourth low voltage N-type wells are formed by the same ion implantation process step that forms the first low voltage N-type well, whereas, the two fourth high voltage N-type wells are formed by the same ion implantation process step that forms the first high voltage N-type well;
forming two fourth low voltage P-type wells and two fourth high voltage P-type wells in the semiconductor layer in the high threshold device region, wherein the two fourth low voltage P-type wells are located beside and in contact with two sides of the first high voltage N-type well, respectively, whereas, the two fourth high voltage P-type wells are located beside and in contact with two sides of the first high voltage N-type well, respectively, wherein lower boundaries the two fourth high voltage P-type wells are in contact with the fourth N-type buried layer, wherein the two fourth low voltage P-type wells, the two fourth high voltage P-type wells and the fourth N-type buried layer constitute a fourth isolation region, which serves to electrically isolate the second PMOS device in the semiconductor layer, wherein the two fourth low voltage P-type wells are formed by the same ion implantation process step that forms the first low voltage P-type well, whereas, the two fourth high voltage P-type wells are formed by the same ion implantation process step that forms the first high voltage P-type well;
forming two fifth low voltage N-type wells and two fifth high voltage N-type wells in the semiconductor layer in the middle threshold device region, wherein the two fifth low voltage N-type wells are located beside and in contact with two sides of the second low voltage P-type well, respectively, whereas, the two fifth high voltage N-type wells are located beside and in contact with two sides of the second low voltage P-type well, respectively, wherein lower boundaries the two fifth high voltage N-type wells are in contact with the fifth N-type buried layer, wherein the two fifth low voltage N-type wells, the two fifth high voltage N-type wells and the fifth N-type buried layer constitute a fifth isolation region, which serves to electrically isolate the third NMOS device in the semiconductor layer, wherein the two fifth low voltage N-type wells are formed by the same ion implantation process step that forms the first low voltage N-type well, whereas, the two fifth high voltage N-type wells are formed by the same ion implantation process step that forms the first high voltage N-type well;
forming two fifth low voltage P-type wells and two fifth high voltage P-type wells in the semiconductor layer in the middle threshold device region, wherein the two fifth low voltage P-type wells are located beside and in contact with two sides of the second low voltage N-type well, respectively, whereas, the two fifth high voltage P-type wells are located beside and in contact with two sides of the second low voltage N-type well, respectively, wherein lower boundaries the two fifth high voltage P-type wells are in contact with the sixth N-type buried layer, wherein the two fifth low voltage P-type wells, the two fifth high voltage P-type wells and the sixth N-type buried layer constitute a sixth isolation region, which serves to electrically isolate the third NMOS device in the semiconductor layer, wherein the two fifth low voltage P-type wells are formed by the same ion implantation process step that forms the first low voltage P-type well, whereas, the two fifth high voltage P-type wells are formed by the same ion implantation process step that forms the first high voltage P-type well;
forming two sixth low voltage N-type wells and two sixth high voltage N-type wells in the semiconductor layer in the low threshold device region, wherein the two sixth low voltage N-type wells are located beside and in contact with two sides of the fourth high voltage P-type well, respectively, whereas, the two sixth high voltage N-type wells are located beside and in contact with two sides of the fourth high voltage P-type well, respectively, wherein lower boundaries the two sixth high voltage N-type wells are in contact with the seventh N-type buried layer, wherein the two sixth low voltage N-type wells, the two sixth high voltage N-type wells and the seventh N-type buried layer constitute a seventh isolation region, which serves to electrically isolate the fourth NMOS device in the semiconductor layer, wherein the two sixth low voltage N-type wells are formed by the same ion implantation process step that forms the first low voltage N-type well, whereas, the two sixth high voltage N-type wells are formed by the same ion implantation process step that forms the first high voltage N-type well;
forming two sixth high voltage N-type wells and two sixth high voltage P-type wells in the semiconductor layer in the low threshold device region, wherein the two sixth high voltage N-type wells are located beside and in contact with two sides of the fourth high voltage N-type well, respectively, whereas, the two sixth high voltage P-type wells are located beside and in contact with two sides of the fourth high voltage N-type well, respectively, wherein lower boundaries the two sixth high voltage P-type wells are in contact with the eighth N-type buried layer, wherein the two sixth high voltage N-type wells, the two sixth high voltage P-type wells and the eighth N-type buried layer constitute an eighth isolation region, which serves to electrically isolate the fourth PMOS device in the semiconductor layer, wherein the two sixth high voltage N-type wells are formed by the same ion implantation process step that forms the first low voltage P-type well, whereas, the two sixth high voltage P-type wells are formed by the same ion implantation process step that forms the first high voltage P-type well.

11. The manufacturing method of claim 9, further comprising:
forming a first N-type source and a first N-type drain, by one same ion implantation process step, in the semiconductor layer of the ultra high threshold device region, wherein the first N-type source and the first N-type drain are located below and outside two sides of the first gate, respectively, wherein a side of the first gate which is closer to the first N-type source is a source side and a side of the first gate which is closer to the first N-type drain is a drain side, and wherein the first N-type source and the first N-type drain are located in the first low voltage P-type well at the source side and the drain side, respectively;
forming a first P-type source and a first P-type drain, by one same ion implantation process step, in the semiconductor layer of the ultra high threshold device region, wherein the first P-type source and the first P-type drain are located below and outside two sides of the second gate, respectively, wherein a side of the second gate which is closer to the first P-type source is a source side and a side of the second gate which is closer to the first P-type drain is a drain side, and wherein the first P-type source and the first P-type drain are located in the first low voltage N-type well at the source side and the drain side, respectively;
forming a second N-type source and a second N-type drain in the semiconductor layer of the high threshold device region by the one same ion implantation process step that forms the first N-type source and the first N-type drain, wherein the second N-type source and the second N-type drain are located below and outside two sides of the third gate, respectively, wherein a side of the third gate which is closer to the second N-type source is a source side and a side of the third gate which is closer to the second N-type drain is a drain side, and wherein the second N-type source and the second N-type drain are located in the first high voltage P-type well at the source side and the drain side, respectively;
forming a second P-type source and a second P-type drain in the semiconductor layer of the high threshold device region by the one same ion implantation process step that forms the first P-type source and the first P-type drain, wherein the second P-type source and the second P-type drain are located below and outside two sides of the fourth gate, respectively, wherein a side of the fourth gate which is closer to the second P-type source is a source side and a side of the fourth gate which is closer to the second P-type drain is a drain side, and wherein the second P-type source and the second P-type drain are located in the first high voltage N-type well at the source side and the drain side, respectively;
forming a third N-type source and a third N-type drain in the semiconductor layer of the middle threshold device region by the one same ion implantation process step that forms the first N-type source and the first N-type drain, wherein the third N-type source and the third N-type drain are located below and outside two sides of the fifth gate, respectively, wherein a side of the fifth gate which is closer to the third N-type source is a source side and a side of the fifth gate which is closer to the third N-type drain is a drain side, and wherein the third N-type source and the third N-type drain are located in the second low voltage P-type well at the source side and the drain side, respectively;
forming a third P-type source and a third P-type drain in the semiconductor layer of the middle threshold device region by the one same ion implantation process step that forms the first P-type source and the first P-type drain, wherein the third P-type source and the third P-type drain are located below and outside two sides of the sixth gate, respectively, wherein a side of the sixth gate which is closer to the third P-type source is a source side and a side of the sixth gate which is closer to the third P-type drain is a drain side, and wherein the third P-type source and the third P-type drain are located in the second low voltage N-type well at the source side and the drain side, respectively;
forming a fourth N-type source and a fourth N-type drain in the semiconductor layer of the low threshold device region by the one same ion implantation process step that forms the first N-type source and the first N-type drain, wherein the fourth N-type source and the fourth N-type drain are located below and outside two sides of the seventh gate, respectively, wherein a side of the seventh gate which is closer to the fourth N-type source is a source side and a side of the seventh gate which is closer to the fourth N-type drain is a drain side, and wherein the fourth N-type source and the fourth N-type drain are located in the second high voltage P-type well at the source side and the drain side, respectively; and
forming a fourth P-type source and a fourth P-type drain in the semiconductor layer of the low threshold device region by the one same ion implantation process step that forms the first P-type source and the first P-type drain, wherein the fourth P-type source and the fourth P-type drain are located below and outside two sides of the eighth gate, respectively, wherein a side of the eighth gate which is closer to the fourth P-type source is a source side and a side of the eighth gate which is closer to the fourth P-type drain is a drain side, and wherein the fourth P-type source and the fourth P-type drain are located in the second high voltage N-type well at the source side and the drain side, respectively.

12. The manufacturing method of claim 9, further comprising:
forming a first P-type conductive region in the first low voltage P-type well in the ultra high threshold device region, wherein the first P-type conductive region serves as an electrical contact of the first low voltage P-type well;
forming a first N-type conductive region in the first low voltage N-type well in the ultra high threshold device region, wherein the first N-type conductive region serves as an electrical contact of the first low voltage N-type well;
forming a second P-type conductive region in the first high voltage P-type well in the high threshold device region by the same ion implantation process step that forms the first P-type conductive region, wherein the second P-type conductive region serves as an electrical contact of the first high voltage P-type well;
forming a second N-type conductive region in the first high voltage N-type well in the high threshold device region by the same ion implantation process step that forms the first N-type conductive region, wherein the second N-type conductive region serves as an electrical contact of the first high voltage N-type well;
forming a third P-type conductive region in the second low voltage P-type well in the middle threshold device region by the same ion implantation process step that forms the first P-type conductive region, wherein the third P-type conductive region serves as an electrical contact of the second low voltage P-type well;
forming a third N-type conductive region in the second low voltage N-type well in the middle threshold device region by the same ion implantation process step that forms the first P-type conductive region, wherein the third N-type conductive region serves as an electrical contact of the second low voltage N-type well;
forming a fourth P-type conductive region in the second high voltage P-type well in the low threshold device region by the same ion implantation process step that forms the first P-type conductive region, wherein the fourth P-type conductive region serves as an electrical contact of the second high voltage P-type well; and
forming a fourth N-type conductive region in the second high voltage N-type well in the low threshold device region by the same ion implantation process step that forms the first P-type conductive region, wherein the fourth N-type conductive region serves as an electrical contact of the second high voltage N-type well.

13. The manufacturing method of claim 9, further comprising:
forming a first high voltage P-type isolation region in the semiconductor layer by the same ion implantation process step that forms the first high voltage P-type well;
forming a first high voltage N-type isolation region in the semiconductor layer by the same ion implantation process step that forms the first high voltage N-type well;
forming a second high voltage P-type isolation region in the semiconductor layer by the same ion implantation process step that forms the first high voltage P-type well;
forming a second high voltage N-type isolation region in the semiconductor layer by the same ion implantation process step that forms the second high voltage N-type well;
wherein the first high voltage P-type isolation region is below and in contact with the first low voltage P-type well;
wherein the first high voltage N-type isolation region is below and in contact with the first low voltage N-type well;
wherein the second high voltage P-type isolation region is below and in contact with the second low voltage P-type well;
wherein the second high voltage N-type isolation region is below and in contact with the second low voltage N-type well.

14. The manufacturing method of claim 9, wherein the semiconductor layer is a P-type semiconductor epitaxial layer having a volume resistivity which is 45 Ohm-cm.

15. The manufacturing method of claim 11, wherein each of the dielectric layer of the first gate, the dielectric layer of the second gate, the dielectric layer of the third gate, the dielectric layer of the fourth gate, the dielectric layer of the fifth gate, the dielectric layer of the sixth gate, the dielectric layer of the seventh gate and the dielectric layer of the eighth gate has a thickness ranging between 80 Å to 100 Å.

16. The manufacturing method of claim 11, wherein the integrated structure of complementary metal-oxide-semiconductor devices has a minimum feature size which is 0.18 micrometer.
